(19) United States
(12) Patent Application Publication
(10) Pub. No.: US 2017/0237036 A1
(43) Pub. Date: Aug. 17, 2017

(54) ORGANIC-ELECTROLUMINESCENT-ELEMENT LIQUID COMPOSITION PACKAGING

(71) Applicants: SUMITOMO CHEMICAL COMPANY, LIMITED, Tokyo (JP); JOLED INC., Tokyo (JP)

(72) Inventors: Takahiro UEOKA, Osaka-shi (JP); Hidenobu KAKIMOTO, Osaka-shi (JP); Masashi KOMATSU, Osaka-shi (JP); Masaki NISHIMURA, Tokyo (JP); Hirotaka NANNO, Tokyo (JP)

(73) Assignees: SUMITOMO CHEMICAL COMPANY, LIMITED, Tokyo (JP); JOLED INC., Tokyo (JP)

(21) Appl. No.: 15/501,357

(22) PCT Filed: Jul. 31, 2015
(86) PCT No.: PCT/JP2015/071878

§ 371 Date: Feb. 2, 2017

(30) Foreign Application Priority Data
Aug. 4, 2014 (JP) 2014-158754

(51) Int. Cl. H01L 51/52; C08G 61/12; C09K 11/06; H01L 51/00; C07F 15/00

(52) U.S. Cl. CPC H01L 51/5237; H01L 51/0007; H01L 51/5284; H01L 51/0039; H01L 51/0043; H01L 51/0085; C07F 15/0033; C09K 11/06; C08G 61/128; H01L 51/5016

(57) ABSTRACT

A problem to be solved of the invention is to provide a package of a liquid composition for an organic electroluminescent device including a phosphorescent material and a solvent with extended storage lifetime, which may be produced with high working efficiency. A solving means of the problem is a package of a liquid composition for an organic electroluminescent device having a liquid composition for an organic electroluminescent device including a phosphorescent material and a solvent, and a container that contains the liquid composition for an organic electroluminescent device, wherein the package of a liquid composition for an organic electroluminescent device has a transmittance of light, that is a wavelength component of from 500 nm to 780 nm, from outside of the package to inside of the container of 15% or less.

### TECHNICAL FIELD

The present invention relates to a liquid composition for an organic electroluminescent device, and particularly, relates to a liquid composition for an organic electroluminescent device including a phosphorescent material and a solvent.

### BACKGROUND ART

An organic electroluminescent device (hereinafter, also referred to as a “light emitting device”) has a high light emitting efficiency and a low driving voltage, thus may be suitably used for a display, and research and development are actively conducted. The light emitting device comprises organic layers such as a light emitting layer, a charge transporting layer. In the formation of the organic layer, there are a case where a small molecule compound is used and a case where a polymer compound is used. When a polymer compound is used, it becomes possible to form the organic layer by a coating method represented by an inkjet printing method. Therefore, a polymer compound available for manufacturing light emitting devices has been studied. Also, in recent years, a small molecule compound which is soluble to an organic solvent and used for manufacture of light emitting devices has been studied.

For the manufacture of light emitting devices by a coating method, a liquid composition for an organic electroluminescent device including an organic luminescent material and a solvent is used. The liquid composition for an organic electroluminescent device is generally poor in storage stability, and it is known that the function is lowered especially when exposed to light.

For example, Patent Document 1 describes a method for producing a coating liquid for a light emitting device for the purpose of improving device properties such as device lifetime. The method prepares the liquid under an environment in which a light with wavelength of shorter than the maximum absorption wavelength of a light emitting material, specifically, a light with a wavelength of 500 nm or less is shaded. Patent Document 2 describes a method for storing a liquid composition for an organic semiconductor device for the purpose of preventing functional degradation of a liquid composition for forming an organic semiconductor device. The method shades a light with a wavelength of 380 nm or less.

Patent Document 3 describes a method for manufacturing an organic electroluminescence device in a dark place, and a method for manufacturing an organic electroluminescence device in a dark place by using a solution prepared and stored in a dark place. Patent Document 4 describes a method for manufacturing a device in which the method defines “illuminance×time” of a phosphorescent polymer compound exposed to a light consisting of a wavelength component of less than 500 nm.

However, production, liquid preparation and film formation of the liquid composition for an organic electroluminescent device in a dark place cause a problem in workability and increased production cost. In addition, the storage stability of a liquid composition for an organic electroluminescent device including a phosphorescent material and a solvent is still insufficient, even when the light with wavelength shorter than the maximum absorption wavelength of the phosphorescent material is shaded.

Particularly, in an event that a liquid composition for an organic electroluminescent device includes a polymer compound having an aryl moiety, and includes as a solvent an aromatic hydrocarbon or aromatic ether, the polymer compound being highly soluble in the solvents, a peroxide and an oxidation reaction product are generated or accumulated in the liquid composition, thus the liquid composition is likely to be deteriorated. Furthermore, when the phosphorescent material includes iridium, iridium promotes a production reaction of a peroxide, thus degradation of performance of the phosphorescent material is likely to occur.

### BACKGROUND ART DOCUMENTS

### Patent Documents

Patent Document 1: Japanese Patent Laid-Open Publication No. 2004-55333

Patent Document 2: Japanese Patent Laid-Open Publication No. 2011-165658

Patent Document 3: Japanese Patent Laid-Open Publication No. 2011-181498

Patent Document 4: Japanese Patent Laid-Open Publication No. 2007-165605

### SUMMARY OF THE INVENTION

### Problems to be Solved by the Invention

The present invention solves the conventional problems described above, and an object thereof is to provide a package of a liquid composition for an organic electroluminescent device including a phosphorescent material and a solvent with extended storage lifetime, which is able to be produced in high working efficiency.

### Means for Solving the Problems

The present invention provides a package of a liquid composition for an organic electroluminescent device having a liquid composition for an organic electroluminescent device including a phosphorescent material and a solvent, and a container that contains the liquid composition for an organic electroluminescent device, wherein the package of a liquid composition for an organic electroluminescent device has a transmittance of light, that is a wavelength component of from 500 nm to 780 nm, from outside of the package to inside of the container of 15% or less.

In one embodiment, the package of a liquid composition for an organic electroluminescent device of the present invention has a wrapping material that covers the container.

In one embodiment, the container has a light-transmitting part, and the wrapping material covers at least the light-transmitting part of the container.

In one embodiment, the phosphorescent material is a compound represented by formula (11):

[Chemical Formula 1]

M(L)ₖₐ(Z)_{kb} (11)

In the formula, M represents ruthenium, rhodium, palladium, osmium, iridium or platinum, L represents a neutral or monovalent to trivalent anionic ligand that may multidentately coordinate by forming at least two bonds selected from the group consisting of a coordinate bond and a covalent bond with the metal atom represented by M, Z represents a counter anion, ka represents an integer of 1 or more, and kb represents an integer of 0 or more. When there are a plurality of Ls, they may be the same or different from each other, and when there are a plurality of Zs, they may be the same or different from each other.

In one embodiment, the phosphorescent material is a polymer compound having a constitutional unit derived from formula (11).

In one embodiment, M in formula (11) is iridium.

In one embodiment, L in formula (11) is a monoanionic ortho-metallized ligand.

In one embodiment, the liquid composition for an organic electroluminescent device further includes an organic compound which is solid at 1 atm and 25° C.

In one embodiment, the organic compound is a polymer compound.

In one embodiment, the solvent is an aromatic hydrocarbon, an aromatic ether or a mixed solvent of an aromatic hydrocarbon and an aromatic ether.

In one embodiment, the liquid composition for an organic electroluminescent device has a product of an illuminance E (lm/m²) of the light, that is a wavelength component of from 500 nm to 780 nm, to which the liquid composition has been exposed, and an irradiation time t (sec) of the light, to which the liquid composition has been exposed, of 4.8×10⁷ (sec·lm/m²) or less.

In one embodiment, in the package of a liquid composition for an organic electroluminescent device, a part or the whole of a package part has a transmittance of light having a wavelength component of from 500 nm to 780 nm of 1% or more.

### Effect of the Invention

According to the present invention, a package of a liquid composition for an organic electroluminescent device including a phosphorescent material and a solvent with extended storage lifetime, which is able to be produced in high working efficiency is provided.

### EMBODIMENTS FOR CARRYING OUT THE INVENTION

### <Explanation of Common Terms>

Hereinafter, terms commonly used in the present specification have the following meanings unless otherwise stated.

Me represents a methyl group, Et represents an ethyl group, Bu represents a butyl group, i-Pr represents an isopropyl group, and t-Bu represents a tert-butyl group.

In the present specification, a hydrogen atom may be a deuterium atom or a light hydrogen atom.

“Polymer compound” denotes a polymer having molecular weight distribution and having a polystyrene-equivalent number average molecular weight of from 1×10³ to 1×10⁸. The total amount of constitutional units included in the polymer compound is 100% by mol.

The polymer compound may be any of a block copolymer, a random copolymer, an alternate copolymer and a graft copolymer, and may also be another embodiment.

An end group of a polymer compound is preferably a stable group. If a polymerization active group remains intact at the end, and the polymer compound is used for manufacture of a light emitting device, the light emitting properties or luminance lifetime may decrease. This end group is preferably a group having a conjugated bond to the main chain, and includes groups bonding to an aryl group or a monovalent heterocyclic group via a carbon-carbon bond.

“Small molecule compound” denotes a compound having no molecular weight distribution and having a molecular weight of 1×10⁴ or less.

“Constitutional unit” denotes a unit found one or more in a polymer compound.

An “alkyl group” may be any of linear, branched or cyclic. The number of carbon atoms of a linear alkyl group is, not including the number of carbon atoms of a substituent, usually from 1 to 50, preferably from 3 to 30 and more preferably from 4 to 20. The number of carbon atoms of a branched or cyclic alkyl group is, not including the number of carbon atoms of a substituent, usually from 3 to 50, preferably from 3 to 30 and more preferably from 4 to 20.

The alkyl group may have a substituent, and examples thereof include non-substituted alkyl groups such as a methyl group, an ethyl group, an n-propyl group, an isopropyl group, an n-butyl group, an isobutyl group, a tert-butyl group, an n-pentyl group, an isoamyl group, 2-ethylbutyl group, an n-hexyl group, a cyclohexyl group, an n-heptyl group, a cyclohexylmethyl group, a cyclohexylethyl group, an n-octyl group, a 2-ethylhexyl group, a 3-n-propylheptyl group, an n-decyl group, a 3,7-dimethyloctyl group, a 2-ethyloctyl group, a 2-n-hexyldecyl group and an n-dodecyl group; and substituted alkyl groups such as a trifluoromethyl group, a pentafluoroethyl group, a perfluorobutyl group, a perfluorohexyl group, a perfluorooctyl group, a 3-phenylpropyl group, a 3-(4-methylphenyl)propyl group, a 3-(3,5-di-n-hexylphenyl) propyl group and a 6-ethyloxyhexyl group.

“Aryl group” denotes an atomic group that remains after removing one hydrogen atom linked directly to a carbon atom, that constitutes the ring, from an aromatic hydrocarbon. The number of carbon atoms of the aryl group is, not including the number of carbon atoms of a substituent, usually from 6 to 60, preferably from 6 to 20 and more preferably from 6 to 10.

The aryl group may have a substituent, and examples thereof include a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, a 4-phenylphenyl group, and groups obtained by substituting a hydrogen atom in these groups with an alkyl group, an alkoxy group, an aryl group, a fluorine atom.

An “alkoxy group” may be any of linear, branched or cyclic. The number of carbon atoms of a linear alkoxy group is, not including the number of carbon atoms of a substituent, usually from 1 to 40, and preferably from 4 to 10. The number of carbon atoms of a branched or cyclic alkoxy group is, not including the number of carbon atoms of a substituent, usually from 3 to 40, and preferably from 4 to 10.

The alkoxy group may have a substituent, and examples thereof include a methoxy group, an ethoxy group, an n-propyloxy group, an isopropyloxy group, an n-butyloxy group, an isobutyloxy group, a tert-butyloxy group, an n-pentyloxy group, an n-hexyloxy group, a cyclohexyloxy group, an n-heptyloxy group, an n-octyloxy group, a 2-ethylhexyloxy group, an n-nonyloxy group, an n-decyloxy group, a 3,7-dimethyloctyloxy group and a lauryloxy group.

The number of carbon atoms of an “aryloxy group” is, not including the number of carbon atoms of a substituent, usually from 6 to 60, and preferably from 7 to 48.

The aryloxy group may have a substituent, and examples thereof include a phenoxy group, a 1-naphthyloxy group, a 2-naphthyloxy group, a 1-anthracenyloxy group, a 9-anthracenyloxy group, a 1-pyrenyloxy group, and groups obtained by substituting a hydrogen atom in these groups with an alkyl group, an alkoxy group, a fluorine atom.

“p-Valent heterocyclic group” (p represents an integer of 1 or more) denotes an atomic group that remains after removing p hydrogen atoms among hydrogen atoms directly linked to a carbon atom or a hetero atom that constitutes the ring of a heterocyclic compound. Among the p-valent heterocyclic groups, a “p-valent aromatic heterocyclic group”, that is an atomic group that remains after removing p hydrogen atoms among hydrogen atoms directly linked to a carbon atom or a hetero atom that constitutes the ring of an aromatic heterocyclic compound, is preferable.

“Aromatic heterocyclic compound” denotes a compound in which the heterocyclic ring itself shows aromaticity, such as oxadiazole, thiadiazole, thiazole, oxazole, thiophene, pyrrole, phosphole, furan, pyridine, pyrazine, pyrimidine, triazine, pyridazine, quinoline, isoquinoline, carbazole, dibenzosilole, dibenzophosphole, and a compound in which an aromatic ring is condensed to the heterocyclic ring even if the heterocyclic ring itself shows no aromaticity, such as phenoxazine, phenothiazine, dibenzoborole, dibenzosilole, benzopyran.

The number of carbon atoms of the monovalent heterocyclic group is, not including the number of carbon atoms of a substituent, usually from 2 to 60, and preferably from 4 to 20.

The monovalent heterocyclic group may have a substituent, and examples thereof include a thienyl group, a pyrrolyl group, a furyl group, a pyridyl group, a piperidyl group, a quinolyl group, an isoquinolyl group, a pyrimidyl group, a triazinyl group, and groups obtained by substituting a hydrogen atom in these groups with an alkyl group, an alkoxy group.

“Halogen atom” refers to a fluorine atom, a chlorine atom, a bromine atom or an iodine atom.

An “amino group” may have a substituent, and is preferably a substituted amino group. A substituent of the amino group is preferably an alkyl group, an aryl group or a monovalent heterocyclic group.

The substituted amino group includes, for example, a dialkylamino group and a diarylamino group.

The amino group includes, for example, a dimethylamino group, a diethylamino group, a diphenylamino group, a bis(4-methylphenyl)amino group, a bis(4-tert-butylphenyl)amino group and a bis(3,5-di-tert-butylphenyl)amino group.

An “alkenyl group” may be any of linear, branched or cyclic. The number of carbon atoms of a linear alkenyl group, not including the number of carbon atoms of a substituent, is usually from 2 to 30, and preferably from 3 to 20. The number of carbon atoms of a branched or cyclic alkenyl group, not including the number of carbon atoms of a substituent, is usually from 3 to 30, and preferably from 4 to 20.

The alkenyl group may have a substituent, and examples thereof include a vinyl group, a 1-propenyl group, a 2-propenyl group, a 2-butenyl group, a 3-butenyl group, a 3-pentenyl group, a 4-pentenyl group, a 1-hexenyl group, a 5-hexenyl group, a 7-octenyl group, and these groups having a substituent.

An “alkynyl group” may be any of linear, branched or cyclic. The number of carbon atoms of the alkynyl group, not including the number of carbon atoms of a substituent, is usually from 2 to 20, and preferably from 3 to 20. The number of carbon atoms of a branched or cyclic alkynyl group, not including the number of carbon atoms of a substituent, is usually from 4 to 30, and preferably from 4 to 20.

The alkynyl group may have a substituent, and examples thereof include an ethynyl group, a 1-propynyl group, a 2-propynyl group, a 2-butynyl group, a 3-butynyl group, a 3-pentynyl group, a 4-pentynyl group, a 1-hexynyl group, a 5-hexynyl group, and these groups having a substituent.

“Arylene group” denotes an atomic group that remains after removing two hydrogen atoms linked directly to carbon atoms, that constitutes the ring, from an aromatic hydrocarbon. The number of carbon atoms of the arylene group is, not including the number of carbon atoms of a substituent, usually from 6 to 60, preferably from 6 to 30, and more preferably from 6 to 18.

The arylene group may have a substituent, and includes, for example, a phenylene group, a naphthalenediyl group, an anthracenediyl group, a phenanthrenediyl group, a dihydrophenanthrenediyl group, a naphthacenediyl group, a fluorenediyl group, a pyrenediyl group, a perylenediyl group, a chrysenediyl group, and these groups having a substituent, and is preferably a group represented by formulae (A-1) to (A-20). The arylene group includes groups obtained by linking a plurality of these groups.

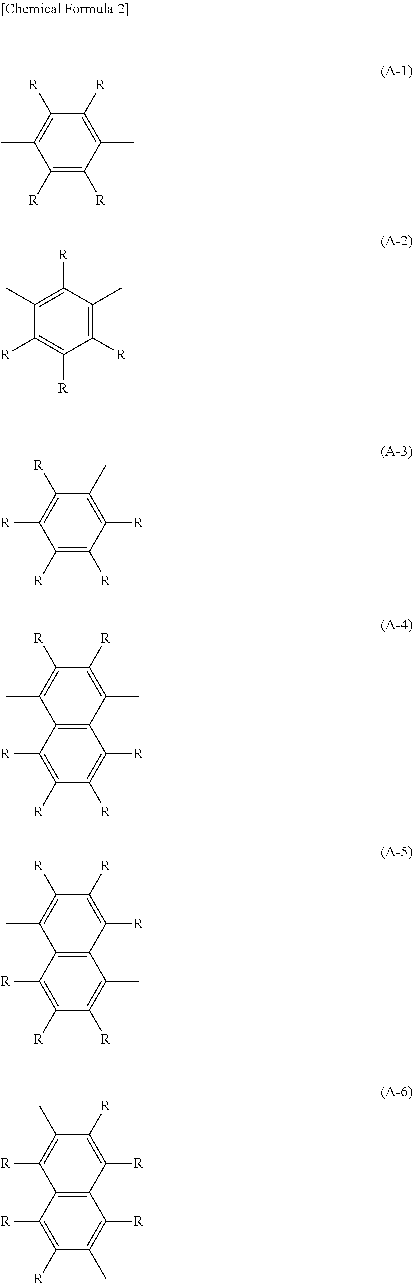

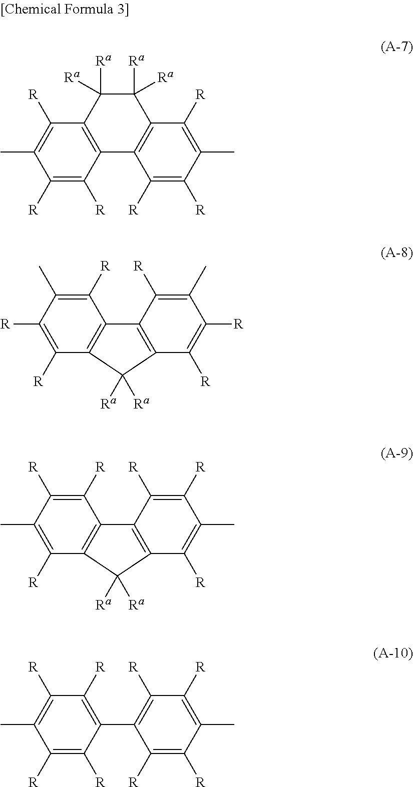

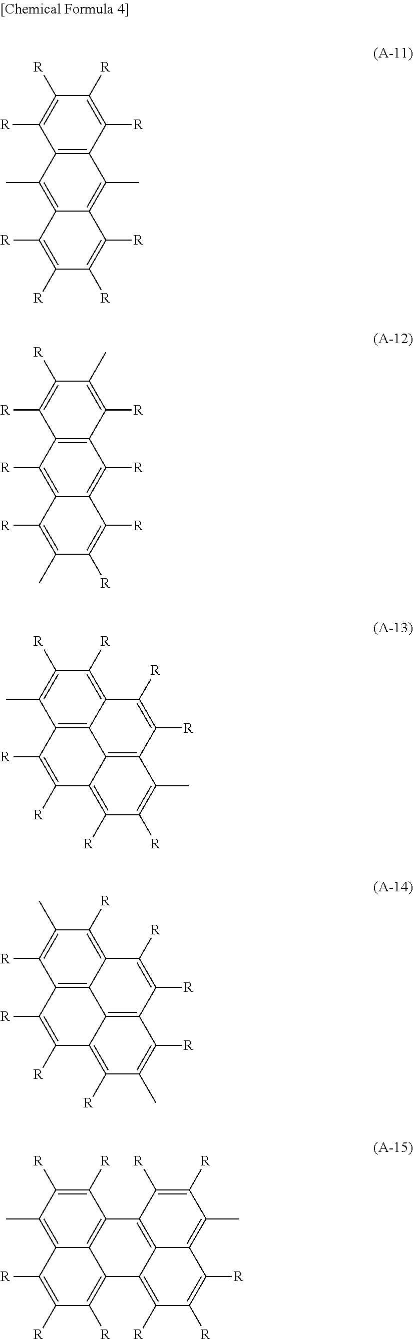

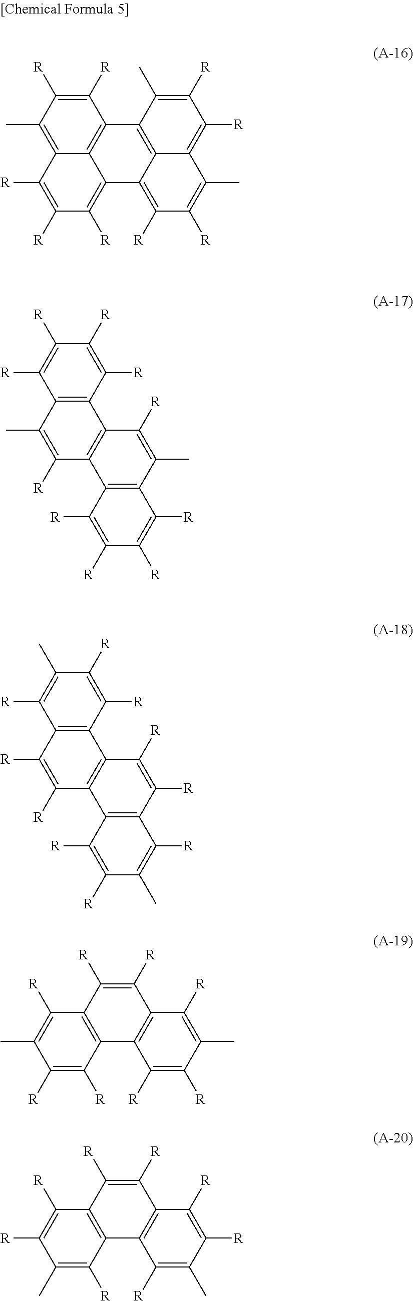

In the formulae, Rs and R^{a}s each independently represent a hydrogen atom, an alkyl group, an aryl group, or a monovalent heterocyclic group. A plurality of Rs and R^{a}s each may be the same or different from each other. R^{a}s may be combined with each other to form a ring together with the carbon atoms with which each of them combines.

The number of carbon atoms of a divalent heterocyclic group is, not including the number of carbon atoms of a substituent, usually from 2 to 60, preferably from 3 to 20, and more preferably from 4 to 15.

The divalent heterocyclic group may have a substituent, and includes, for example, divalent groups obtained by removing two hydrogen atoms among hydrogen atoms linking directly to a carbon atom or a hetero atom constituting the ring, from pyridine, diazabenzene, triazine, azanaphthalene, diazanaphthalene, carbazole, dibenzofuran, dibenzothiophene, dibenzosilole, phenoxazine, phenothiazine, acridine, dihydroacridine, furan, thiophene, azole, diazole and triazole, and is preferably a group represented by formulae (AA-1) to (AA-34). The divalent heterocyclic group includes groups obtained by linking a plurality of these groups.

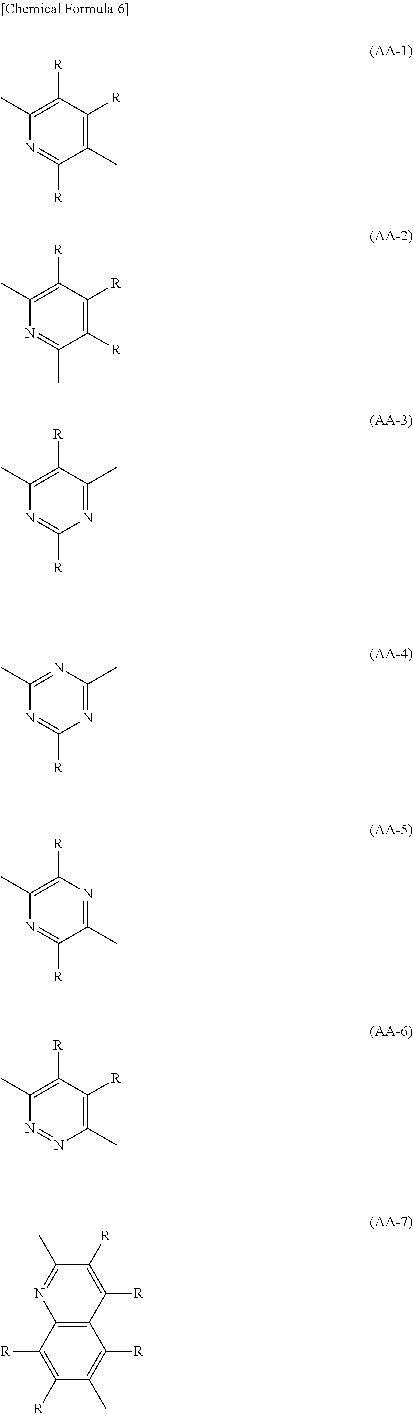

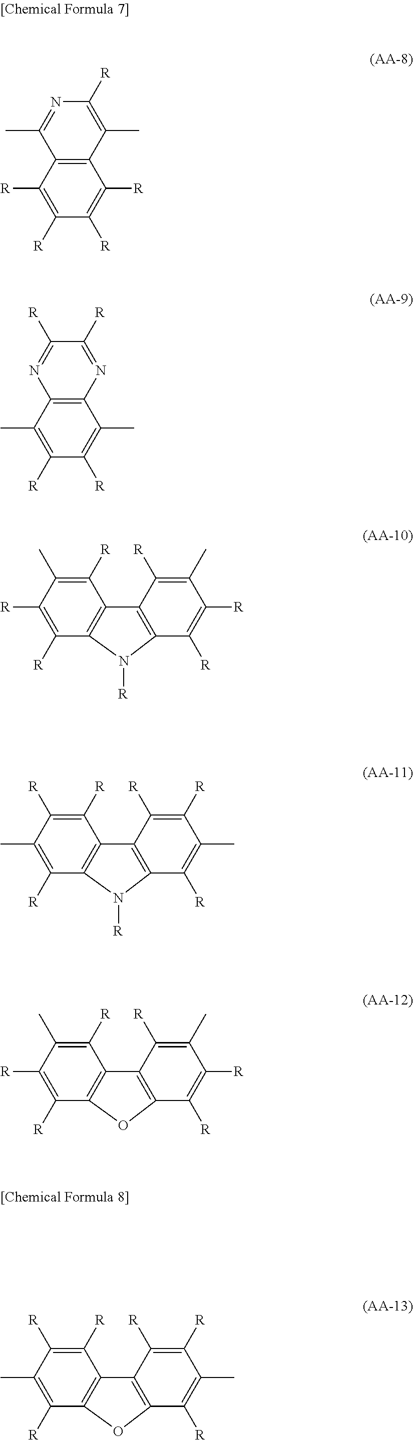

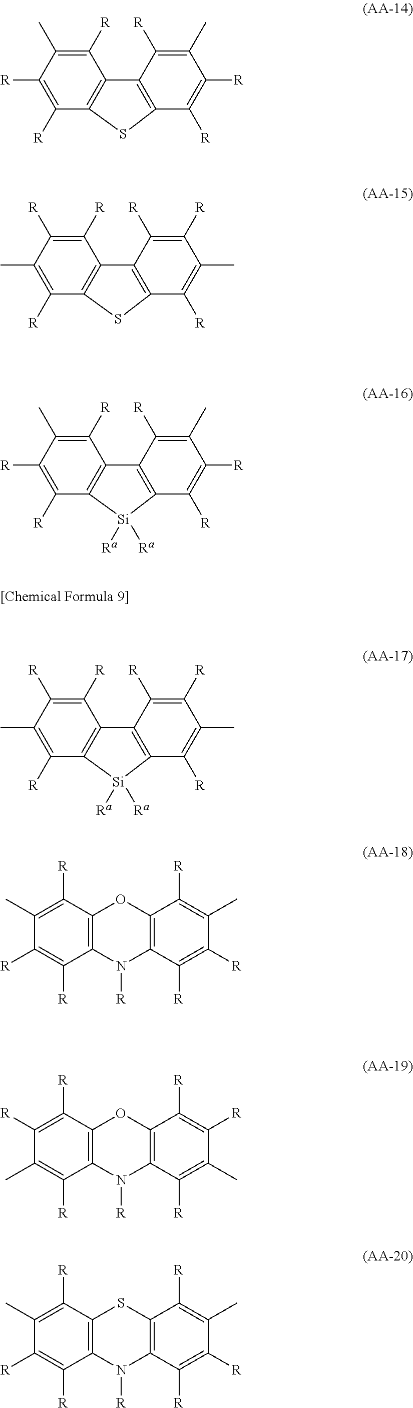

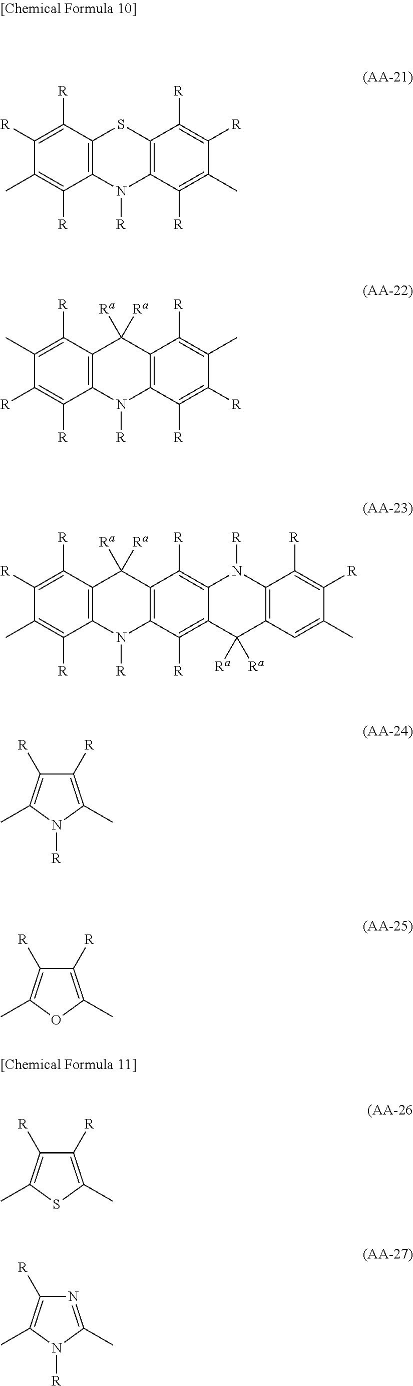

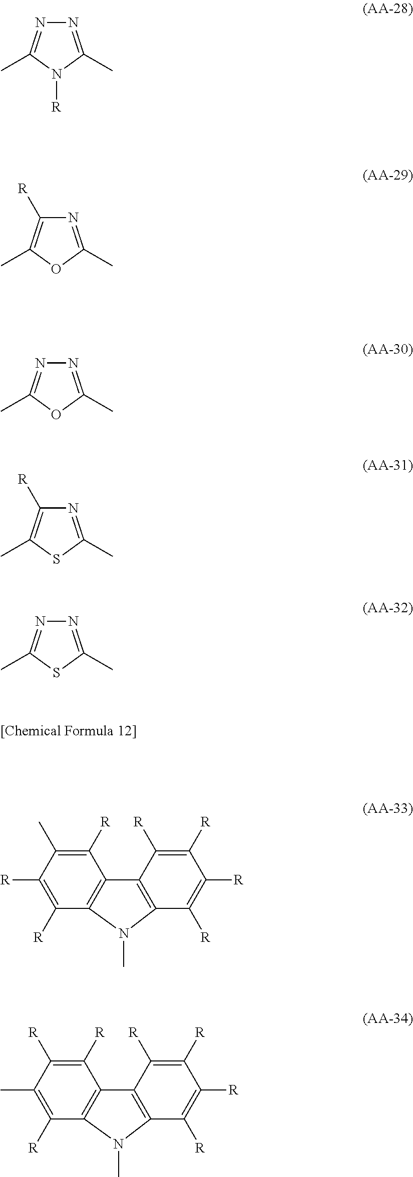

In the formulae, Rs and R^{a}s represent the same meaning as described above.

A “crosslink group” is a group capable of generating a new bond by subjecting it to a heat treatment, an ultraviolet irradiation treatment, a radical reaction, and is preferably a group represented by formula (B-1), (B-2), (B-3), (B-4), (B-5), (B-6), (B-7), (B-8), (B -9), (B-10), (B-11), (B-12), (B-13), (B-14), (B-15), (B-16) or (B-17).

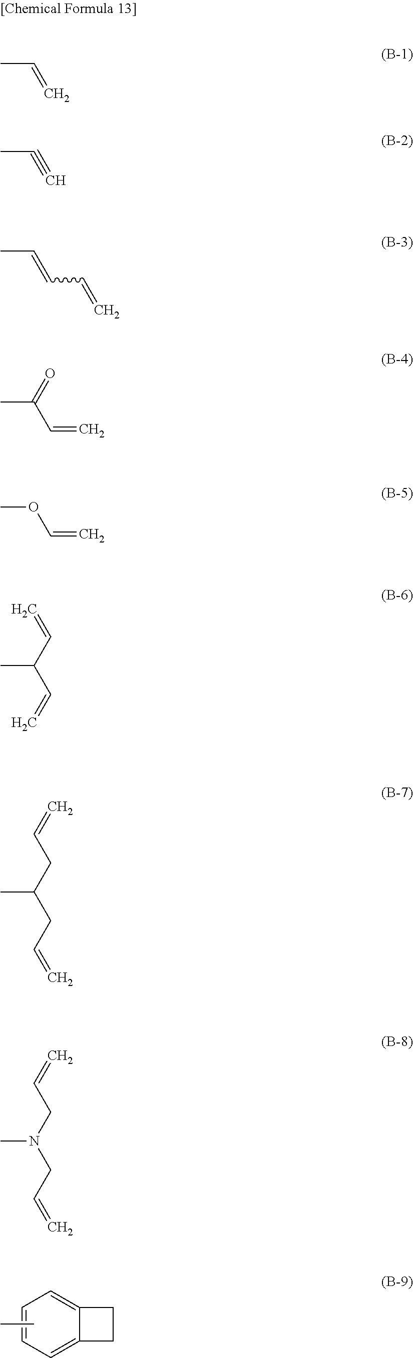

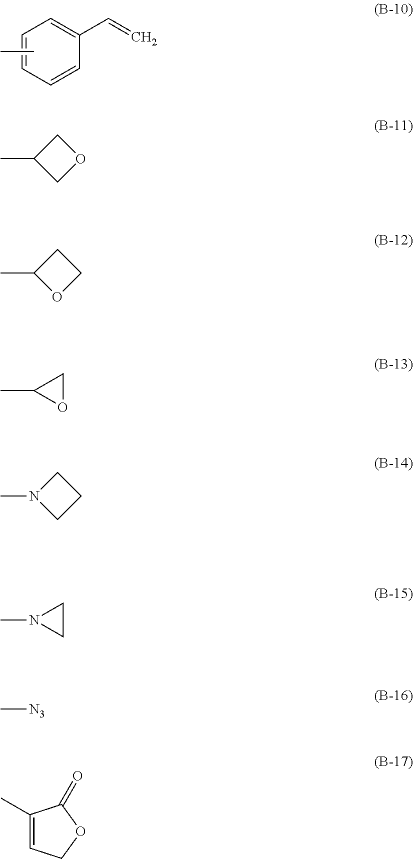

In the formulae, these groups each may have a substituent.

“Substituent” represents a halogen atom, a cyano group, an alkyl group, an aryl group, a monovalent heterocyclic group, an alkoxy group, an aryloxy group, an amino group, a substituted amino group, an alkenyl group or an alkynyl group. The substituent may be a crosslink group.

A “dendron” is a group having a regular dendritic branched structure (a dendrimer structure) having a branching point at an atom or ring. A compound having dendron as a partial structure (called a dendrimer in some cases) includes, for example, structures described in literatures such as WO 02/067343, Japanese Patent Laid-open Publication No. 2003-231692, WO 2003/079736, WO 2006/097717.

The dendron is preferably a group represented by formula (D-A) or (D-B).

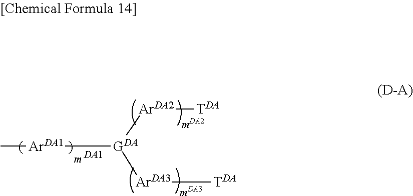

In the formula, m^{DA1}, m^{DA2} and m^{DA3} each independently represent an integer of 0 or more.

G^{DA} represents a nitrogen atom, an aromatic hydrocarbon group or a heterocyclic group, and these groups each may have a substituent.

Ar^{DA1}, Ar^{DA2} and Ar^{DA3} each independently represent an arylene group or a divalent heterocyclic group, and these groups each may have a substituent. When there are a plurality of Ar^{DA1}s, a plurality of Ar^{DA2}s and a plurality of Ar^{DA3}s, each of them may be the same or different from each other.

T^{DA}s represent an aryl group or a monovalent heterocyclic group, and these groups each may have a substituent. A plurality of T^{DA}s may be the same or different from each other.

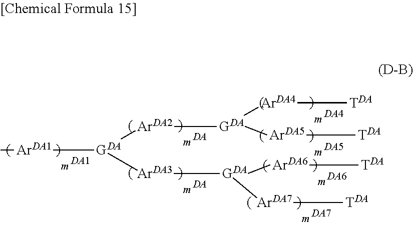

In the formula, m^{DA1}, m^{DA2}, m^{DA3}, m^{DA4}, m^{DA5}, m^{DA6} and m^{DA7} each independently represent an integer of 0 or more.

G^{DA} represents a nitrogen atom, an aromatic hydrocarbon group or a heterocyclic group, and these groups each may have a substituent. A plurality of G^{DA}s may be the same or different from each other.

Ar^{DA1}, Ar^{DA2}, Ar^{DA3}, Ar^{DA4}, Ar^{DA5}, Ar^{DA6} and Ar^{DA7} each independently represent an arylene group or a divalent heterocyclic group, and these groups each may have a substituent. When there are a plurality of Ar^{DA1}s, a plurality Ar^{DA2}s, a plurality of Ar^{DA3}s, a plurality of Ar^{DA4}s, a plurality of Ar^{DA5}s, a plurality of Ar^{DA6}s and a plurality of Ar^{DA7}s, each of them may be the same or different from each other.

T^{DA}s represent an aryl group or a monovalent heterocyclic group, and these groups each may have a substituent. A plurality of T^{DA}s may be the same or different from each other.

m^{DA1}, m^{DA2}, m^{DA3}, m^{DA4}, m^{DA5}, m^{DA6} and m^{DA7} each independently represent usually an integer of 10 or less, preferably an integer of 5 or less, more preferably 0 or 1, and more preferably 0 or 1. Also, it is preferable that m^{DA1}, m^{DA2}, m^{DA3}, m^{DA4}, m^{DA5}, and m^{DA6} and m^{DA7} are the same integer.

G^{DA}s are preferably groups represented by formulae (GDA-11) to (GDA-15), and these groups each may have a substituent.

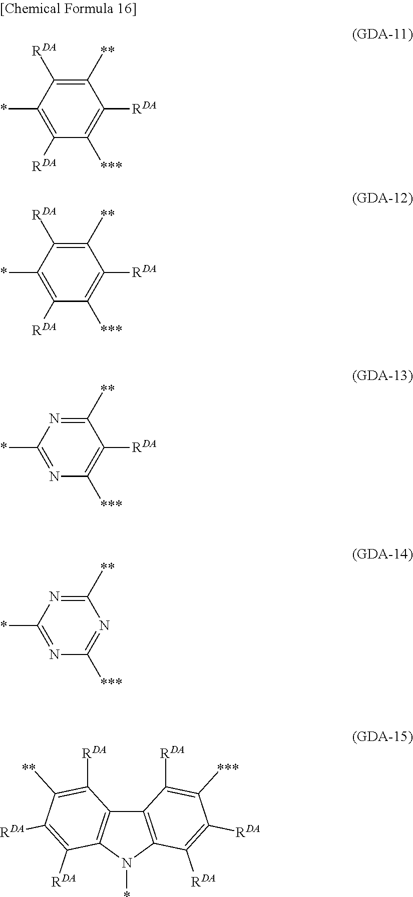

In the formulae, * represents a position linking to Ar^{DA1} in formula (D-A), a position linking to Ar^{DA2} in formula (D-B), or a position linking to Ar^{DA3} in formula (D-B).

** represents a position linking to Ar^{DA2} in formula (D-A), a position linking to Ar^{DA4} in formula (D-B), or a position linking to Ar^{DA6} in formula (D-B).

*** represents a position linking to Ar^{DA3} in formula (D-A), a position linking to Ar^{DA5} in formula (D-B), or a position linking to Ar^{DA7} in formula (D-B).

R^{DA} represents a hydrogen atom, an alkyl group, an alkoxy group, an aryl group or a monovalent heterocyclic group, and these groups further may have a substituent. When there are a plurality of R^{DA}s, they may be the same or different from each other.

R^{DA} is preferably a hydrogen atom, an alkyl group or an alkoxy group, and more preferably a hydrogen atom or an alkyl group, and these groups may have a substituent.

Ar^{DA1}, Ar^{DA2}, Ar^{DA3}, Ar^{DA4}, Ar^{DA5}, Ar^{DA6} and Ar^{DA7} are preferably groups represented by formulae (ArDA-1) to (ArDA-3).

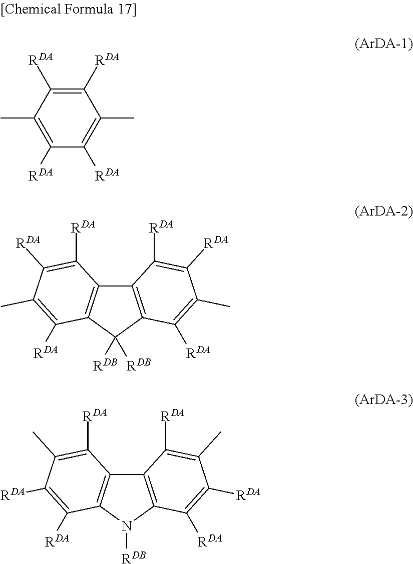

In the formulae, R^{DA}s represent the same meaning as described above.

R^{DB} represents a hydrogen atom, an alkyl group, an aryl group or a monovalent heterocyclic group, and these groups may have a substituent. When there are a plurality of R^{DB}s, they may be the same or different from each other.

R^{DB} is preferably an alkyl group, an aryl group or a monovalent heterocyclic group, more preferably an aryl group or a monovalent heterocyclic group and further preferably an aryl group.

T^{DA}s are preferably groups represented by formulae (TDA-1) to (TDA-3).

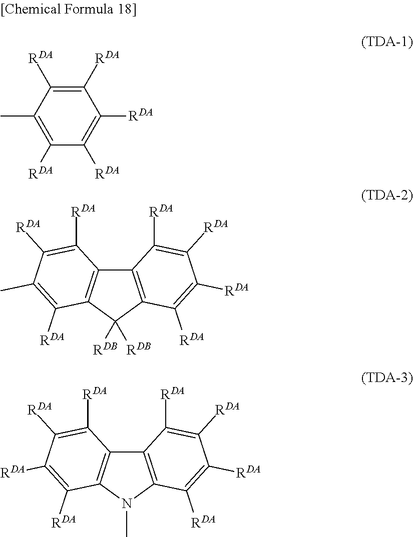

In the formulae, R^{DA}s and R^{DB}s represent the same meaning as described above.

The group represented by formula (D-A) is preferably a group represented by formulae (D-A1) to (D-A3).

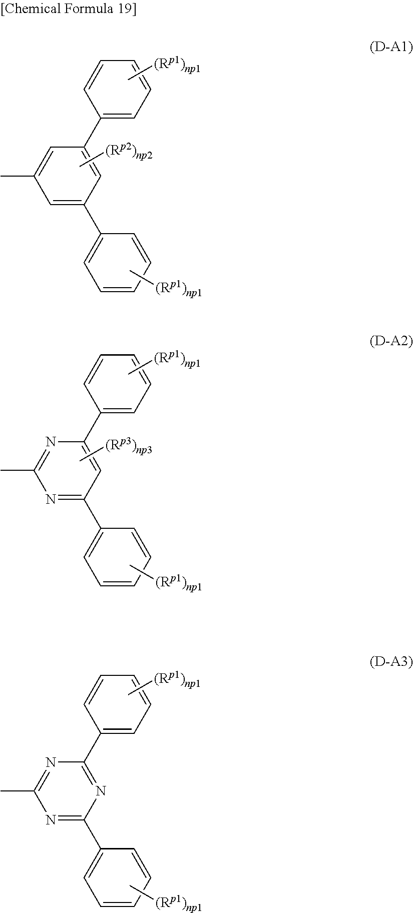

In the formulae, R^{p1}s, R^{p2}s, R^{p3}s each independently represent an alkyl group, an alkoxy group or a halogen atom. When there are a plurality of R^{p1}s and a plurality of R^{p2}s, each of them may be the same of different from each other.

np1s represent an integer of from 0 to 5, np2 represents an integer of from 0 to 3, and np3 represents an integer of 0 or I. A plurality of np1s may be the same or different from each other.

The group represented by formula (D-B) is preferably a group represented by formulae (D-B1) to (D-B3).

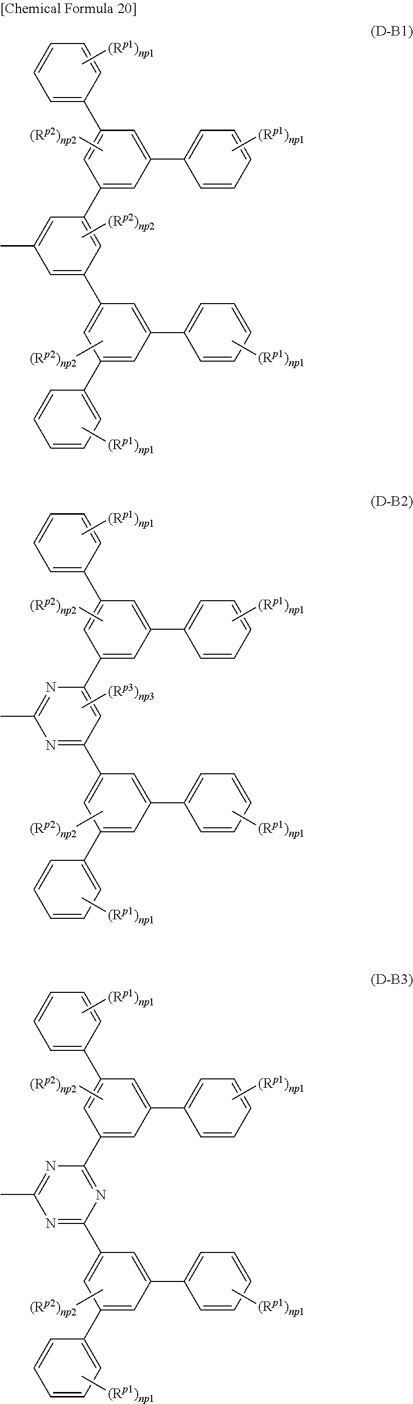

In the formulae, R^{p1}s, R^{p2}s and R^{p3}s each independently represent an alkyl group, an alkoxy group or a halogen atom. When there are a plurality of R^{p1}s and a plurality of R^{p2}s, each of them may be the same or different from each other.

np1s represent an integer of from 0 to 5, np2s represent an integer of from 0 to 3, and np3 represents an integer of 0 or 1. When there are a plurality of np1s and a plurality of np2s, each of them may be the same or different from each other.

np1s are preferably 0 or 1 and more preferably 1. np2s are preferably 0 or 1 and more preferably 0. np3 is preferably 0.

R^{p1}s, R^{p2}s and R^{p3} are preferably alkyl groups.

### <Package of Liquid Composition for Organic Electroluminescent Device>

The package of a liquid composition for an organic electroluminescent device in the present invention refers to an article that has a liquid composition for an organic electroluminescent device and a container containing the same. The container is a tool used for storing and transporting the liquid composition for an organic electroluminescent device.

The package of a liquid composition for an organic electroluminescent device may have a wrapping material that covers the container containing the liquid composition for an organic electroluminescent device. In the package of a liquid composition for an organic electroluminescent device, a part except for the liquid composition for an organic electroluminescent device, which is contained item, herein refers to a “package part”. When the package of a liquid composition for an organic electroluminescent device has a wrapping material covering the container, as described above, the package part of the liquid composition for an organic electroluminescent device has a container and a wrapping material.

When the container that contains the liquid composition for an organic electroluminescent device has a light-transmitting part, it is preferred that the package of a liquid composition for an organic electroluminescent device has a wrapping material covering at least the light-transmitting part of the container.

When the container uses piping in its liquid contact part, specifically, an inner wall of the container, a liquid contact surface of a lid of the container and the container, it is desirable that a contact part of the piping with a liquid composition and packing that may contact the liquid composition are chemically stable to the liquid composition, and are made of a material that does not elute impurities. As such materials, examples include glass, metals such as iron, aluminum, stainless steel, gold, silver and copper, and plastics such as polyethylene, polypropylene, nylon, PEN resins, PES resins and fluororesins. Among them, glass, aluminum, stainless steel, polyethylene and fluororesins are more preferred. When using plastics, the plastics not including an additive are more preferred. The materials exemplified above are sufficiently be used for the surface at the liquid contact part of the container, and the material of the part that does not contact the liquid composition is not particularly limited. The volume of the container body is not particularly restricted, but is usually a volume that may store 2 ml or more of a liquid composition.

In the package of a liquid composition for an organic electroluminescent device of the present invention, the transmittance of a light having wavelength corresponding to yellow from the outside of the package of a liquid composition for an organic electroluminescent device to the inside of the container is 15% or less, and preferably 10% or less. The transmittance of light of 15% or less, and preferably 10 or less, may be achieved by the container alone, or may be achieved by a combination of the container and a wrapping material. The light having wavelength corresponding to yellow is a light having a wavelength component of from 500 nm to 780 nm.

When using the package of a liquid composition for an organic electroluminescent device, it is necessary to visually confirm properties, quality, consumption rate, remaining rate of the liquid composition for an organic electroluminescent device from the outside of the package. Therefore, it is preferred that the package part of the package of a liquid composition for an organic electroluminescent device somewhat transmits a wavelength component of from 500 nm to 780 nm of the light in an environment in which the package of a liquid composition for an organic electroluminescent device is used.

The package of a liquid composition for an organic electroluminescent device is generally used in a clean room. Therefore, light in an environment for performing an operation includes white light from a fluorescent lamp, yellow light. In a preferred embodiment, light in an environment for performing an operation is yellow light.

In the package of a liquid composition for an organic electroluminescent device of the present invention, transmittance of light in a part or the hole of the package part in an environment for performing an operation is preferably 1% or more. Properties, quality of the liquid composition for an organic electroluminescent device may be visually confirmed from the outside of the package, by observing a portion with a transmittance of 1% or more of the package part.

In a preferred embodiment, transmittance of light in a part or the whole of the package part in an environment for performing an operation is 2.5% or more, and more preferably 3% or more.

A material of the wrapping material is not particularly restricted, as long as the material has light shielding properties such that, when combined with the container, transmittance of light having wavelength corresponding to yellow is 15% or less, and preferably 10% or less, and examples thereof include paper, resin bags, metals. Specifically, a corrugated cardboard box, a colored resin bag, a black resin bag, an aluminum-coated bag or a metal may be used. Also, when a container having a certain level of light transmitting properties such as brown glass is used, it is very useful to combinedly use a wrapping material having light shielding properties. Furthermore, several kinds of wrapping materials may be combined for improving light shielding properties and impact resistance.

When a glass container is used as the container, a brown glass container is usually preferred; however, brown glass has the transmittance of light of from about 20 to 30%, thus a wrapping material is combined to achieve a transmittance of 15% or less and preferably 10% or less. In a case of a container made of metal, a wrapping material may not be necessarily combined. In a case of a plastic container, a wrapping material may not be necessarily combined when the plastic is colored and the inside of the container is shaded; however, a plastic container is usually combined with a wrapping material to achieve a transmittance of 15% or less, and preferably 10% or less. Transmittance of light having a wavelength component of from 500 nm to 780 nm from the outside of the package of a liquid composition for an organic electroluminescent device to the inside of the container is more preferably 5% or less. Furthermore, the package of a liquid composition for an organic electroluminescent device of the present invention is preferably a package which blocks light having a wavelength component of 500 nm or less.

In the liquid composition for an organic electroluminescent device contained in the package of the present invention, exposure to the light having wavelength corresponding to yellow is reduced, whereby deterioration is delayed, and storage lifetime, or usable period is extended.

### <Liquid Composition for Organic Electroluminescent Device>

The liquid composition for an organic electroluminescent device contained in the package of the present invention will be described below. The liquid composition for an organic electroluminescent device is a liquid composition used for forming a function layer constituting an organic electroluminescent device. The liquid composition for an organic electroluminescent device includes a phosphorescent material and a solvent.

### <Phosphorescent Material>

Examples of the phosphorescent material include a phosphorescent compound.

As the phosphorescent compound, known compounds such as triplet light emitting complexes may be adopted, and examples include metal complexes disclosed in: Nature, (1998), 395, 151; Appl. Phys. Lett., (1999), 75(1), 4; Proc. SPIE-Int. Soc. Opt. Eng., (2001), 4105 (Organic Light-Emitting Materials and Devices IV), 119; J. Am. Chem. Soc., (2001), 123, 4304; Appl. Phys. Lett., (1997), 71(18), 2596; Syn. Met.,(1998), 94(1), 103; Syn. Met., (1999), 99(2), 1361; Adv. Mater., (1999), 11(10), 852; Inorg. Chem., (2003), 42, 8609; Inorg. Chem., (2004), 43, 6513; Journal of the SID 11/1; 161(2003); WO2002/066552; WO2004/020504; WO2004/020448.

Examples of the metal complex that is a phosphorescent compound include ortho-metallized complexes of which central metal is a transition metal belonging to the fifth period or the sixth period.

Examples of the central metal of the metal complex that is a phosphorescent compound include a metal which is an atom having an atomic number of 50 or more, in which spin-orbit interaction occurs in the complex, and intersystem crossing between a singlet state and a triplet state may occur, and ruthenium, rhodium, palladium, osmium, iridium and platinum are preferred, platinum and iridium are more preferred, and iridium is further preferred.

As the phosphorescent compound, a phosphorescent compound represented by the following general formula (11) is preferred.

[Chemical Formula 21]

M(L)ₖₐ(Z)_{kb} (11)

In the formula, M represents ruthenium, rhodium, palladium, osmium, iridium or platinum, L represents a neutral or monovalent to trivalent anionic ligand that may multidentately coordinate by forming at least two bonds selected from the group consisting of a coordinate bond and a covalent bond with the metal atom represented by M, Z represents a counter anion, ka represents an integer of 1 or more, and kb represents an integer of 0 or more, when there are a plurality of Ls, they may be the same or different from each other, and when there are a plurality of Zs, they may be the same or different from each other.

The phosphorescent compound represented by formula (11) has an atomic value that is neutral as a whole.

In formula (11), M is preferably platinum or iridium, and more preferably iridium. The phosphorescent material is preferably an iridium compound. A phosphorescent material whose central metal is iridium has high phosphorescence efficiency at room temperature, and is advantageous for fabricating a highly efficient light emitting device.

In formula (11), examples of L include a ligand including a nitrogen atom that may link to the metal atom represented by M by a coordinate bond or covalent bond and an oxygen atom that may link to the metal atom represented by M by a coordinate bond or a covalent bond, a ligand including a nitrogen atom that may link to the metal atom represented by M by a coordinate bond or a covalent bond and a carbon atom that may link to the metal atom represented by M by a coordinate bond or a covalent bond, a ligand including two oxygen atoms that may link to the metal atom represented by M by a coordinate bond or a covalent bond, a ligand including two nitrogen atoms that may link to the metal atom represented by M by a coordinate bond, and ligands including a phosphorus atom that may link to the metal atom represented by M by a coordinate bond or a covalent bond and a carbon atom that may link to the metal atom represented by M by a coordinate bond or a covalent bond.

Examples of the ligand including a nitrogen atom that may link to the metal atom represented by M by a coordinate bond or a covalent bond and an oxygen atom that may link to the metal atom represented by M by a coordinate bond or a covalent bond include 8-quinolinol, derivatives of 8-quinolinol, benzoquinolinol and derivatives of benzoquinolinol.

Examples of the ligand including a nitrogen atom that may link to the metal atom represented by M by a coordinate bond or a covalent bond and a carbon atom that may link to the metal atom represented by M by a coordinate bond or a covalent bond include 2-phenyl-pyridine and derivatives of 2-phenyl-pyridine. Examples of the ligand including two oxygen atoms that may link to the metal atom represented by M by a coordinate bond or a covalent bond include acetylacetone and derivatives of acetylacetone. Examples of the ligand including two nitrogen atoms that may link to the metal atom represented by M by a coordinate bond include 2,2′-bipyridyl and derivatives of 2,2′-bipyridyl.

As L, a ligand including a nitrogen atom that may link to the metal atom represented by M by a coordinate bond or a covalent bond and a carbon atom that may link to the metal atom represented by M by a coordinate bond or a covalent bond, and a ligand including two nitrogen atoms that may link to the metal atom represented by M by a coordinate bond are preferred, a monoanionic ortho⁻metallized ligand that is a ligand including a nitrogen atom that may link to the metal atom represented by M by a coordinate bond or a covalent bond and a carbon atom that may link to the metal atom represented by M by a coordinate bond or a covalent bond (hereinafter, also referred to as a “monoanionic ortho-metallized ligand”) and a divalent or trivalent ligand obtained by monoanionic ortho-metallized ligands linked to each other are more preferred, and a monoanionic ortho-metallized ligand that is a ligand including a nitrogen atom that may link to the metal atom represented by M by a coordinate bond or a covalent bond and a carbon atom that may link to the metal atom represented by M by a coordinate bond or a covalent bond is further preferred.

As L in formula (11), one kind may be used alone or two kinds or more may be used in combination. When one kind is used alone, the phosphorescent compound represented by formula (11) becomes a homoleptic complex, and when two kinds or more are used in combination, the phosphorescent compound represented by formula (ii) becomes a heteroleptic complex.

Here, the monoanionic ortho-metallized ligand is exemplified as below.

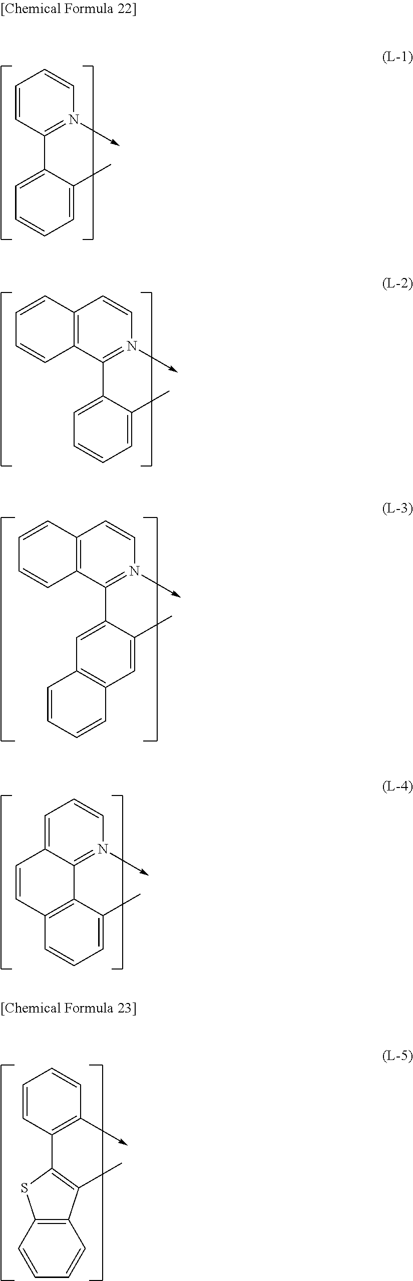

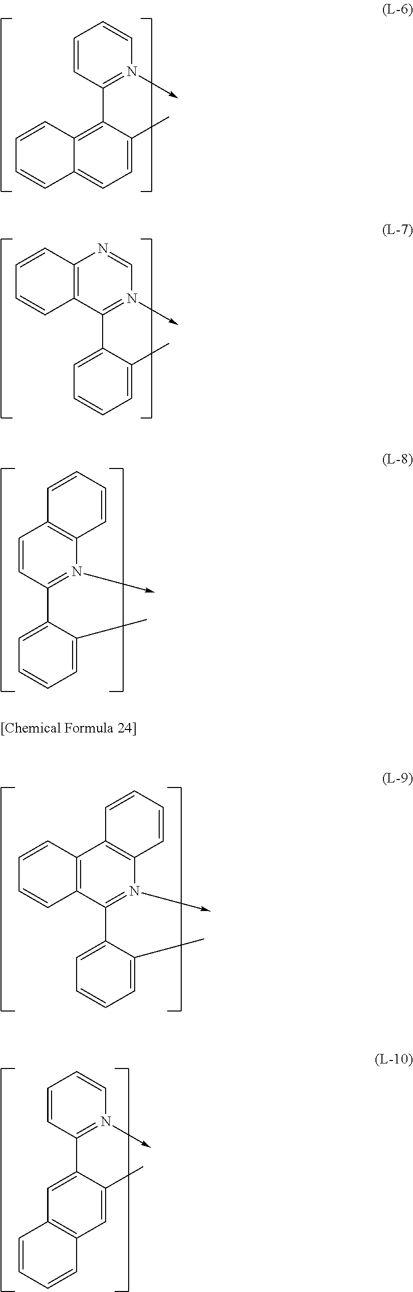

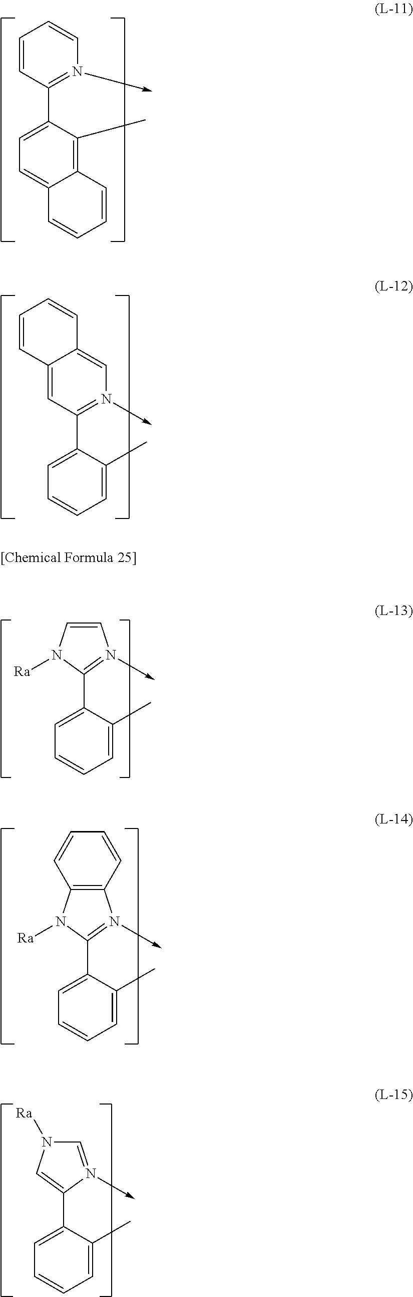

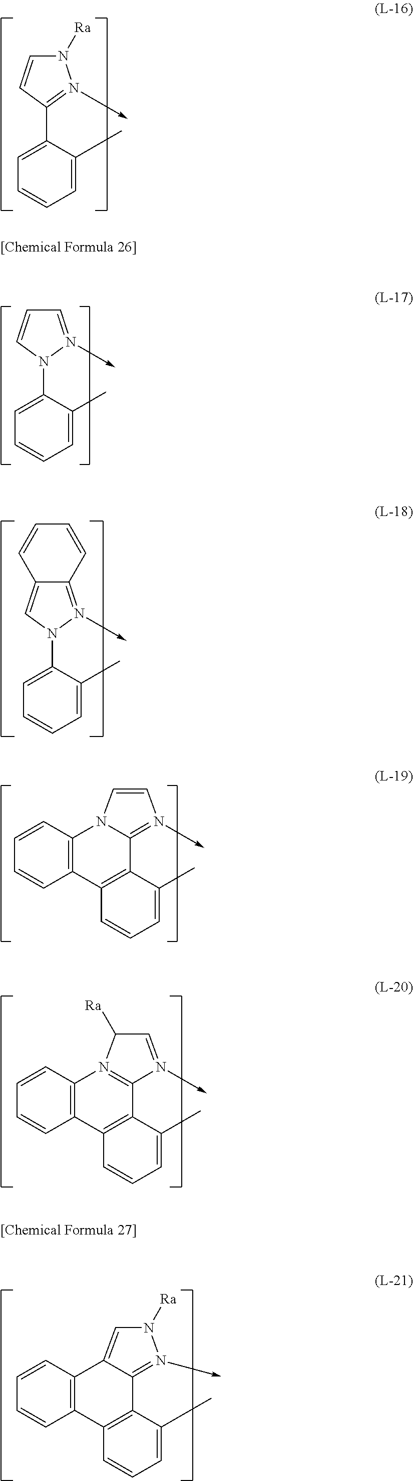

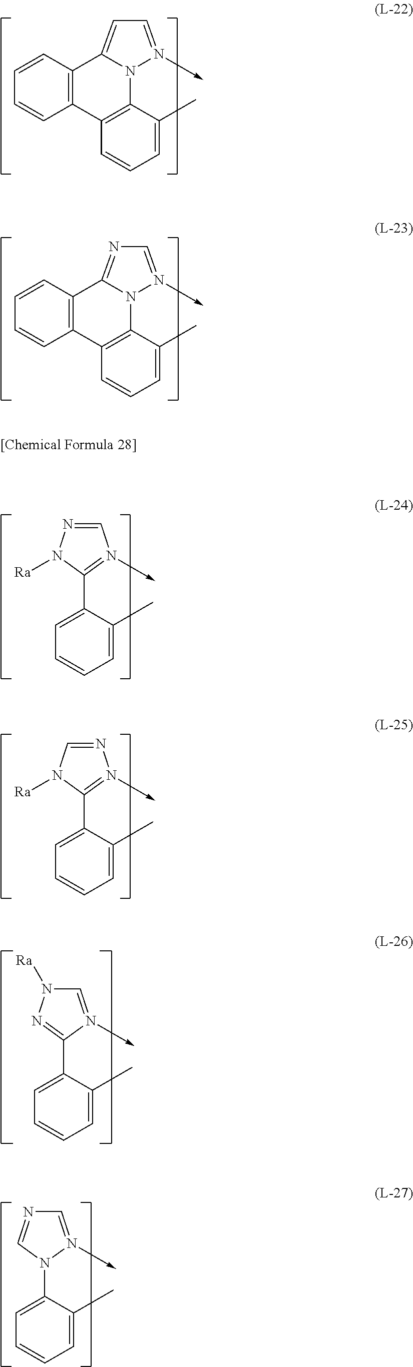

In the formulae, Ra shows an alkyl group, an alkoxy group, an aryl group, an aryloxy group, a monovalent heterocyclic group, a substituted amino group, a substituted carbonyl group, a substituted oxycarbonyl group, a fluorine atom or a cyano group. The arrow shows a coordinate bond.

As Ra, an alkyl group, an alkoxy group, an aryl group and an arylalkyl group are preferred.

The substituted carbonyl group herein means a group obtained by removing a hydroxyl group in a carboxylic acid, and the substituted carbonyl group has the number of carbon atoms of usually from 2 to 20. Specific examples of the acyl group include alkylcarbonyl groups having 2 to 20 carbon atoms that may have been substituted with a fluorine atom such as an acetyl group, a propionyl group, a butyryl group, an isobutyryl group, a pivaloyl group, a trifluoroacetyl group , and phenylcarbonyl groups that may have been substituted with a fluorine atom such as a benzoyl group, a pentafluorobenzoyl group.

The substituted oxycarbonyl group herein means a group obtained by removing a hydrogen atom in a carboxylic acid, and the substituted oxycarbonyl group has the number of carbon atoms of usually from 2 to 20. Specific examples of the acyloxy group include an acetoxy group, a propionyloxy group, a butyryloxy group, an isobutyryloxy group, a pivaloyloxy group, a benzoyloxy group, a trifluoroacetyloxy group and a pentafluorobenzoyloxy group.

An arbitrary hydrogen atom in the monoanionic ortho-metallized ligand exemplified above may have been substituted with an alkyl group, an aryl group, a monovalent aromatic heterocyclic group, an alkoxy group, a substituted amino group, a substituted carbonyl group, a substituted oxycarbonyl group, a fluorine atom or a cyano group. When there are a plurality of substituents, they may be the same or different from each other. They may be combined with each other to form a ring structure together with the atoms with which each of them combines.

Also, as the phosphorescent compound represented by formula (11), those represented by formulae (L-1) to (L-12) are preferred among the monoanionic ortho-metallized ligands exemplified above.

From the viewpoint of solubility in a solvent, it is preferred that ligand L included in the phosphorescent compound includes a substituent that increases solubility in an organic solvent. As the substituent that increases solubility in an organic solvent, an alkyl group, an alkoxy group, an aryl group and a monovalent aromatic heterocyclic group are preferred. The total number of the atoms other than hydrogen atoms of the substituent that increases solubility in an organic solvent is preferably 3 or more, more preferably 5 or more, further preferably 7 or more, and particularly preferably 10 or more. Also, it is preferred that the substituent that increases solubility in an organic solvent is introduced into all ligands of the phosphorescent compound. In this case, the substituent that increases solubility in an organic solvent may be the same or different for each ligand.

As the substituent that increases solubility in an organic solvent, a dendron including one or more kinds of groups selected from the group consisting of an aryl group and a monovalent aromatic heterocyclic group is preferred.

Typical dendrons are exemplified below.

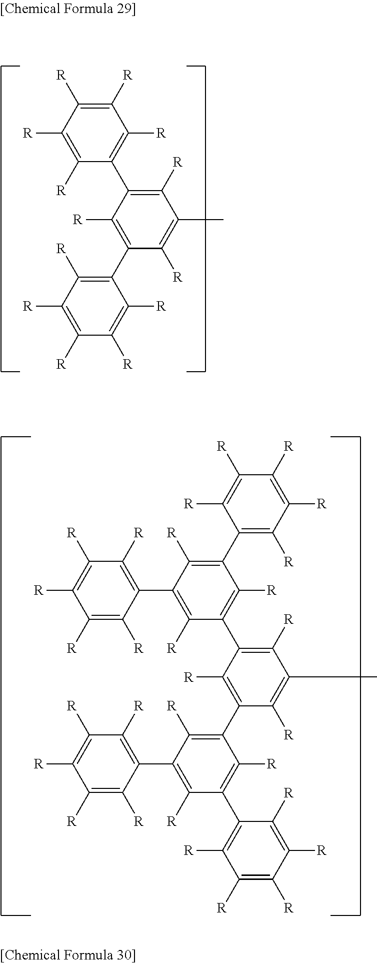

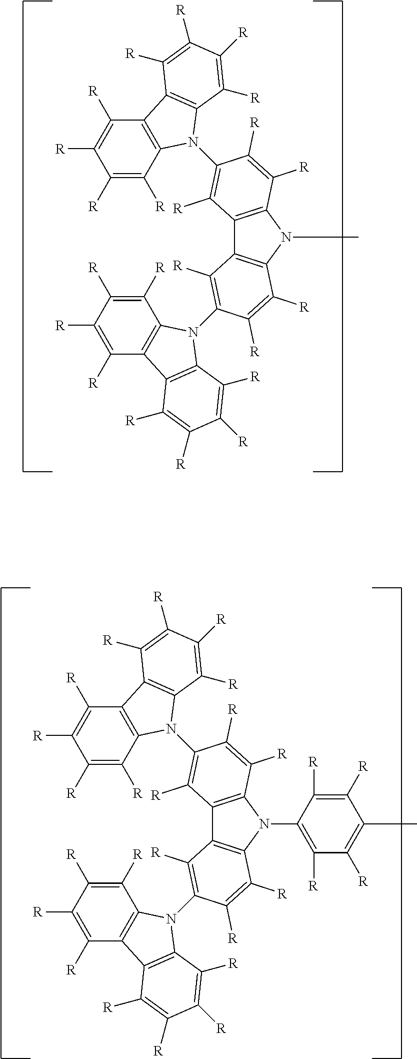

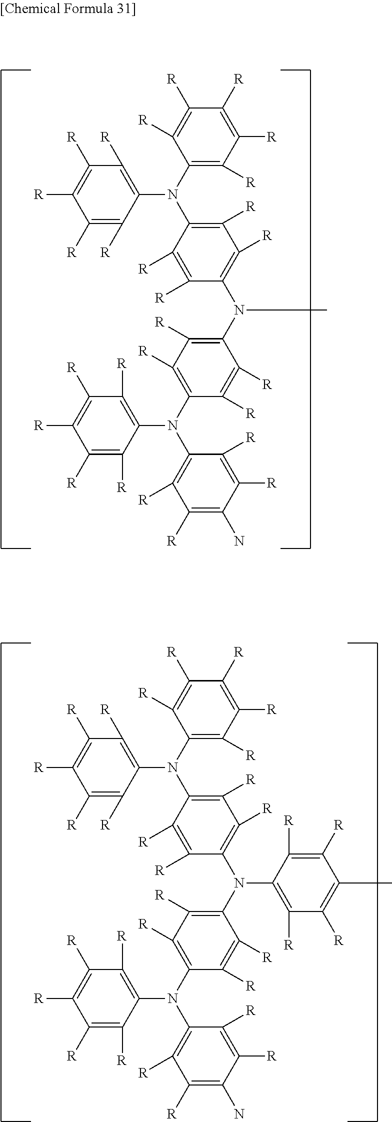

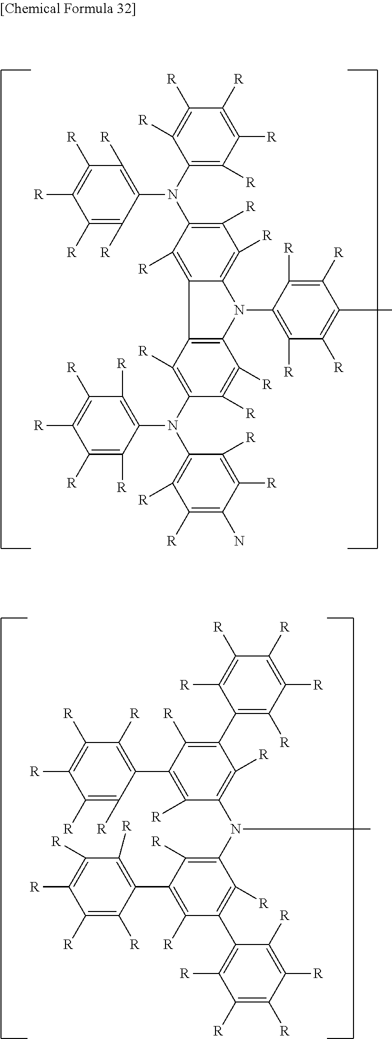

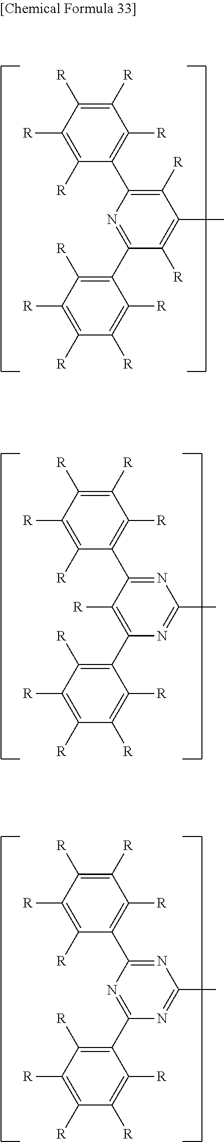

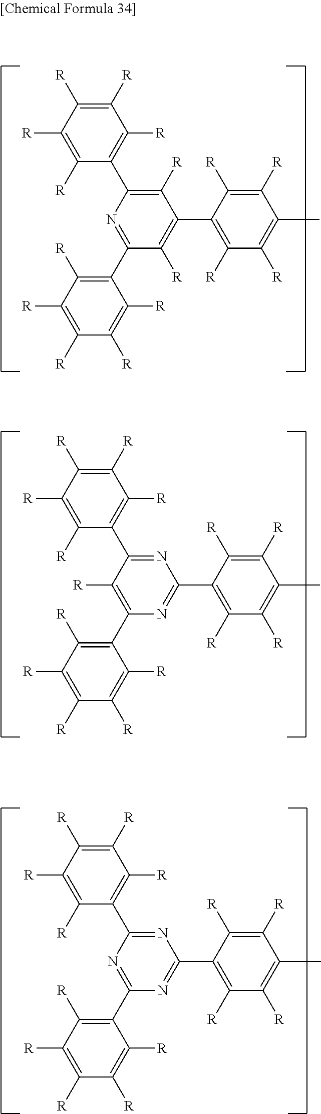

In the formulae, R represents a hydrogen atom, an alkyl group, an alkoxy group, an aryl group, a monovalent aromatic heterocyclic group, a substituted amino group, a substituted carbonyl group, a substituted oxycarbonyl group, a fluorine atom or a cyano group, and two Rs are combined to form a ring structure together with the carbon atoms with which each of them combines. A plurality of Rs may be the same or different from each other.

R is preferably a hydrogen atom, an alkyl group, an aryl group, a monovalent aromatic heterocyclic group or a substituted amino group, and more preferably a hydrogen atom, an alkyl group or an aryl group.

As a ring structure formed by linking two Rs, a cyclopentyl ring that may have been substituted with an alkyl group, a cyclohexyl ring that may have been substituted with an alkyl group and a cycloheptyl ring that may have been substituted with an alkyl group are preferred. Here, the ring structure may further be a fused ring structure fused with a benzene ring or the like.

In formula (11), a counter anion represented by Z includes, for example, a conjugate base of a Bronsted acid. Specific examples of the conjugate base of a Bronsted acid include a fluoride ion, a chloride ion, a bromide ion, an iodide ion, a sulfate ion, a nitrate ion, a carbonate ion, a perchlorate ion, a tetrafluoroborate ion, a tetrakis(pentafluorophenyl)borate ion, a hexafluorophosphate ion, a methanesulfonate ion and a trifluoromethanesulfonate ion.

As the phosphorescent compound represented by formula (11.), a phosphorescent compound in which M is iridium(III), L is a monoanionic ortho-metallized ligand, ka is 3, and kb is 0 is preferred.

As the phosphorescent compound represented by formula (11), the following phosphorescent compounds are exemplified.

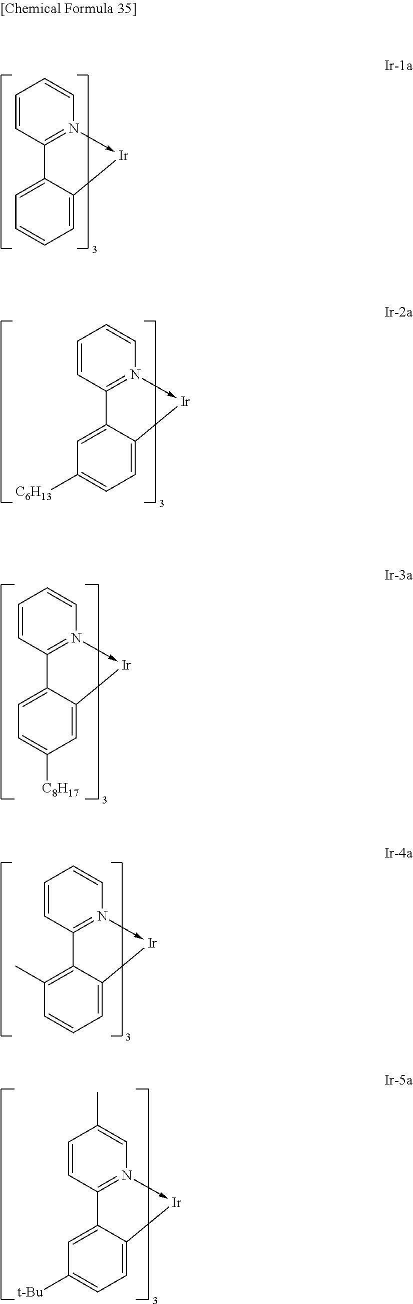

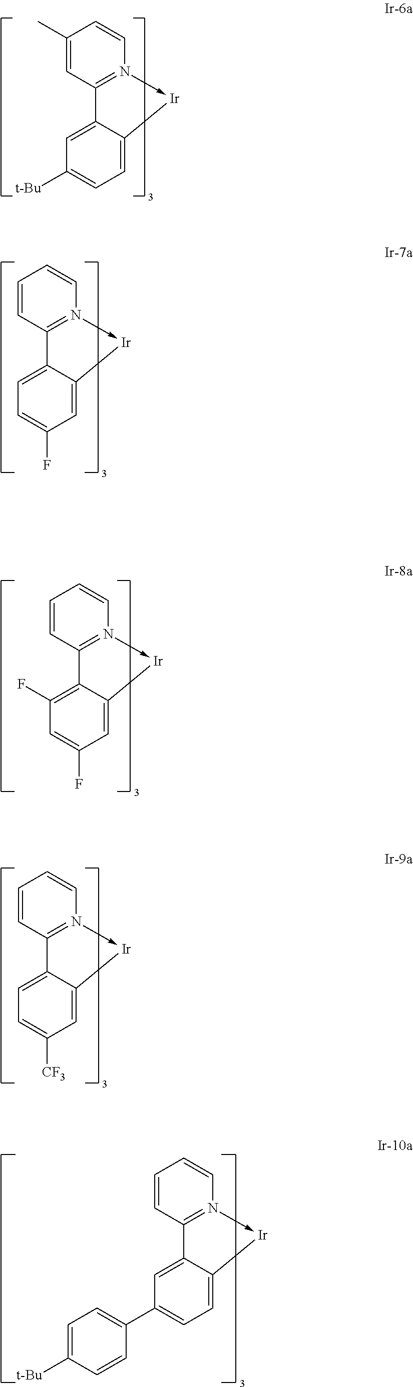

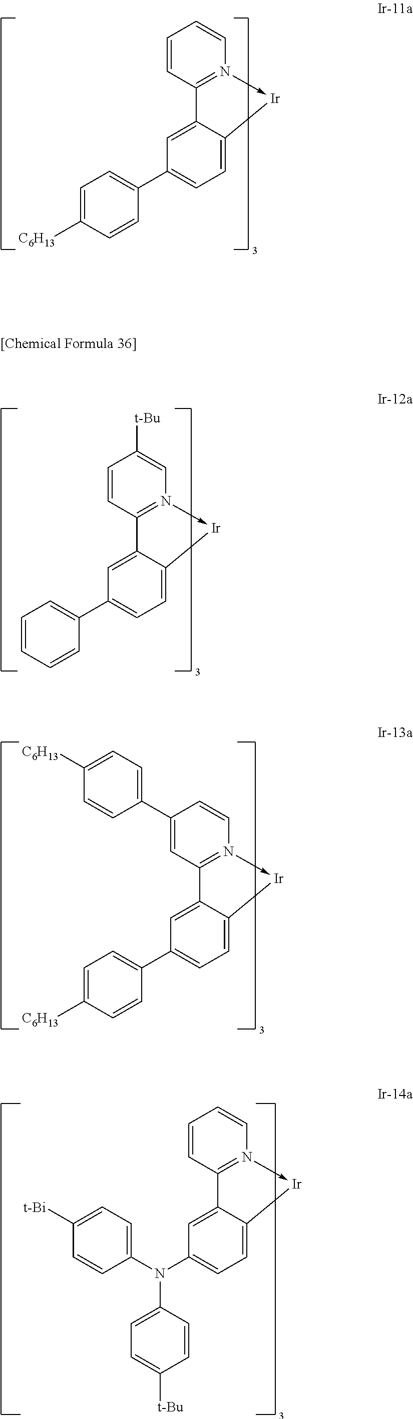

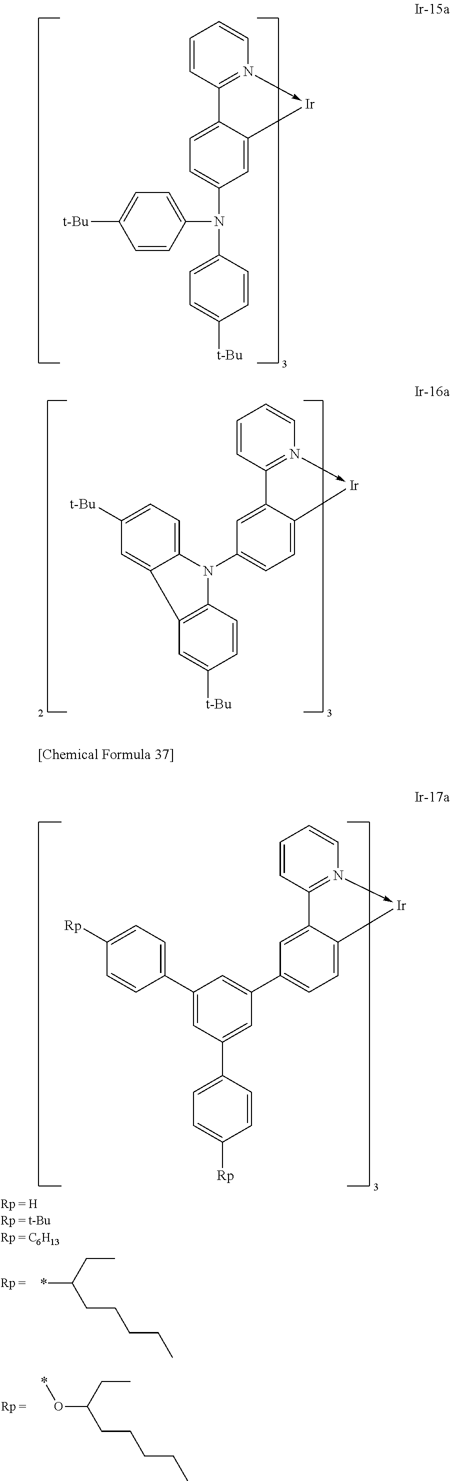

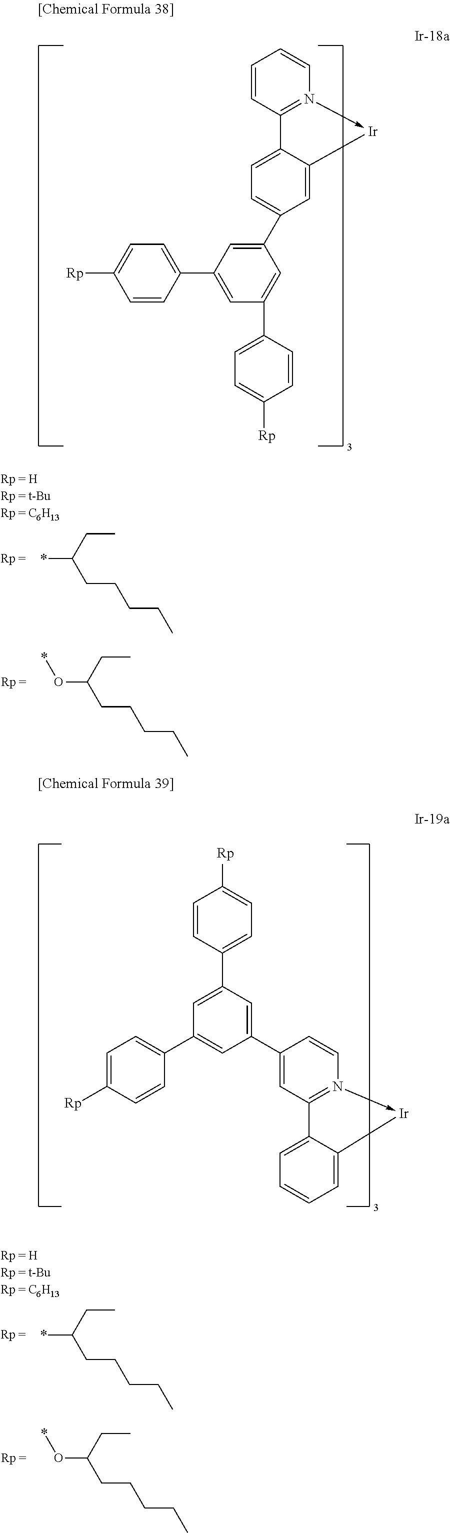

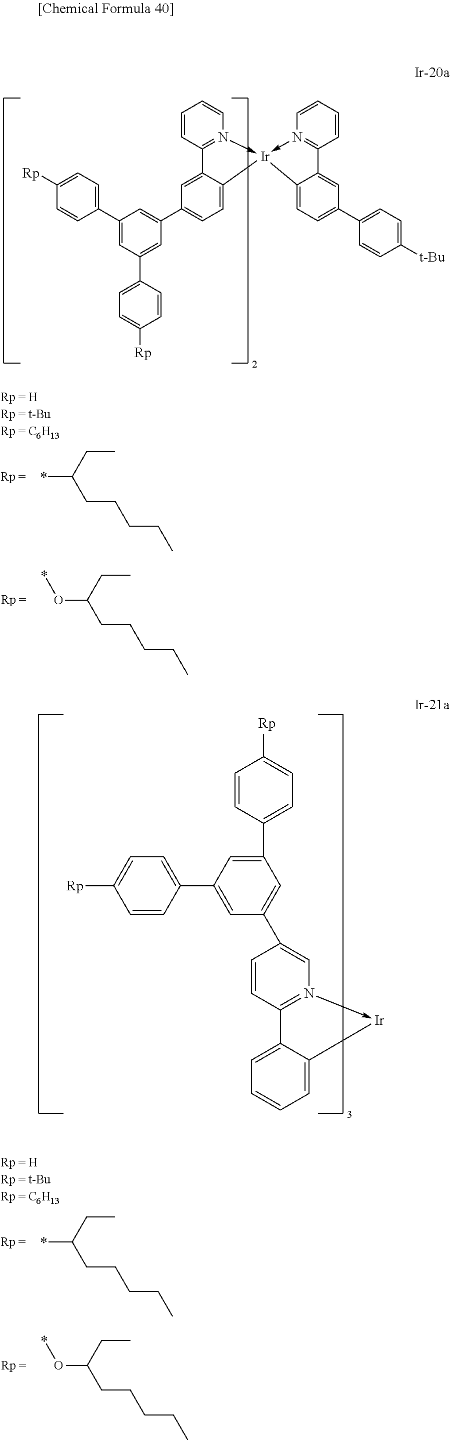

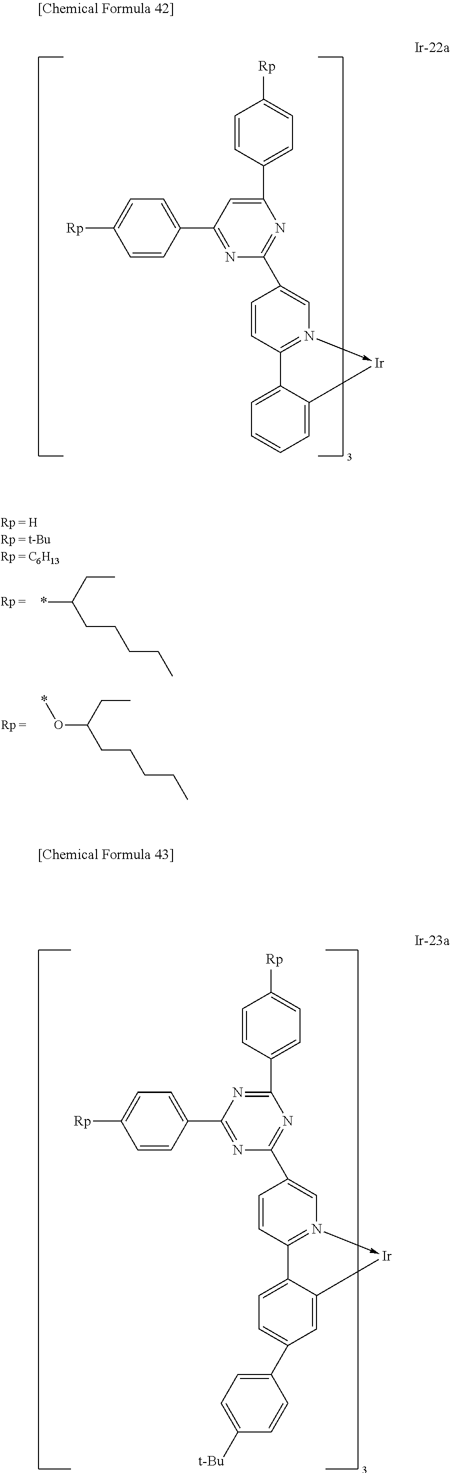

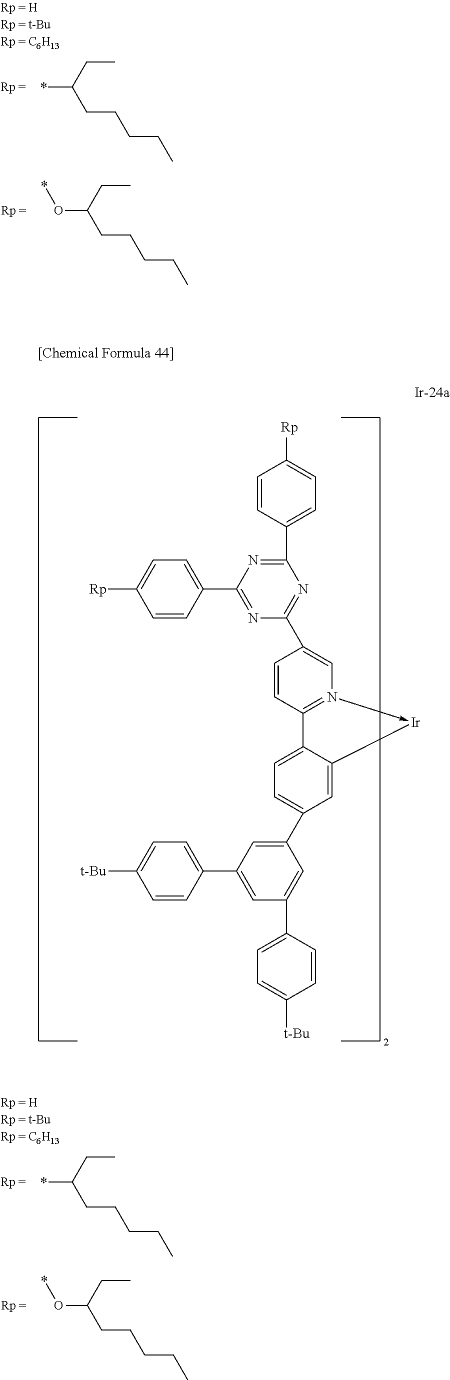

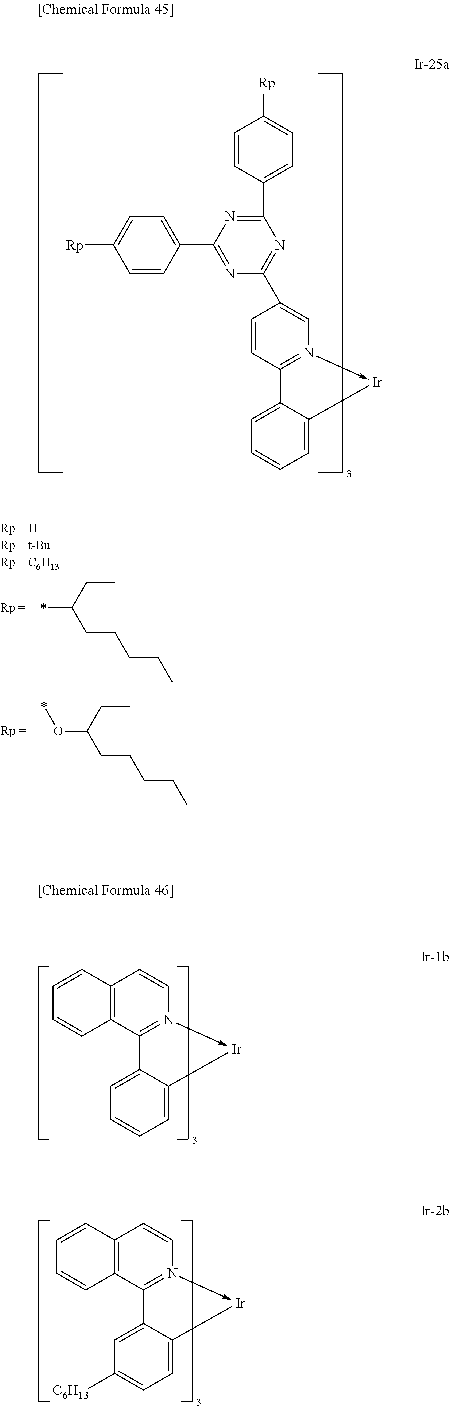

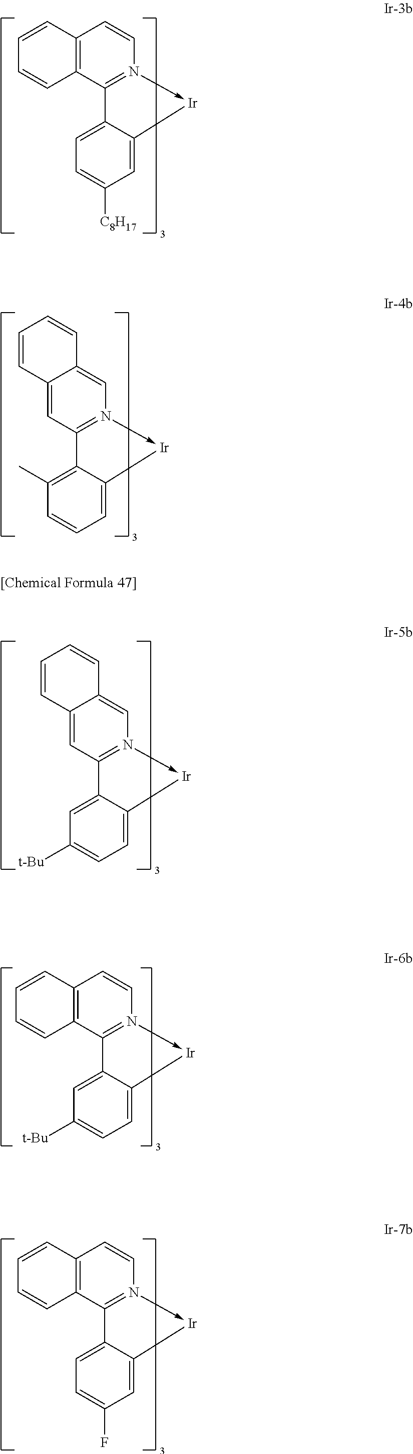

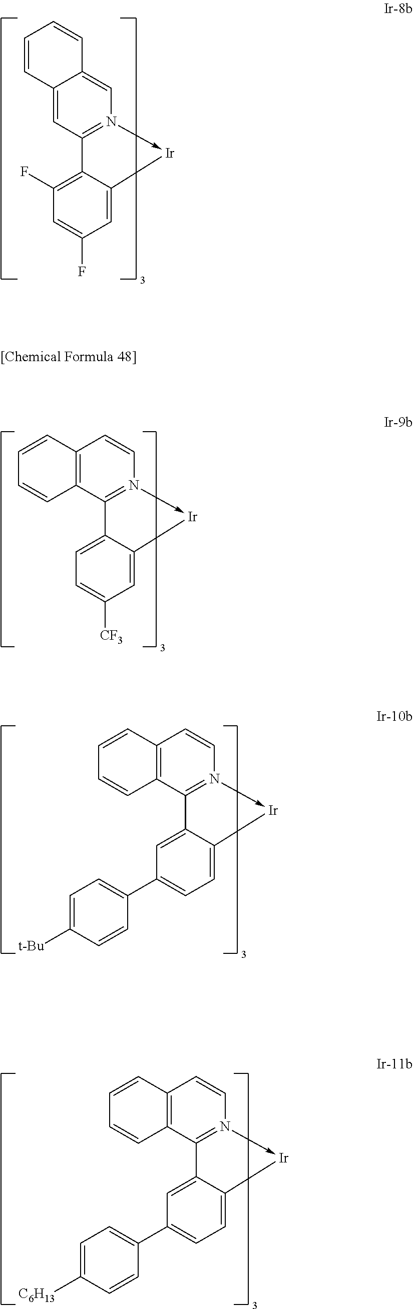

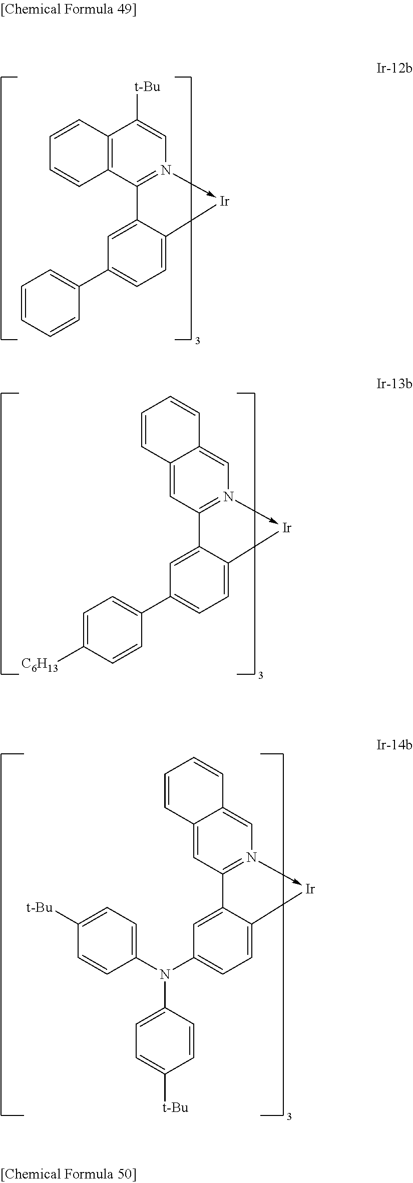

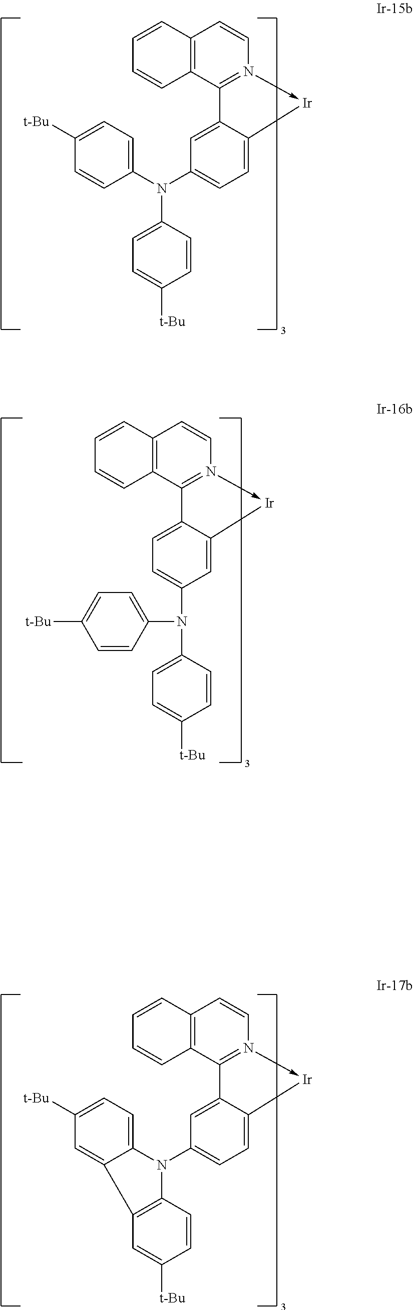

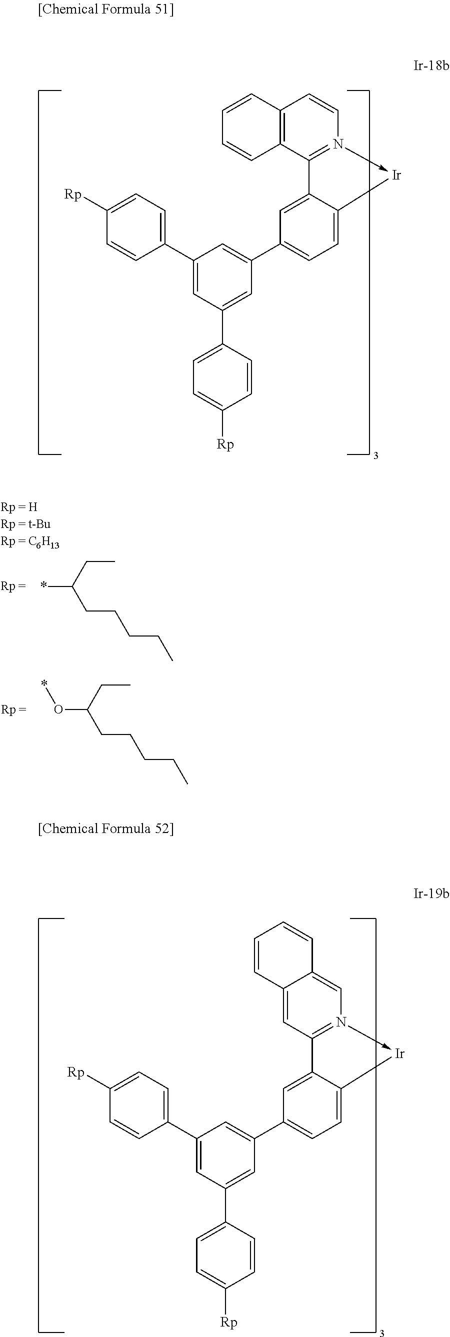

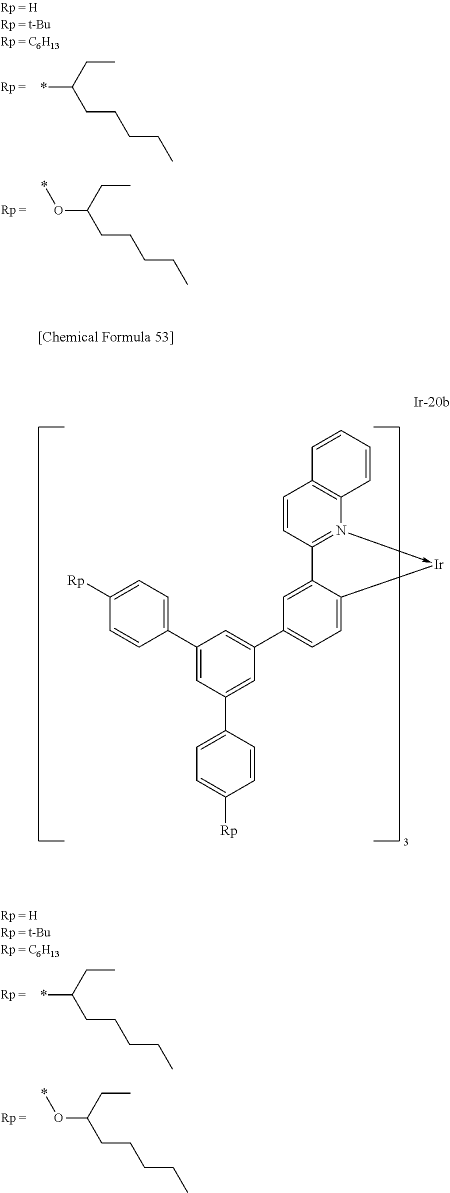

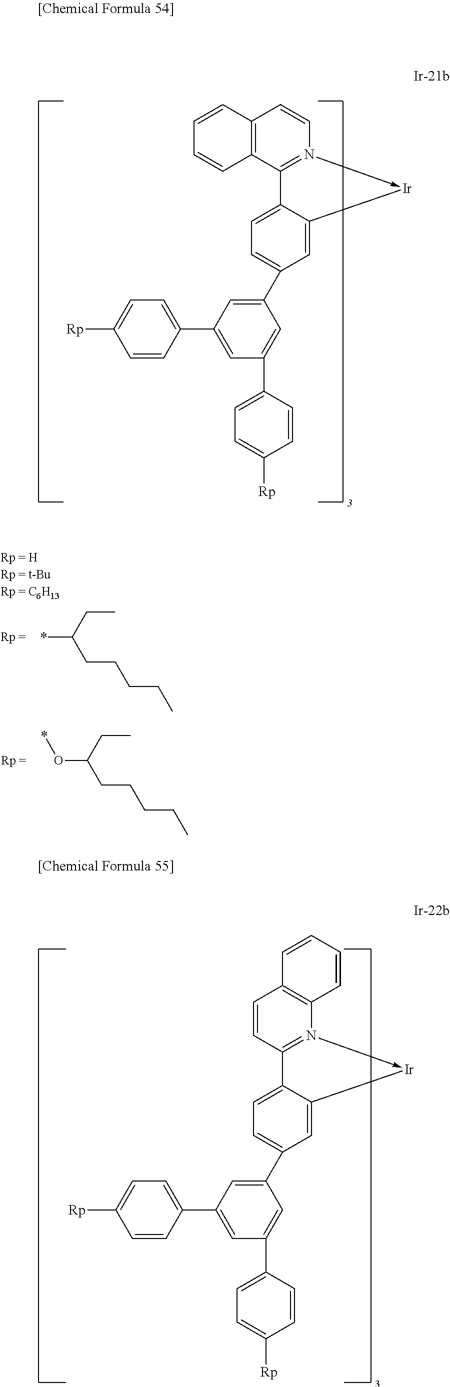

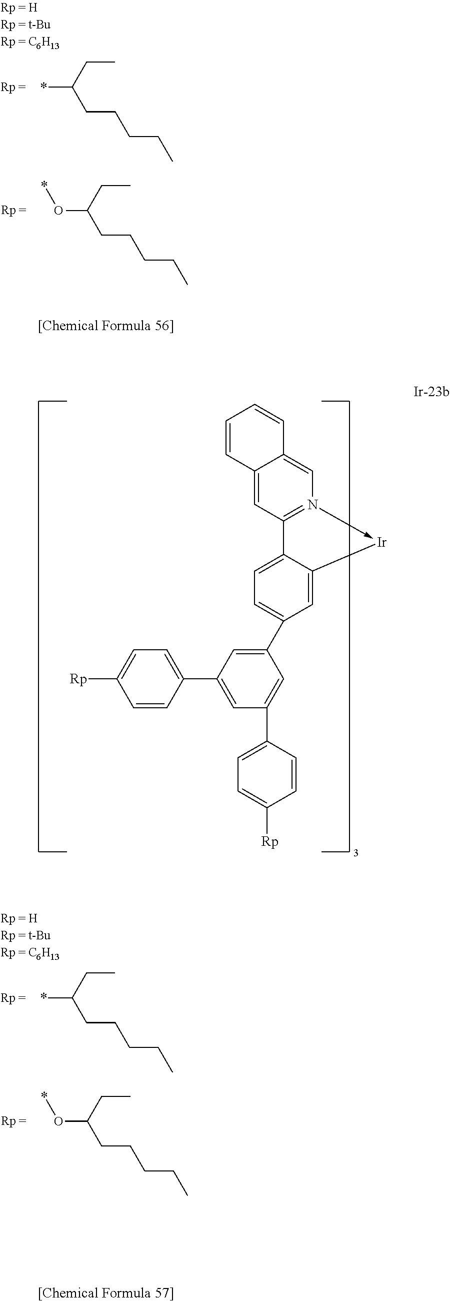

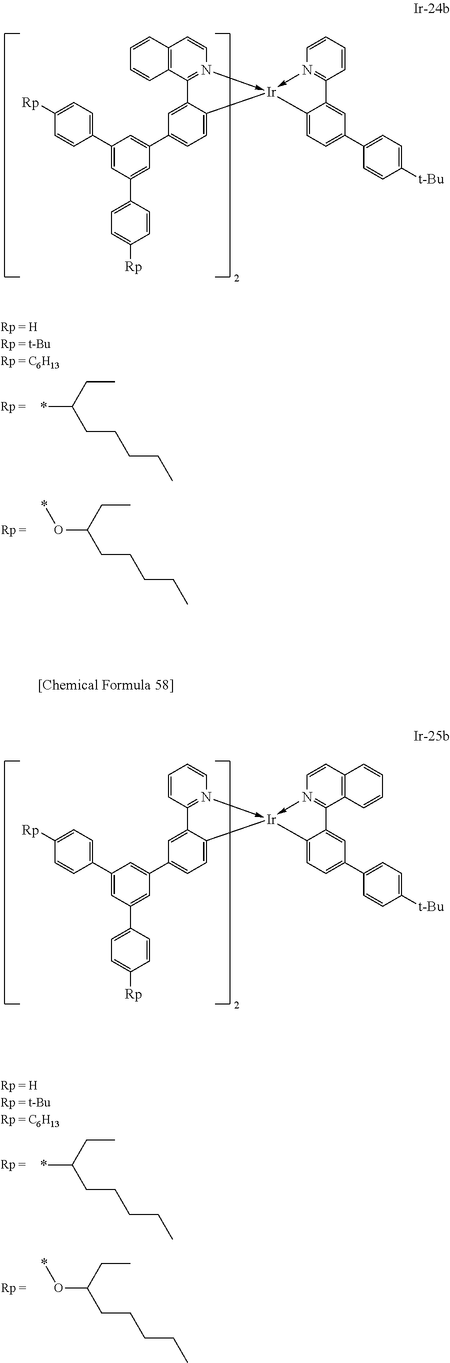

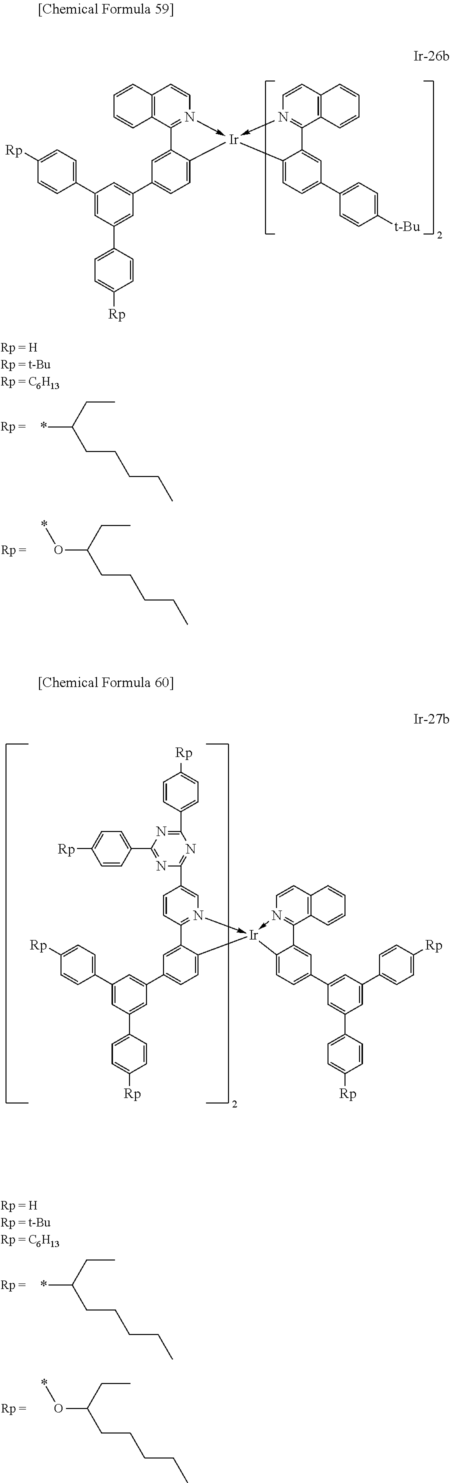

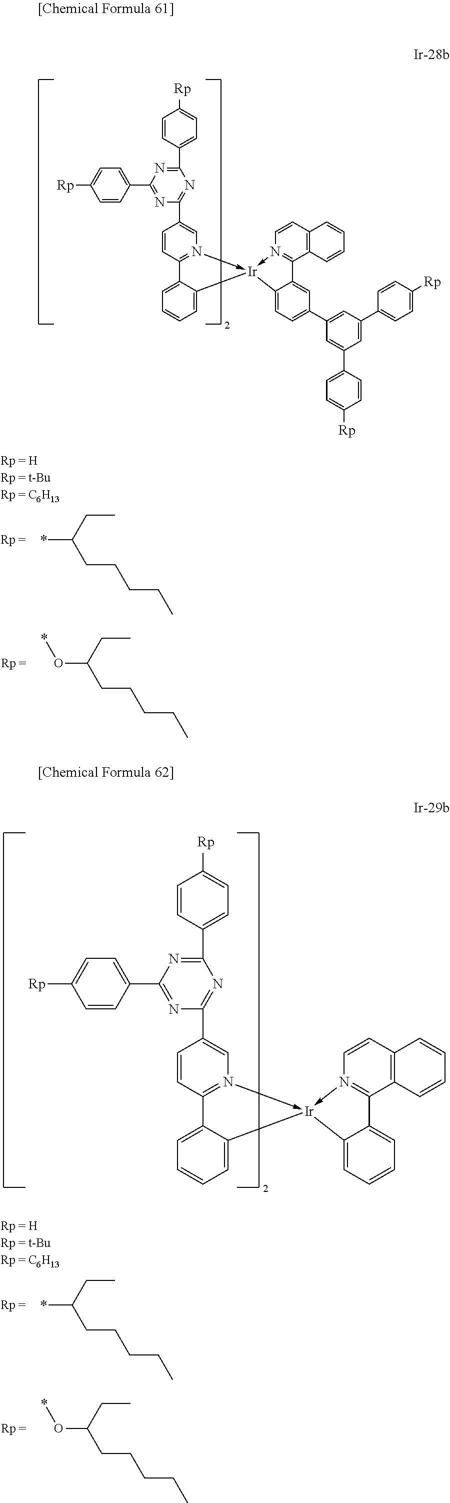

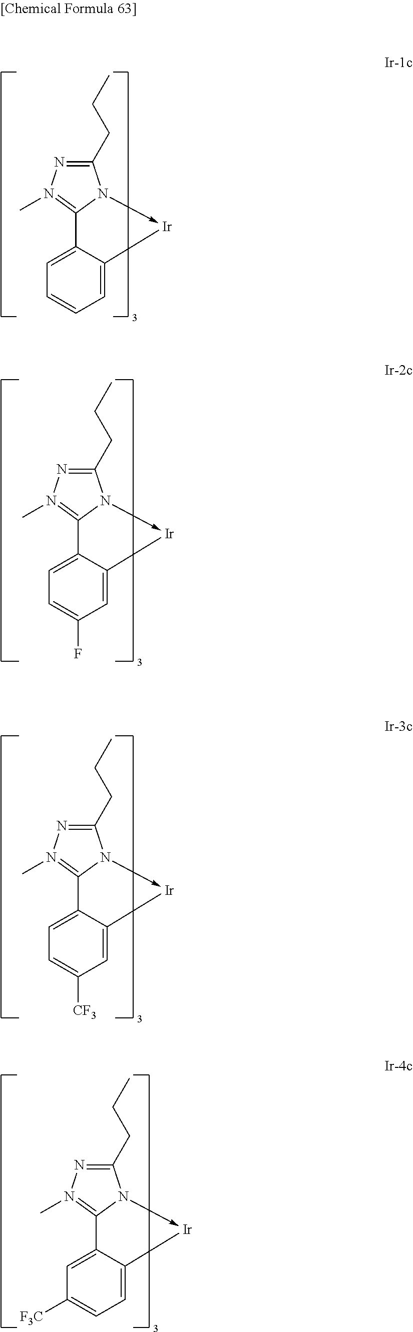

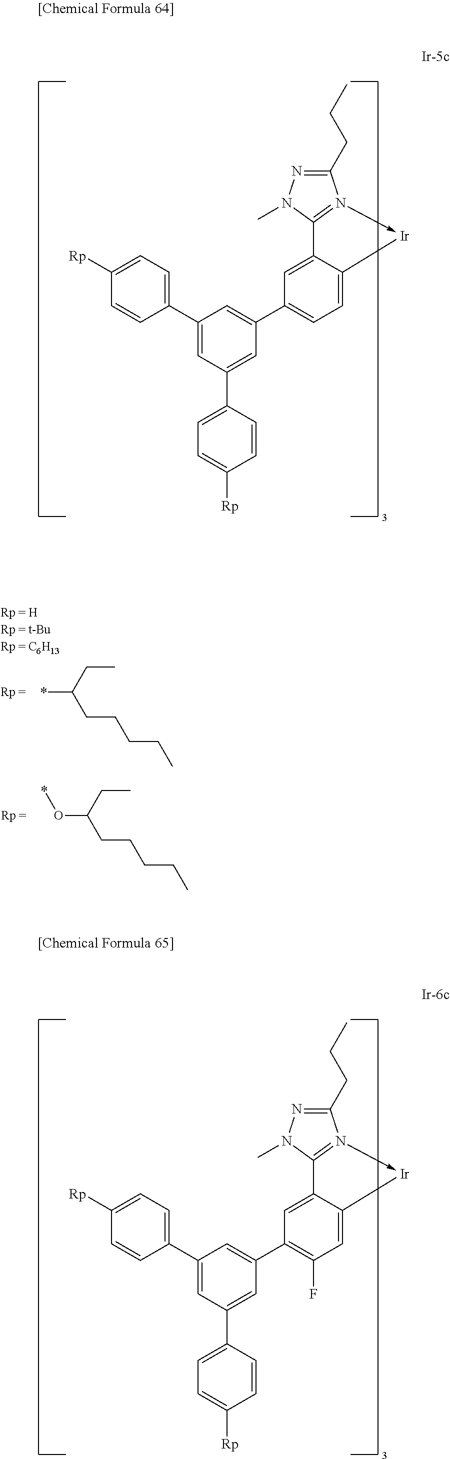

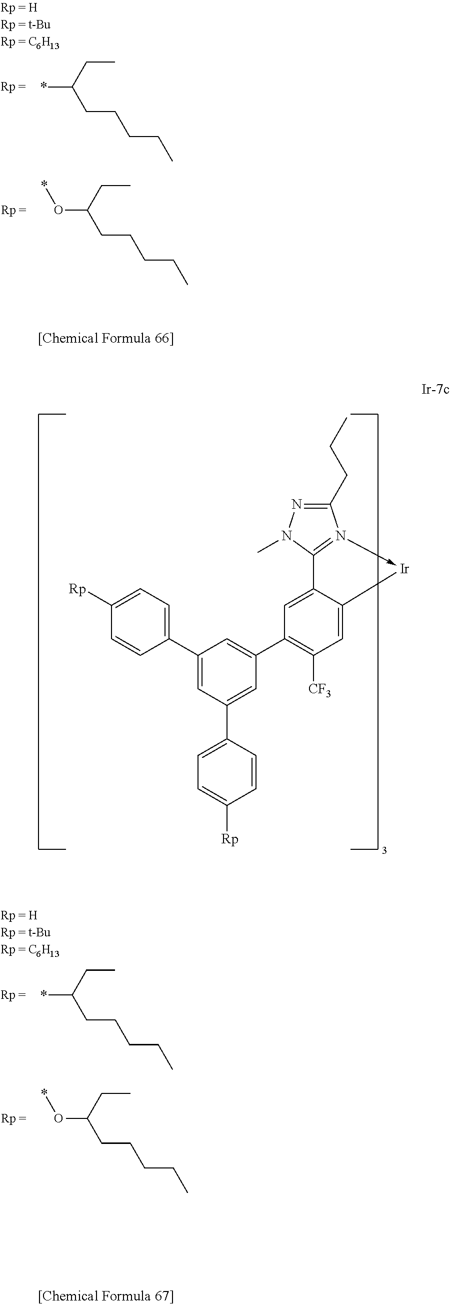

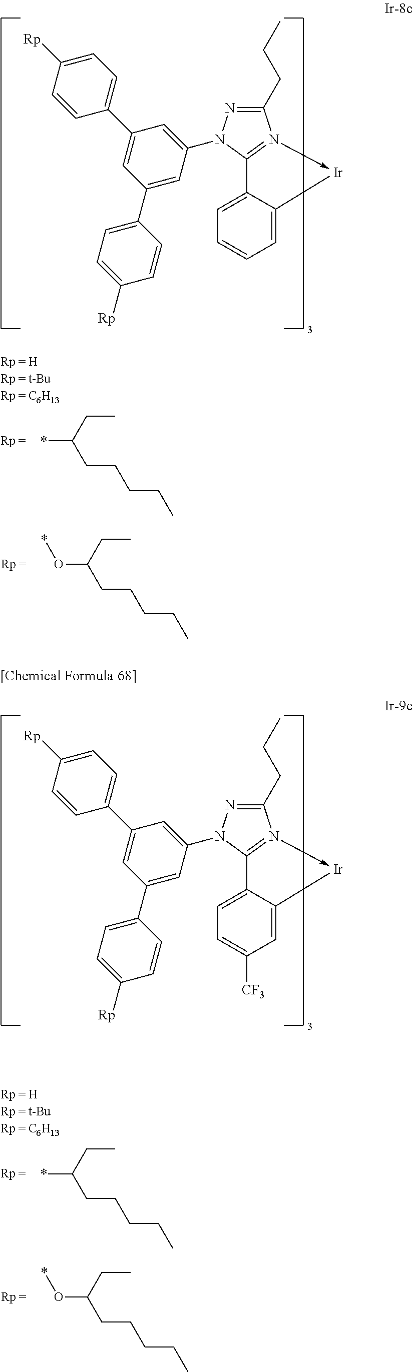

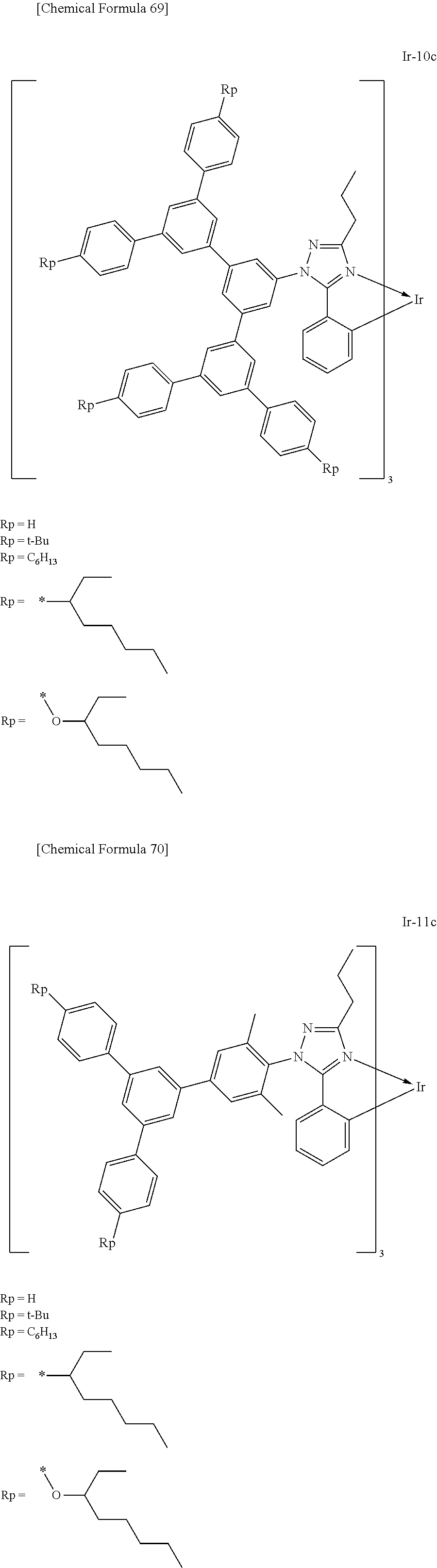

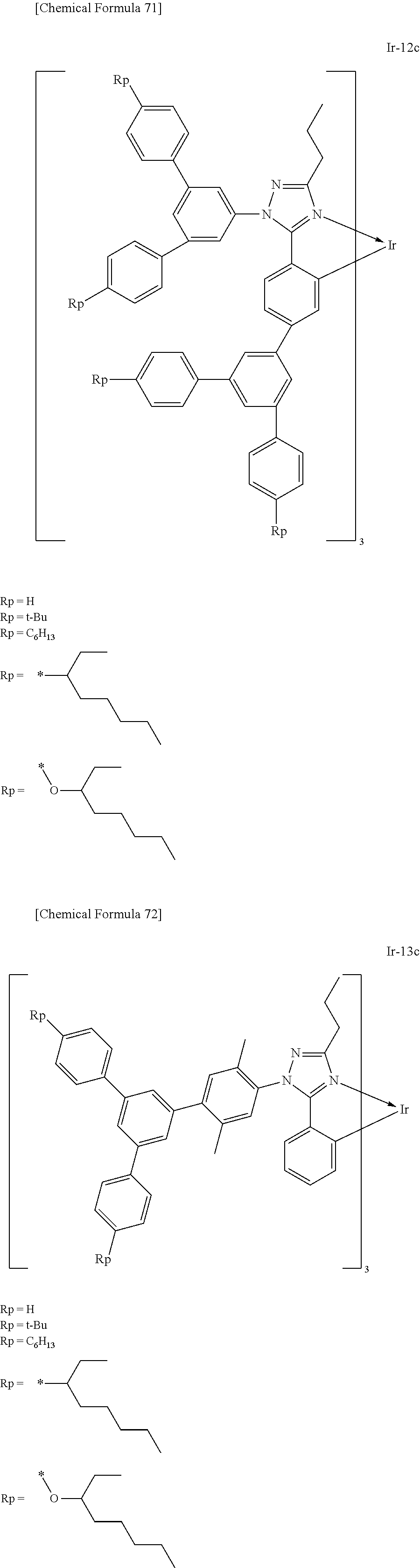

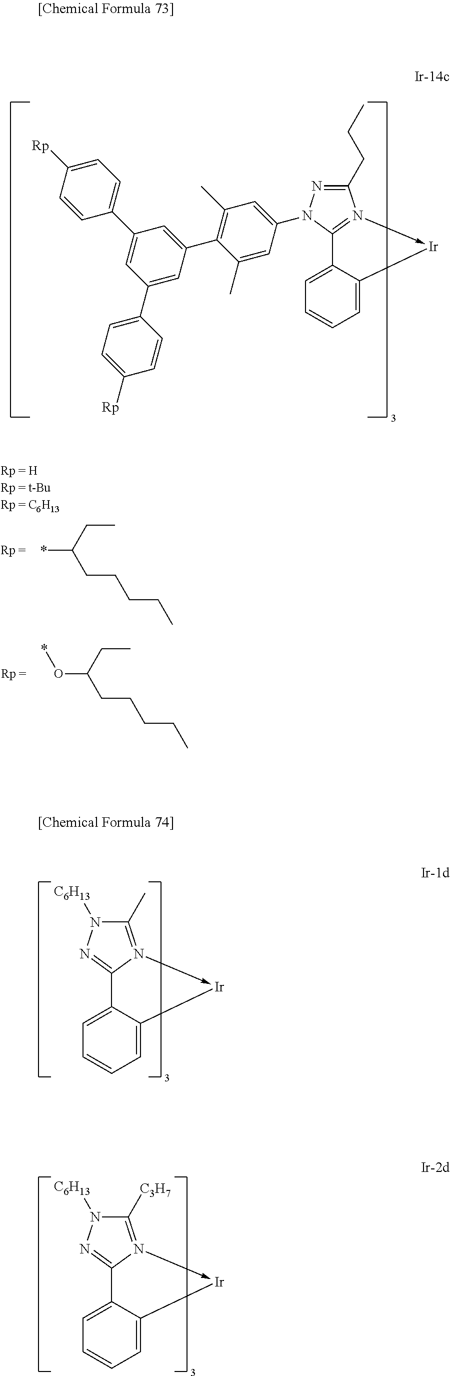

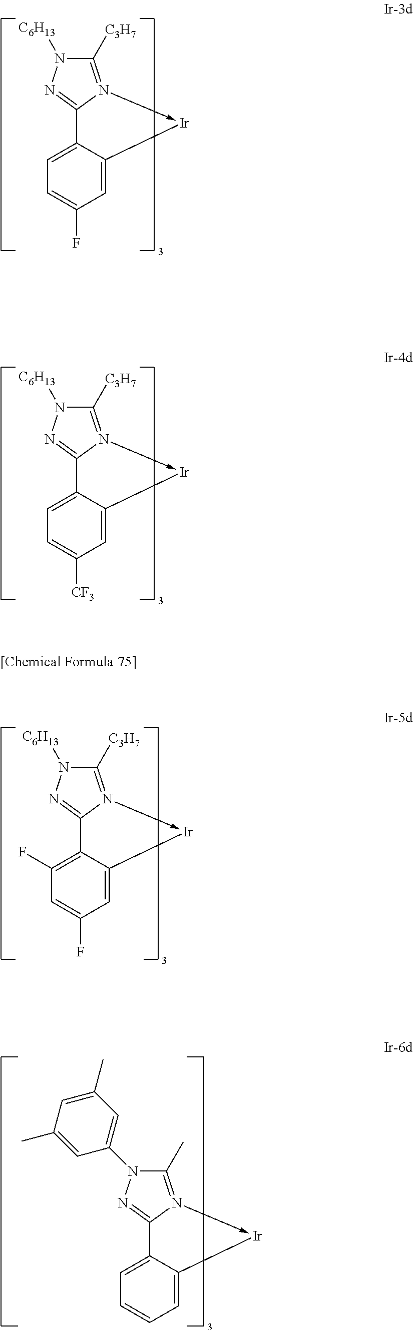

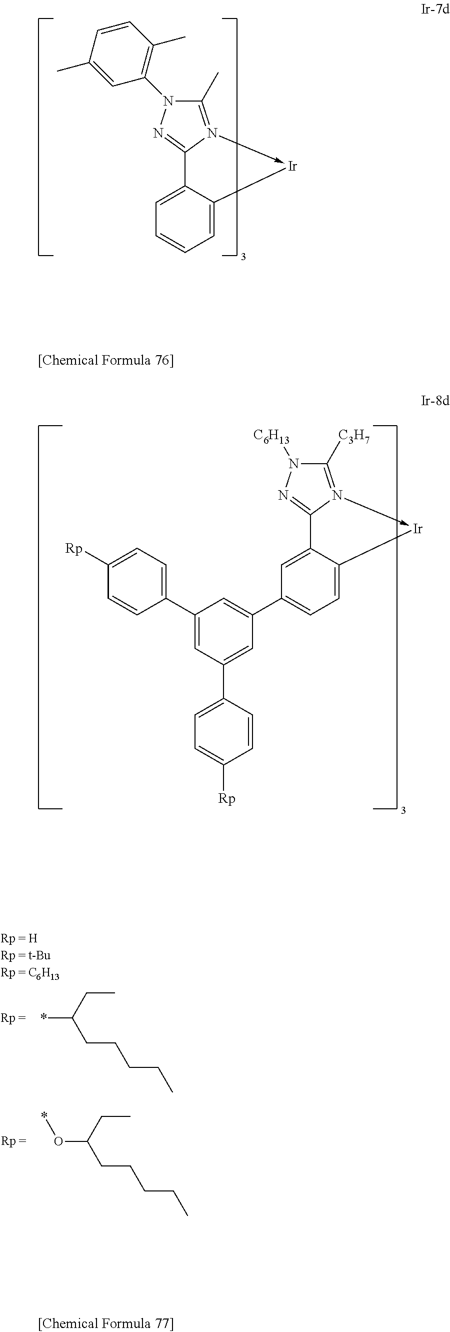

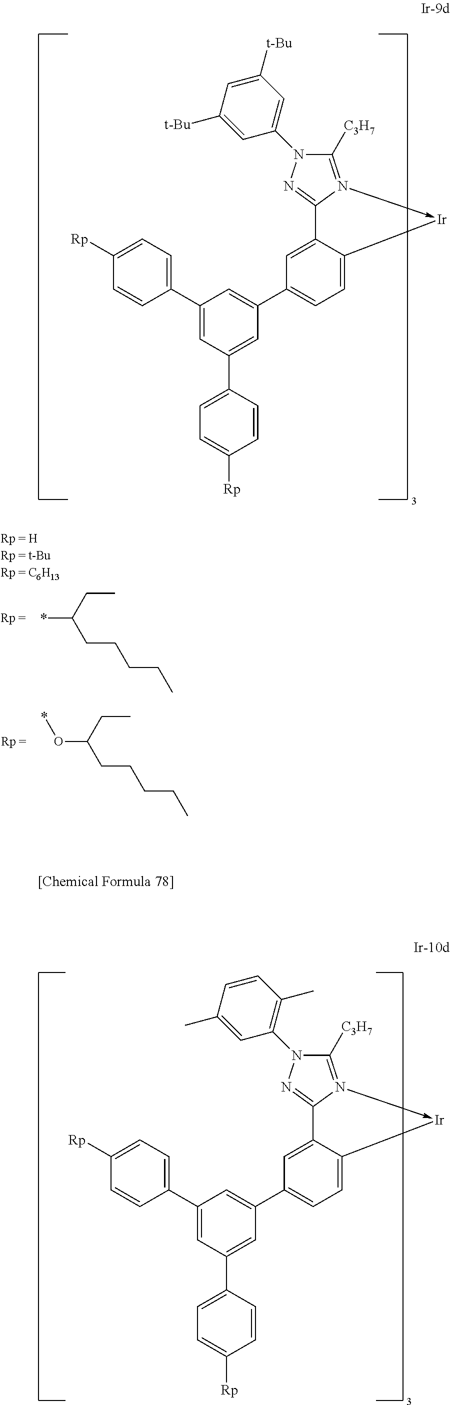

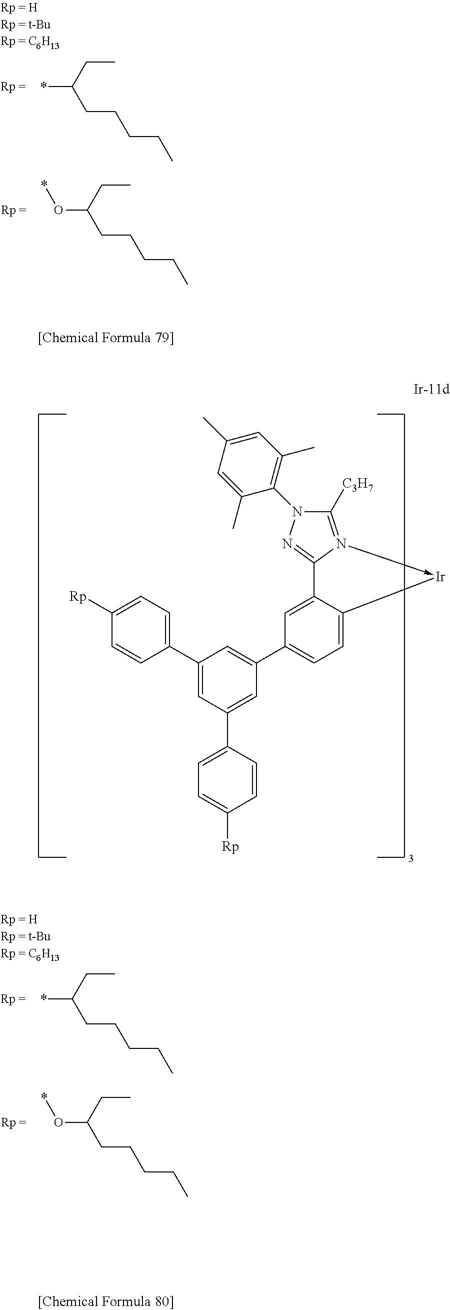

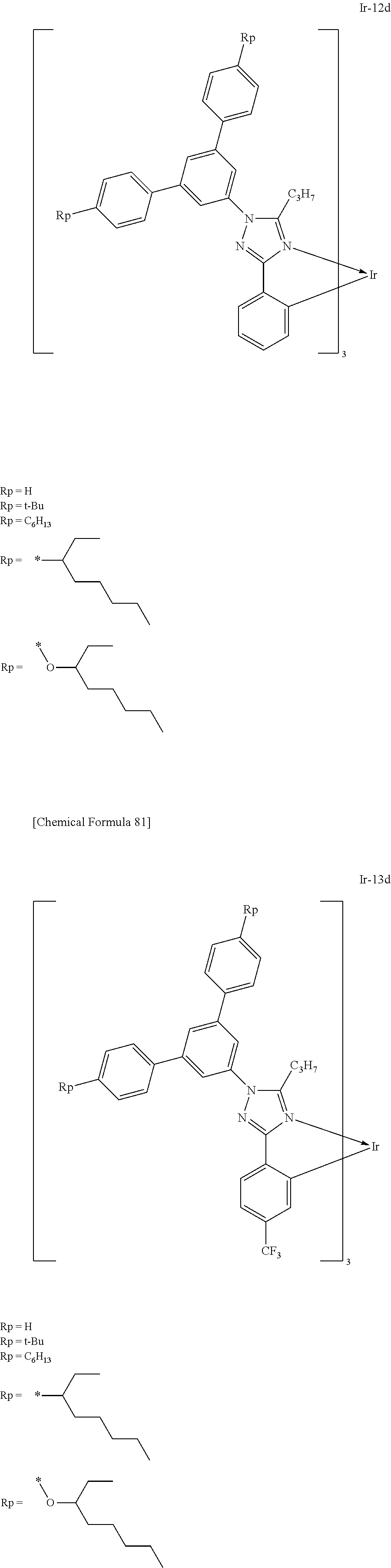

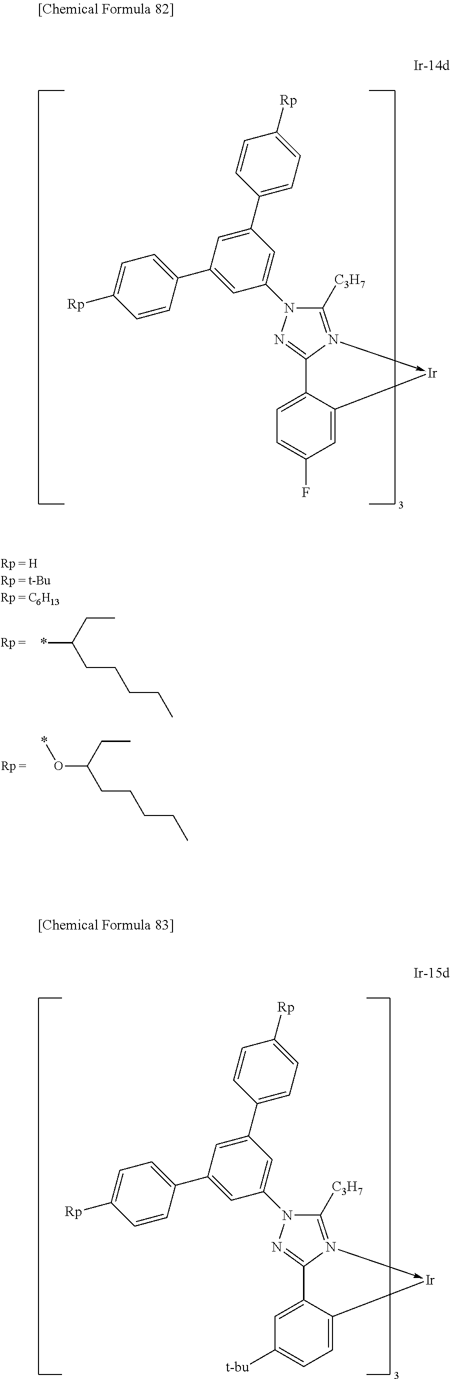

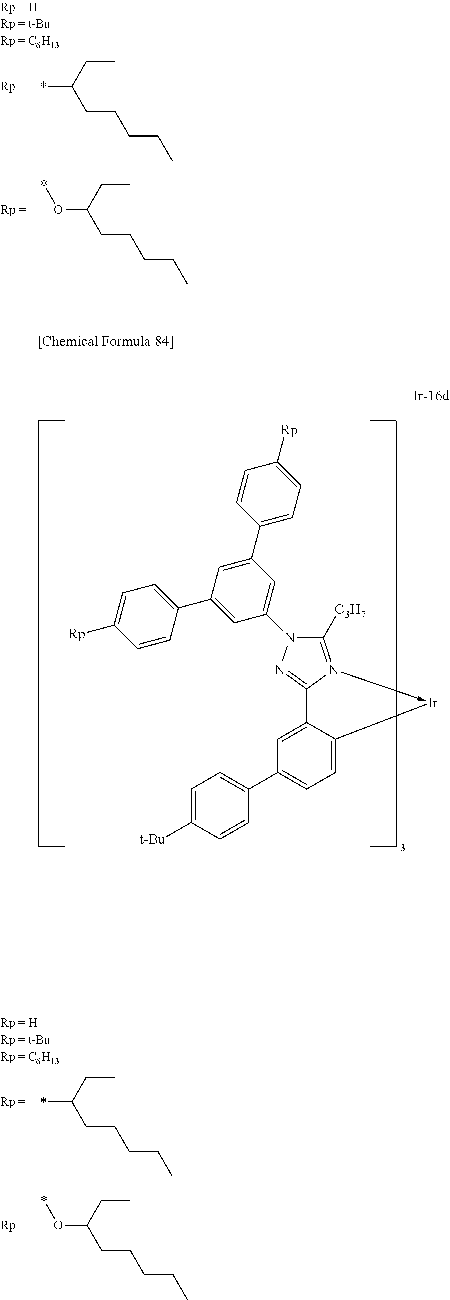

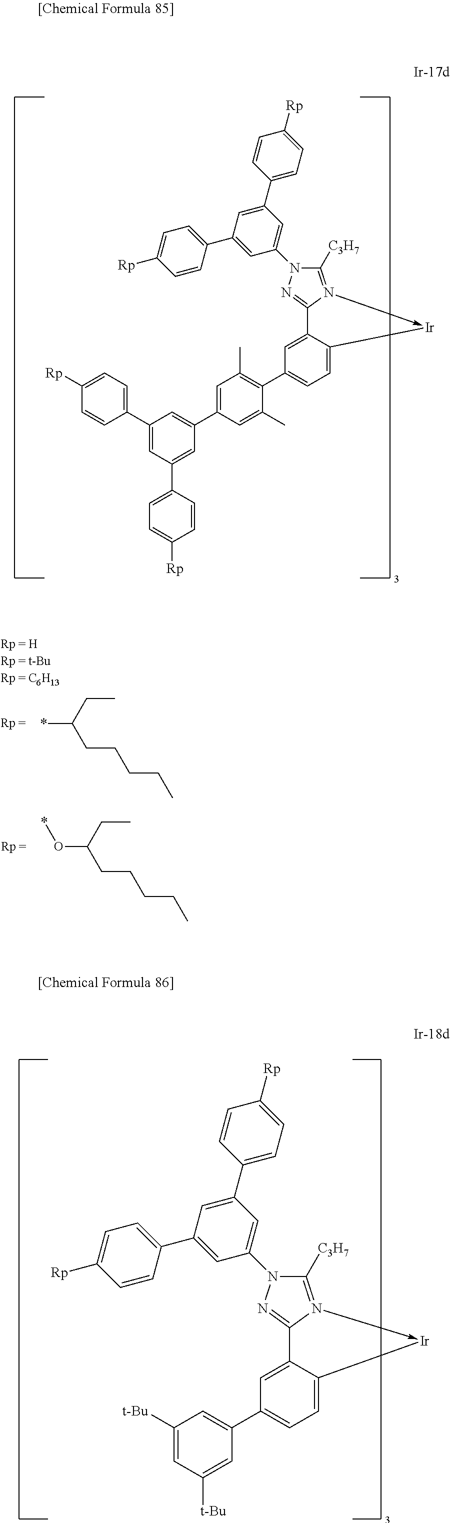

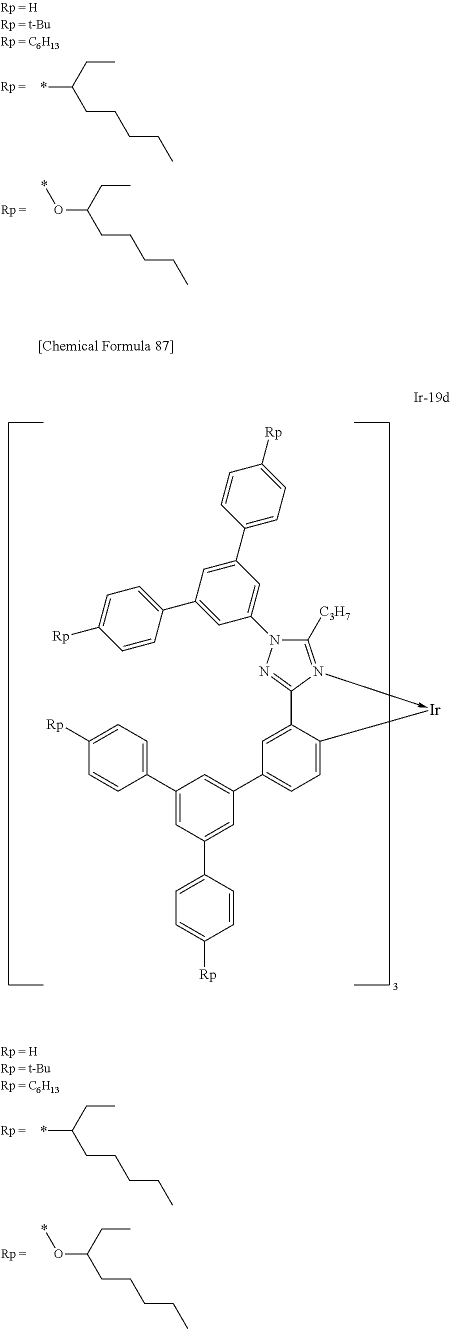

In the formulae, t-Bu represents a tert-butyl group.

An arbitrary hydrogen atom in the phosphorescent compounds exemplified above may have been substituted with an alkyl group, an alkoxy group, an aryl group, a monovalent aromatic heterocyclic group, a substituted amino group, a substituted carbonyl group, a substituted oxycarbonyl group, a fluorine atom or a cyano group. When there are a plurality of substituents, they may be the same or different from each other. They may be combined with each other to form a ring structure together with the atoms with which each of them combines.

In the above exemplification of the phosphorescent compounds, as Rp described as a substituent in the dendron moiety, alkyl groups and alkoxy groups are preferred, and linear, branched or cyclic unsubstituted alkyl group are more preferred. From viewpoints of ease of synthesis, and of ease of dissolution in an organic solvent when using an obtained phosphorescent compound in manufacture of a light emitting device, an alkyl group such as a t-Bu (tert-butyl group), C₆H₁₃ (a hexyl group), an ethylhexyl group is preferred.

The phosphorescent compound represented by formula (11) preferably has a UV-vis absorption edge of 500 nm or more, and examples thereof include those represented by formulae Ir-1a to Ir-25a and formulae Ir-1b to Ir-29b. Also, from a viewpoint of luminance lifetime, those represented by formulae Ir-2a to Ir-6a, formulae Ir-10a to Ir-13a, formulae Ir-17a to Ir-25a, formulae Ir-2b to Ir-6b, formulae Ir-10b to Ir-13b and formulae Ir-18b to Ir-29b are further preferred.

### <Solvent>

The solvent included in the liquid composition of the present invention is a liquid at 25° C. and 1 atm. The solvent is not particularly limited, as long as the solvent dissolves the phosphorescent material and does not react with the phosphorescent material , and examples include an aromatic hydrocarbon, an aromatic ether, an aliphatic hydrocarbon, an aliphatic ether, alcohol, a ketone, an amide, ester, a carbonate.

As the aromatic hydrocarbon, a benzene having a carbon number in one molecule in a range of from 8 to 14 and having 1 to 3 substituents is preferred. As the substituent, a linear or branched unsubstituted alkyl group having 1 to 8 carbon atoms, a cyclopentyl group, a methylcyclopentyl group, a cyclohexyl group, a methylcyclohexyl group, a cycloheptyl group and a methylcycloheptyl group are preferred. Alkyl groups may be combined with each other to form a ring. Such a compound has a boiling point in a preferred range, solubility of the phosphorescent material is relatively good, and such an organic compound that is solid at 25° C. and 1 atm has good solubility in a polymer compound including a structure represented by formula (12) as at least one constitutional unit. Specific examples of a preferred aromatic hydrocarbon include toluene, o-xylene, m-xylene, p-xylene, ethylbenzene, 1,2,3-trimethylbenzene, 1,2,4-trimethylbenzene, 1,3,5-trimethylbenzene, 1,2,3,4-tetramethylbenzene, 1,2,3,5-tetramethylbenzene, 1,2,4,5-tetramethylbenzene, n-propylbenzene, cumene, n-butylbenzene, tert-butylbenzene, n-pentylbenzene, cyclopentylbenzene, 2-methylcyclopentylbenzene, 3-methylcyclopentylbenzene, n-hexylbenzene, cyclohexylbenzene, 2-methylcyclohexylbenzene, 3-methylcyclohexylbenzene, 4-methylcyclohexylbenzene, n-heptylbenzene, cycloheptylbenzene, 2-methylcycloheptylbenzene, 3-methylcycloheptylbenzene, 4-methylcycloheptylbenzene, n-octylbenzene, tetralin. Among the aromatic hydrocarbons, aromatic carbon rings such as toluene, o-xylene, m-xylene, p-xylene, ethylbenzene, 1,2,4-trimethylbenzene, 1,3,5-trimethylbenzene, tetra-methylbenzene, n-propylbenzene, cumene, n-butylbenzene, n-pentylbenzene, cyclopentylbenzene, n-hexylbenzene, cyclohexylbenzene, n-heptylbenzene, n-octylbenzene, tetralin , and a compound including a carbon atom directly linked to the aromatic carbon ring and a hydrogen atom linked to the carbon atom are preferred.

As the aromatic ether, ether having a carbon number in one molecule in a range of from 7 to 12, obtained by bonding a phenyl group that may have been substituted with an unsubstituted alkyl group having 4 or less carbon atoms and an unsubstituted alkyl group having 4 or less carbon atoms through an ether bond, is preferred. Such a compound has a boiling point in a preferred range, and has excellent solubility of a phosphorescent material. Specific examples of a preferred aromatic ether include anisole, ethoxybenzene, 1-propoxybenzene, 2-propoxybenzene, 1-butoxybenzene, 2-butoxybenzene, (2-methyl)propoxybenzene, tert-butoxybenzene, 2-methoxytoluene, 3-methoxytoluene, 4-methoxytoluene, 2-ethoxytoluene, 3-ethoxytoluene and 4-ethoxytoluene, and specific examples of a particularly preferred aromatic ether include anisole, ethoxybenzene, 2-propoxybenzene, tert-butoxybenzene, 2-methoxytoluene, 3-methoxytoluene and 4-methoxytoluene.

As the aliphatic hydrocarbon, those having a carbon number in one molecule in a range of from 5 to 20 are preferred. Among them, linear, branched and cyclic saturated hydrocarbons are particularly preferred, and examples of particularly preferred aliphatic hydrocarbons include hexane, heptane, octane, nonane, decane, cyclopentane, methylcyclopentane, cyclohexane, methylcyclohexane and bicyclohexyl.

As the aliphatic ether, ether having a carbon number in one molecule in a range of from 5 to 12, and an oxygen number in one molecule in a range of from 1 to 4 is preferred, and linear, branched and cyclic saturated aliphatic ethers are particularly preferred. Examples include diisopropyl ether, methyl-tert-butyl ether, di-n-butyl ether, tetrahydrofuran, dioxane, ethylene glycol dimethyl ether, ethylene glycol diethyl ether, diethylene glycol dimethyl ether, and triethylene glycol dimethyl ether.

As the alcohol, alcohol having a carbon number in one molecule in a range of from 2 to 15 is preferred. Examples include ethyl alcohol, propyl alcohol, butyl alcohol, pentyl alcohol, cyclopentyl alcohol, hexyl alcohol, cyclohexyl alcohol, heptyl alcohol, octyl alcohol, benzyl alcohol, phenylethanol, ethylene glycol, propylene glycol, diethylene glycol monomethyl ether, propanediol, glycerol.

As the ketone, a ketone having a carbon number in one molecule in a range of from 3 to 12 is preferred, and a ketone having no alkene or alkyne moiety is particularly preferred. Examples include acetone, methyl ethyl ketone, methyl isobutyl ketone, diisobutyl ketone, cyclohexanone, methylcyclohexanone, 1-hexanone, 2-hexanone, 1-octanone, 2-octanone, 1-nonanone, 2-nonanone, phenylacetone, acetylacetone, acetonylacetone, acetophenone, methyl naphthyl ketone and isophorone.

Preferred examples of the amide include 1-methyl-2-pyrrolidone, 1-ethyl-2-pyrrolidone, N,N-dimethylacetamide, N, N-dimethylformamide and 1,3-dimethyl-2-imidazolidinone.

As the ester, ester having a carbon number in one molecule in a range of from 4 to 12 is preferred, and examples include butyl acetate, ethyl acetate, isopropyl acetate, pentyl acetate, isopentyl acetate, amyl acetate, ethyl propionate, ethyl butyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, propyl formate, propyl lactate, ethyl phenylacetate, ethyl benzoate, β-propiolactone, γ-butyrolactone and δ-valerolactone.

As the carbonate, dimethyl carbonate, diethyl carbonate, ethylene carbonate and propylene carbonate are preferred.

As the solvent, any of the above-described solvents may be used alone, or a mixture of two or more kinds of the solvents may be used. A single solvent with a boiling point at 1 atm of from 60 to 280° C., and preferably from 80 to 280° C., is used. More preferably, a boiling point of at least one kind of solvents is from 180 to 280° C. When a boiling point at 1 atm of a single solvent or a mixed solvent is less than 60° C., the solvent is likely to dry out during storage, and when a boiling point exceeds 280° C., the solvent is likely to remain in a light emitting layer. As the solvent, an aromatic hydrocarbon, an aromatic ether and a mixed solvent of an aromatic hydrocarbon and an aromatic ether are preferred. These solvents have high solubility in a polymer compound having an aryl moiety, and easily dissolve a phosphorescent compound.

The above solvent is preferably subjected to purification treatment before producing a liquid composition. By the purification treatment, oxides included in the solvent may be removed, and an antioxidant, a light stabilizer and other additives that are unfavorable to an organic EL device, added in the production process of the solvent or unexpectedly contaminated, may be removed. As the purification method, purification by distillation, and purification or adsorption treatment by a column using silica gel, alumina, ion exchange resin, activated carbon or the like are preferred. The purified solvent is preferably stored in a resin container, fluororesin container, glass container, metal container or the like that does not contain an additive. In order to prevent oxidative degradation of the purified solvent during storage, the gas phase part of the solvent container may be replaced with an inert gas, and the purified solvent may be stored while maintaining temperature at 25° C. or less. In addition, an additive for preventing oxidative degradation may be added immediately after the purification treatment, and at this time, addition amount of the additive is preferably from 0.1 to 10000 ppm based on weight of the solvent. In storage of a solvent, nitrogen replacement, low temperature storage, and addition of an additive may be independently performed, or may be performed in combination.

<Organic Compound that is Solid at 1 atm and 25° C.>

The liquid compound of the present invention may further contain an organic compound that is solid at 25° C. and 1 atm (hereinafter, may also be referred to as a “second material for a light emitting layer”). The second material for a light emitting layer is preferably a host material. The host material refers to a material that makes a phosphorescent material emit light by energy transfer from an excited state, and may be a small molecule compound, a polymer compound or a mixture thereof. The host material is preferably a charge transporting polymer compound. Also, the host material is preferably a polymer compound since it gives excellent properties to a film when coated thereon.

[Host Material]

The liquid composition of the present invention is a composition of a host material having at least one function selected from hole injecting property, hole transporting property, electron injecting property and electron transporting property, and a phosphorescent material. In the composition of the present invention, one single host material may be included, or two or more kinds of host materials may be included.

In the composition including a host material and a phosphorescent material, the content of the phosphorescent material is usually from 0.05 to 80 parts by weight, preferably from 0.1 to 50 parts by weight, and more preferably from 0.5 to 40 parts by weight, based on 100 parts by weight of the total of the host material and the phosphorescent material.

It is preferred that an energy level of the minimum triplet excited state (T₁) of the host material is equal to or higher than an energy level of the minimum triplet excited state (T₁) of the phosphorescent material.

As the host material, from a viewpoint of fabricating a light emitting device obtained by using the composition of the present invention by solution coating process, a host material that shows solubility in a solvent capable of dissolving a phosphorescent material is preferred.

The host materials are classified into small molecule compounds and polymer compounds.

Examples of a small molecule compound used as the host material include;

a compound having a carbazole backbone, a compound having a triarylamine backbone, a compound having a phenanthroline backbone, a compound having a triaryl triazine backbone, a compound having an azole backbone, a compound having a benzothiophene backbone, a compound having a benzofuran backbone, a compound having a fluorene backbone and a compound having a spirofluorene backbone. More specifically, the small molecule compound used as the host material is a compound represented by the following structural formulae.

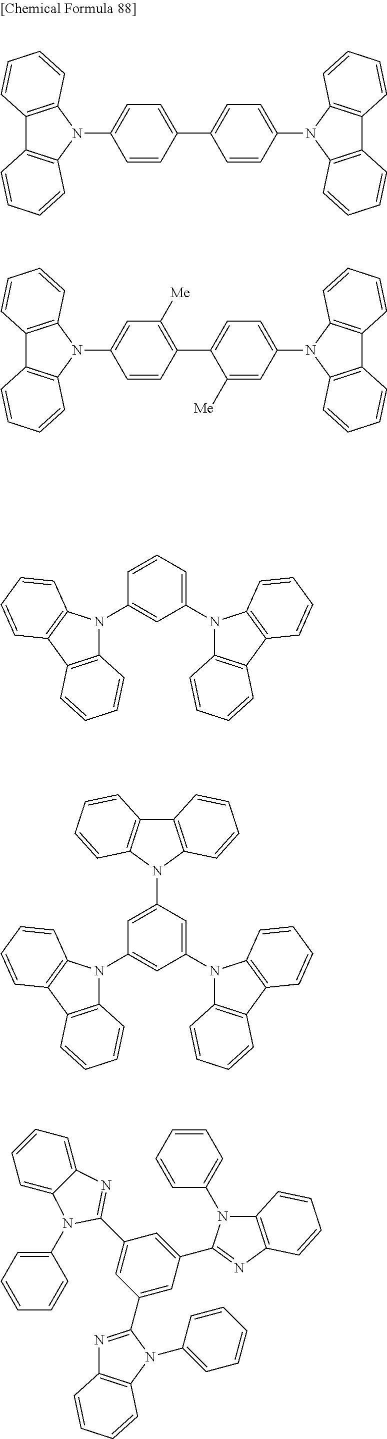 [SMILES: c1ccc2c(c1)c1ccccc1n2-c1ccc(-c2ccc(-n3c4ccccc4c4ccccc43)cc2)cc1 ; Cc1cc(-n2c3ccccc3c3ccccc32)ccc1-c1ccc(-n2c3ccccc3c3ccccc32)cc1C ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; c1ccc(-n2c(-c3cc(-c4nc5ccccc5n4-c4ccccc4)cc(-c4nc5ccccc5n4-c4ccccc4)c3)nc3ccccc32)cc1]

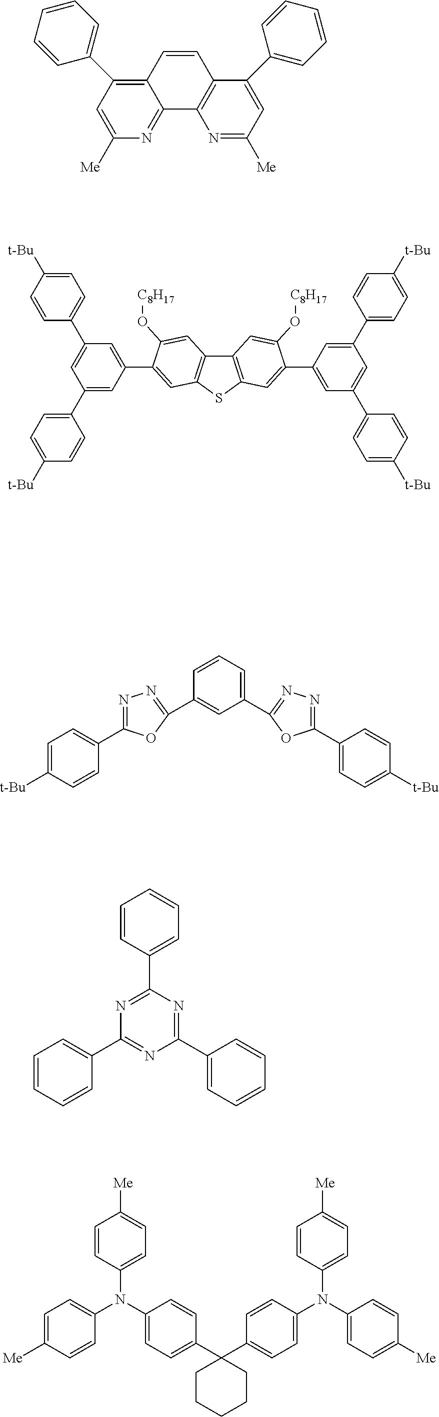

Examples of the polymer compound used as the host material include a polymer compound that is a hole transporting material described below, and a polymer compound that is an electron transporting material described below.

[Polymer Host]

A polymer compound preferred as a host compound (hereinafter also referred to as a “polymer host”) will be described.

As a polymer host, a polymer compound including a constitutional unit represented by formula (Y) is preferred.

[Chemical Formula 89]

Ar^{Y1} (Y)

In the formula, Ar^{Y1} represents an arylene group, a divalent heterocyclic group or a divalent group formed by direct bonding between at least one kind of arylene group and at least one kind of divalent heterocyclic group, and these groups each may have a substituent.

As the arylene group represented by Ar^{Y1}, particularly preferred is a group represented by formula (A-1), formula (A-2), formulae (A-6) to (A-10), formula (A-19) or formula (A-20), and especially preferred is a group represented by formula (A-1), formula (A-2), formula (A-7), formula (A-9) or formula (A-19), and these groups may have a substituent.

As the divalent heterocyclic group represented by Ar^{Y1}, particularly preferred is a group represented by formulae (A-21) to (A-24), formulae (A-30) to (A-35), formulae (A-38) to (A-41), formula (A-53) or formula (A-54), and especially preferred is a group represented by formula (A-24), formula (A-30), formula (A-32), formula (A-34) or formula (A-53), and these groups may have a substituent.

In the divalent group represented by Ar^{Y1}, formed by direct bonding between at least one kind of arylene group and at least one kind of divalent heterocyclic group, a particularly preferred range and an especially preferred range of the arylene group and those of the divalent heterocyclic group are the same as the particularly preferred range and especially preferred range of the arylene group represented by Ar^{Y1}, described above, and those of the divalent heterocyclic group represented by Ar^{Y1}, described above, respectively.

Examples of the “divalent group formed by direct bonding between at least one kind of arylene group and at least one kind of divalent heterocyclic group” include groups represented by the following formulae, and these groups each may have a substituent.

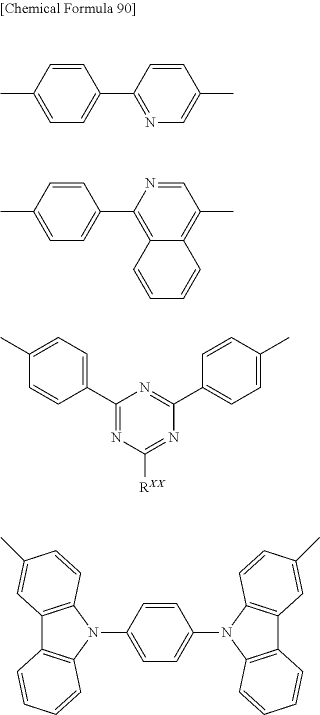

In the formulae, R^{XX} represents a hydrogen atom, an alkyl group, an aryl group or a monovalent heterocyclic group, and these groups may have a substituent.

R^{XX} is preferably an alkyl group or an aryl group, and these groups may have a substituent.

The optional substituent of the group represented by Ar^{Y1} is preferably an alkyl group or an aryl group, and these groups further may have a substituent.

Examples of the constitutional unit represented by formula (Y) include constitutional units represented by formulae (Y-1) to (Y-13). The constitutional unit represented by formula (Y) is preferably a constitutional unit represented by formula (Y-1), (Y-2) or (Y-3) from a viewpoint of luminance lifetime of a light emitting device using a compound of a polymer host and a phosphorescent material, preferably constitutional units represented by formulae (Y-4) to (Y-7) from a viewpoint of electron transporting property, and preferably constitutional units represented by formulae (Y-8) to (Y-10) from a viewpoint of hole transporting property.

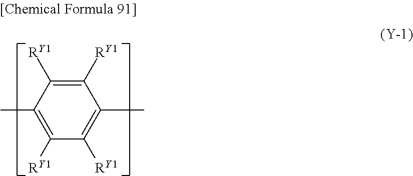

In the formula, R^{Y1} represent a hydrogen atom, an alkyl group, an alkoxy group, an aryl group or a monovalent heterocyclic group, and these groups may have a substituent. A plurality of R^{Y1}s may be the same or different from each other. Adjacent R^{Y1}s may be combined with each other to form a ring together with the carbon atoms with which each of them combines.

R^{Y1} is preferably a hydrogen atom, an alkyl group or an aryl group, and these groups may have a substituent.

The constitutional unit represented by formula (Y-1) is preferably a constitutional unit represented by formula (Y-1′).

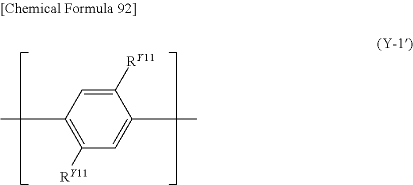

In the formula, R^{Y11} represent an alkyl group, an alkoxy group, an aryl group or a monovalent heterocyclic group, and these groups may have a substituent. A plurality of R^{Y1}s may be the same or different from each other.

R^{Y11} is preferably an alkyl group or an aryl group, and more preferably an alkyl group, and these groups may have a substituent.

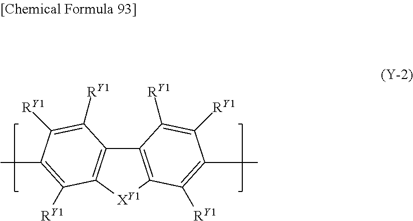

In the formula, R^{Y1} represents the same meaning as described above. X^{Y1} represents a group represented by —C(R^{Y2})₂—, —C(R^{Y2})=C(R^{Y2})— or C(R^{Y2})₂—C(R^{Y2})₂—. R^{Y2} represents a hydrogen atom, an alkyl group, an alkoxy group, an aryl group or a monovalent heterocyclic group, and these groups may have a substituent. A plurality of R^{Y2}s may be the same or different from each other. R^{Y2}s may be combined with each other to form a ring together with the carbon atoms with which each of them combines.

R^{Y2} is preferably an alkyl group, an aryl group or a monovalent heterocyclic group, and more preferably an alkyl group or an aryl group, and these groups may have a substituent.

In X^{Y1}, as a combination of two R^{Y2}s in a group represented by —C(R^{Y2})₂—, preferably, both are alkyl groups, both are aryl groups, both are monovalent heterocyclic groups, or one is an alkyl group and other is an aryl group or a monovalent heterocyclic group, and more preferably, one is an alkyl group and the other is an aryl group, and these groups may have a substituent. Two R^{Y2}s may be combined with each other to form a ring together with the atoms with which each of them combines, and when R^{Y2}s form a ring, the group represented by —C(R^{Y2})₂— is preferably a group represented by one of formulae (Y-A1) to (Y-A5), and more preferably a group represented by formula (Y-A4), and these groups may have a substituent.

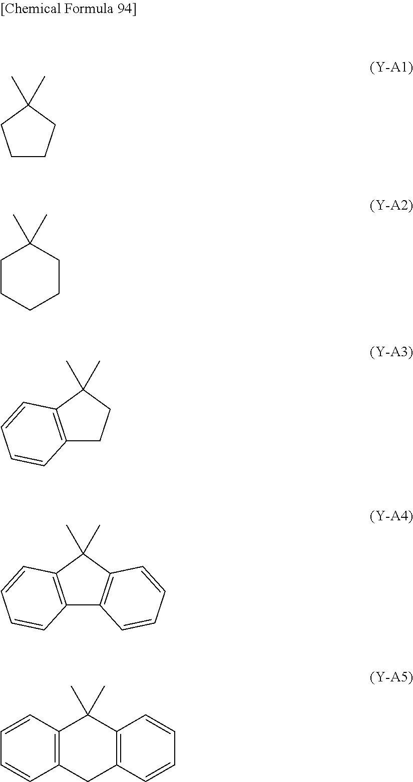

In X^{Y1}, as the combination of two R^{Y2}s in the group represented by —C(R^{Y2})═C(R^{Y2})—, preferably, both are alkyl groups, or one is an alkyl group and the other is an aryl group, and these groups may have a substituent.

In X^{Y1}, four R^{Y2}s in the group represented by —C(R^{Y2})₂—C(R^{Y2})₂— are preferably alkyl groups each optionally having a substituent. A plurality of R^{Y2}s may be combined with each other to form a ring together with the atoms with which each of them combines, and when R^{Y2}s form a ring, the group represented by —C(R^{Y2})₂—C(R^{Y2})₂— is preferably a group represented by one of formulae (Y-B1) to (Y-B5), and more preferably a group represented by formula (Y-B3), and these groups may have a substituent.

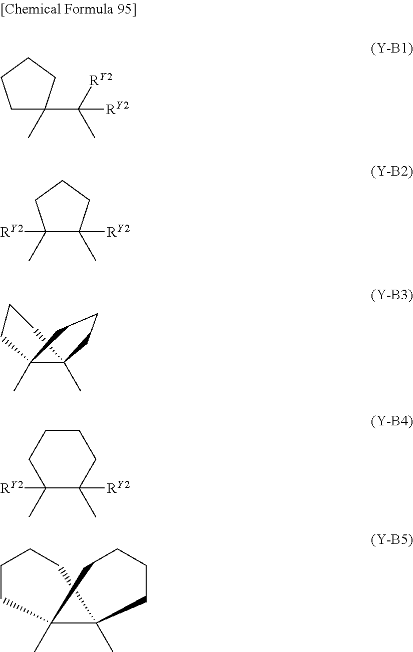

In the formulae, R^{Y2} represents the same meaning as described above.

The constitutional unit represented by formula (Y-2) is preferably a constitutional unit represented by formula (Y-2′).

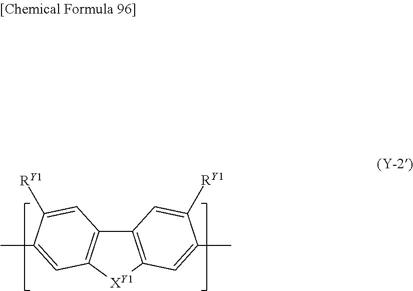

In the formula, R^{Y1} and X^{Y1} represent the same meaning as described above.

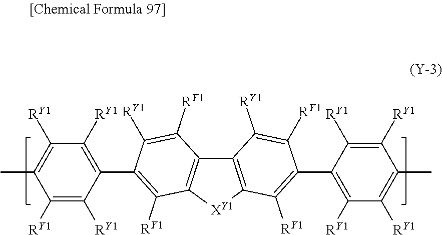

In the formula, R^{Y1} and X^{Y1} represent the same meaning as described above.

The constitutional unit represented by formula (Y-3) is preferably a constitutional unit represented by formula (Y-3′).

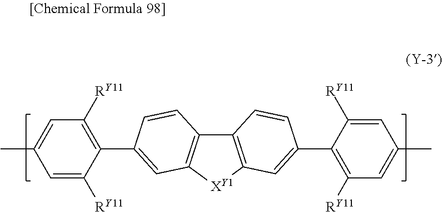

In the formula, R^{Y11} and X^{Y1} represent the same meaning as described above.

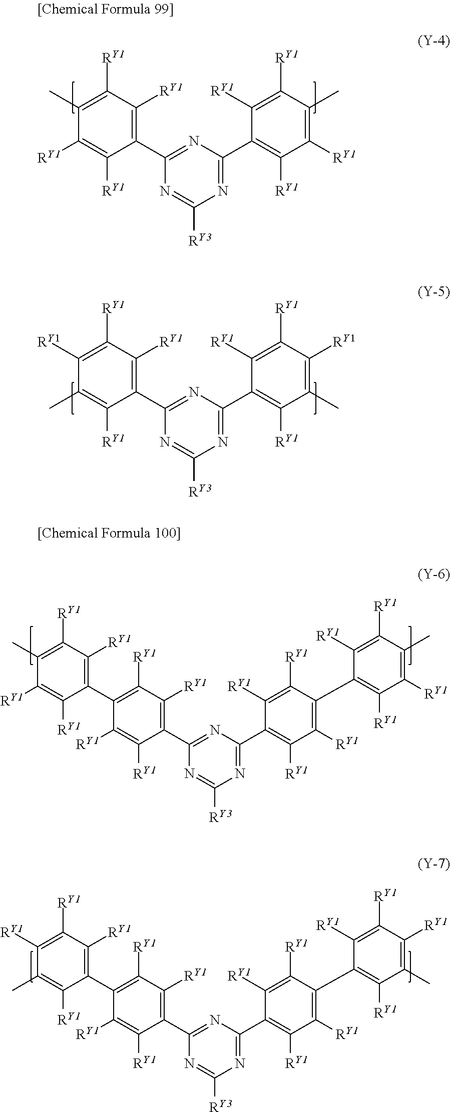

In the formulae, R^{Y1} represents the same meaning as described above. R^{Y3} represents a hydrogen atom, an alkyl group, an alkoxy group, an aryl group or a monovalent heterocyclic group, and these groups may have a substituent.

R^{Y3} is preferably an alkyl group, an alkoxy group, an aryl group or a monovalent heterocyclic group, and more preferably an aryl group, and these groups may have a substituent.

The constitutional unit represented by formula (Y-4) is preferably a constitutional unit represented by formula (Y-4′), and the constitutional unit represented by formula (Y-6) is preferably a constitutional unit represented by formula (Y-6′).

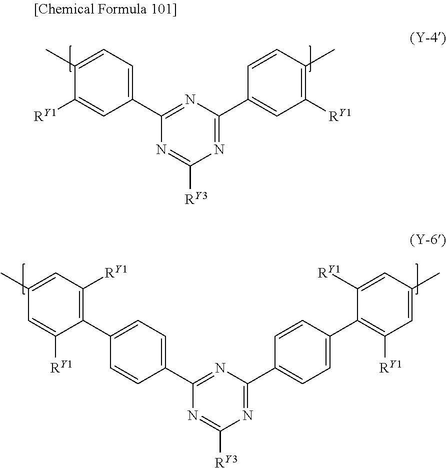

In the formulae, R^{Y1} and R^{Y3} represent the same meaning as described above.

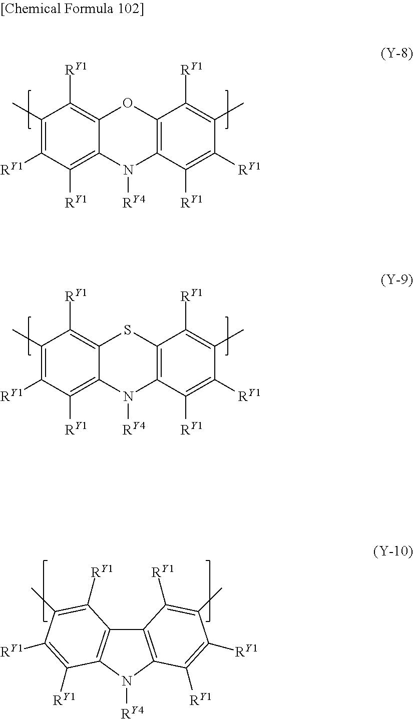

In the formulae, R^{Y1} represents the same meaning as described above. R^{Y4} represents a hydrogen atom, an alkyl group, an alkoxy group, an aryl group or a monovalent heterocyclic group, and these groups may have a substituent.

R^{Y4} is preferably an alkyl group, an alkoxy group, an aryl group or a monovalent heterocyclic group, and more preferably an aryl group, and these groups may have a substituent.

Examples of the constitutional unit represented by formula (Y) include a constitutional unit comprising an arylene group represented by formulae (Y-101) to (Y-121), a constitutional unit comprising a divalent heterocyclic group represented by formulae (Y-201) to (Y-206), and a constitutional unit comprising a divalent group formed by direct bonding between at least one kind of arylene group and at least one kind of divalent heterocyclic group represented by formulae (Y-301) to (Y-304).

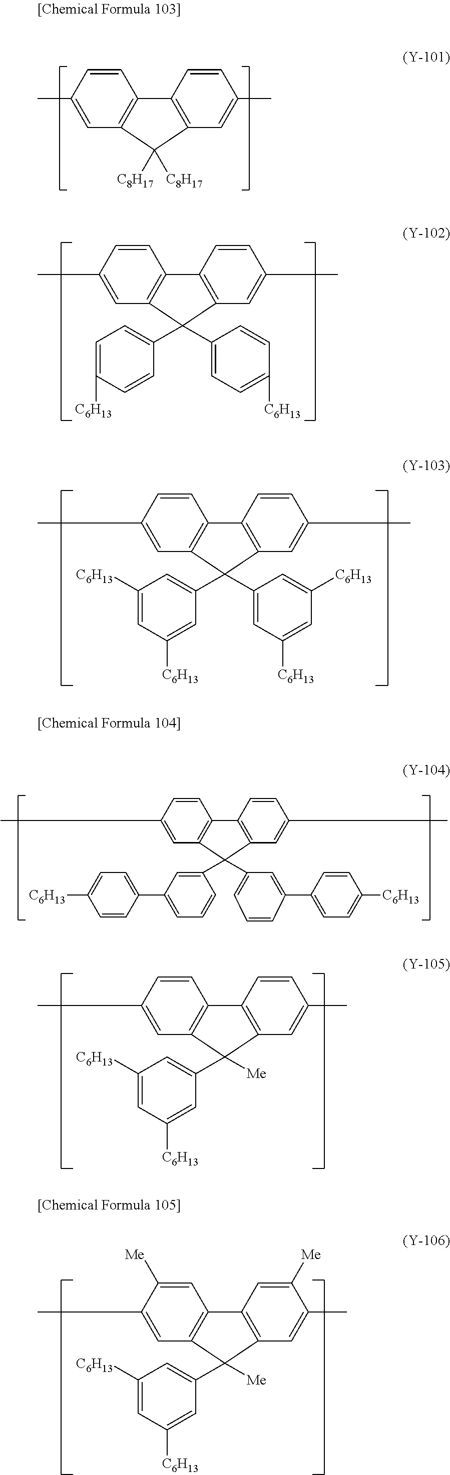

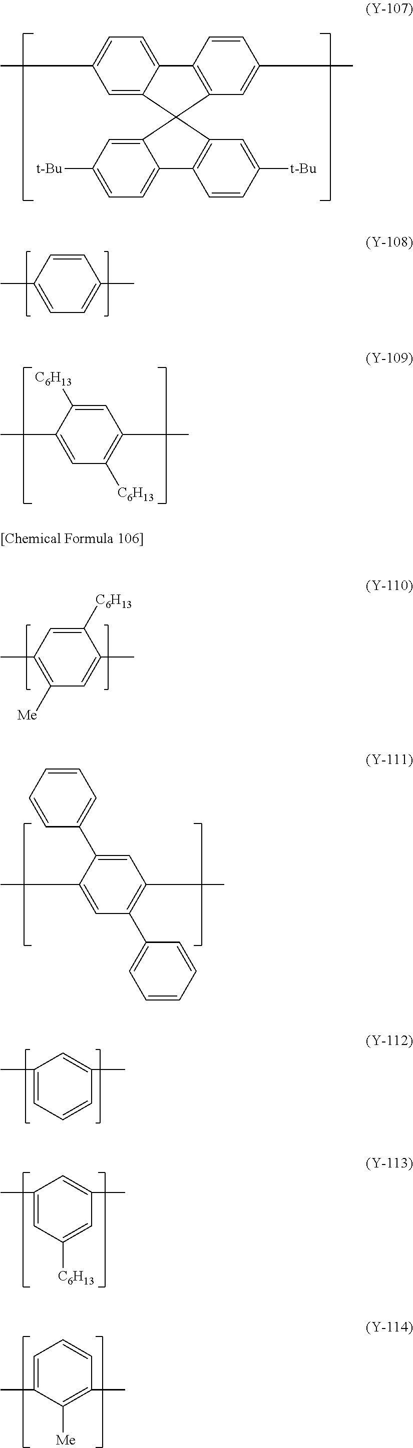

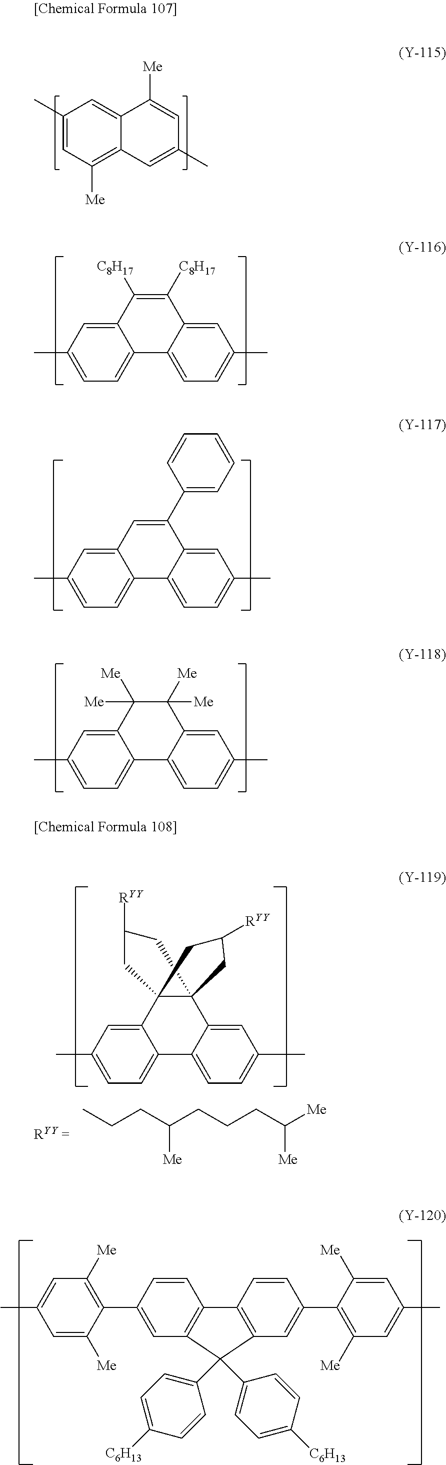

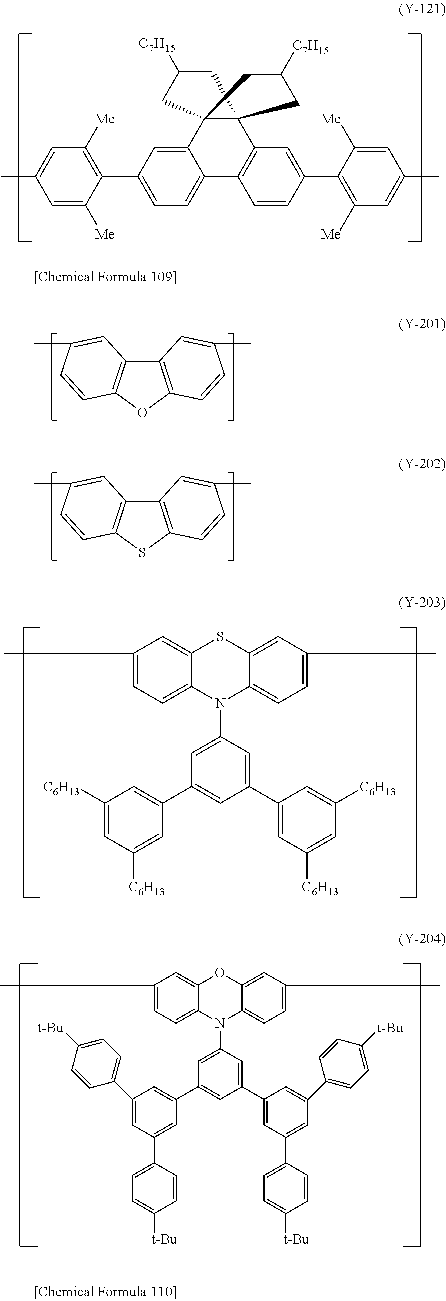

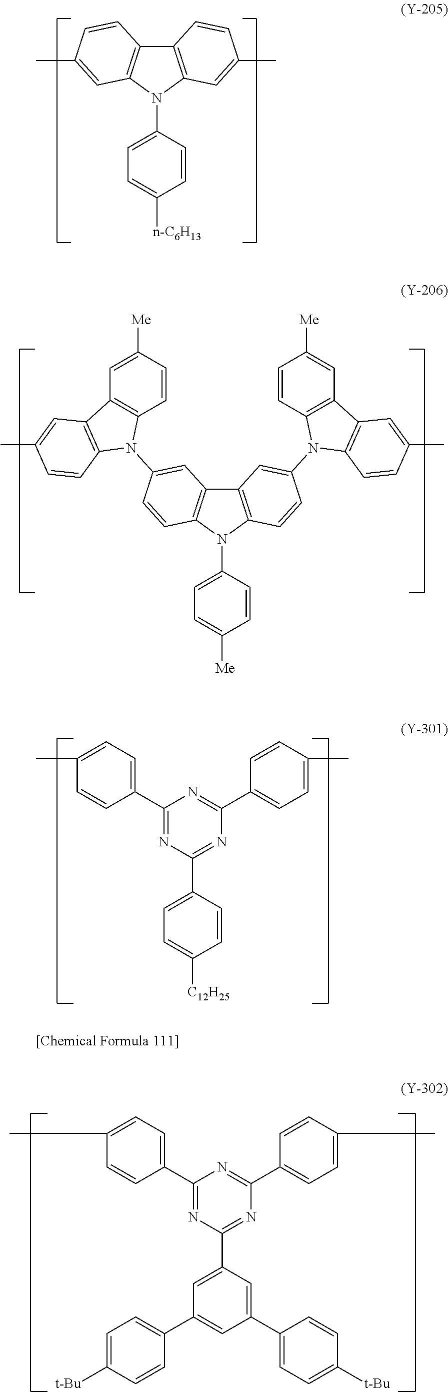

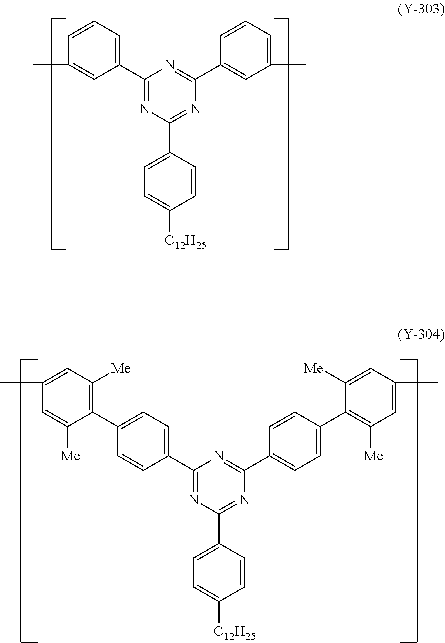

The constitutional unit represented by formula (Y) wherein Ar^{Y1} is an arylene group is preferably from 0.5 to 80% by mol, and more preferably from 30 to 60% by mol, based on the total amount of constitutional units included in a polymer compound, since luminance lifetime of a light emitting device using a compound of a polymer host and a phosphorescent material is excellent.

The constitutional unit represented by formula (Y) wherein Ar^{Y1} is a divalent heterocyclic group or a divalent group formed by direct bonding between at least one kind of arylene group and at least one kind of divalent heterocyclic group is preferably from 0.5 to 30% by mol, and more preferably from 3 to 20% by mol, based on the total amount of constitutional units included in a polymer compound, since charge transporting property of a light emitting device using a compound of a polymer host and a phosphorescent material is excellent.

Only one kind of the constitutional unit represented by formula (Y) may be included in a polymer host, or two or more kinds may be included therein.

The polymer host has excellent hole transporting properties, thus preferably further includes a constitutional unit represented by the following formula (X).

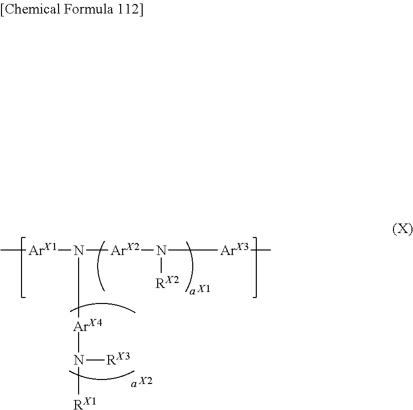

In the formula, a^{X1} and a^{X2} each independently represent an integer of 0 or more. Ar^{X1} and Ar^{X3} each idependently represent an arylene group or a divalent heterocyclic group, and these groups each may have a substituent. Ar^{X2} and Ar^{X4} each independently represent an arylene group, a divalent heterocyclic group or a divalent group formed by direct bonding between at least one kind of arylene group and at least one kind of divalent heterocyclic group, and these groups each may have a substituent. R^{X1}, R^{X2} and R^{X3} each independently represent a hydrogen atom, an alkyl group, an aryl group or a monovalent heterocyclic group, and these groups may have a substituent.

a^{X1} is preferably 2 or less and more preferably 1, since luminance lifetime of a light emitting device using a compound of a polymer host and a phosphorescent material is excellent.

a^{X2} is preferably 2 or less and more preferably 0, since the luminance lifetime of the light emitting device using a compound of a polymer host and a phosphorescent material is excellent.

R^{X1}, R^{X2} and R^{X3} are preferably an alkyl group, an aryl group or a monovalent heterocyclic group, and more preferably an aryl group, and these groups may have a substituent.

As the arylene groups represented by Ar^{X1} and Ar^{X3}, particularly preferred is a group represented by formula (A-1) or formula (A-9), and especially preferred is a group represented by formula (A-1), and these groups may have a substituent.

As the divalent heterocyclic groups represented by Ar^{X1} and Ar^{X3}, particularly preferred is a group represented by formula (A-21), formula (A-22) or formulae (A-27) to (A-46), and these groups may have a substituent.

Ar^{X1} and Ar^{X3} are preferably arylene groups optionally having a substituent.

As the arylene groups represented by Ar^{X2} and Ar^{X4}, particularly preferred is a group represented by formula (A-1), formula (A-6), formula (A-7), formulae (A-9) to (A-11) or formula (A-19), and these groups may have a substituent.

Particularly preferred ranges of divalent heterocyclic groups represented by Ar^{X2} and Ar^{X4} is the same as the particularly preferred ranges of the divalent heterocyclic groups represented by Ar^{X1} Ar^{X3}.

In the divalent groups represented by Ar^{X2} and Ar^{X4}, formed by direct bonding between at least one kind of arylene group and at least one kind of divalent heterocyclic group, a particularly preferred range and an especially preferred range of the arylene group and those of the divalent heterocyclic group are the same as the particularly preferred range and especially preferred range of the arylene group and those of the divalent heterocyclic group, represented by Ar^{X1} and Ar^{X3}, respectively.

Examples of the divalent groups formed by direct bonding between at least one kind of arylene group and at least one kind of divalent heterocyclic group represented by Ar^{X2} and Ar^{X4} include those same as the divalent group formed by direct bonding between at least one kind of arylene group and at least one kind of divalent heterocyclic group represented by Ar^{Y1}.

Ar^{X2} and Ar^{X4} are preferably arylene groups each optionally having a substituent.

An optional substituent of the groups represented by Ar^{X1} to Ar^{X4} and R^{X1} R^{X3} is preferably an alkyl group, and these groups may further have a substituent.

The constitutional unit represented by formula (X) is preferably a constitutional unit represented by formulae (X-1) to (X-7), more preferably a constitutional unit represented by formulae (X-1) to (X-6) and further preferably a constitutional unit represented by formulae (X-3) to (X-6).

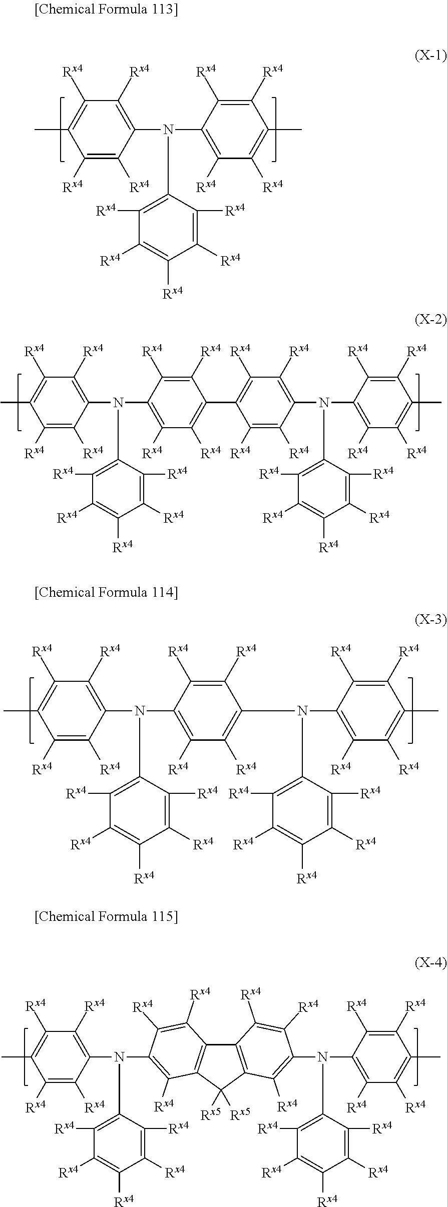

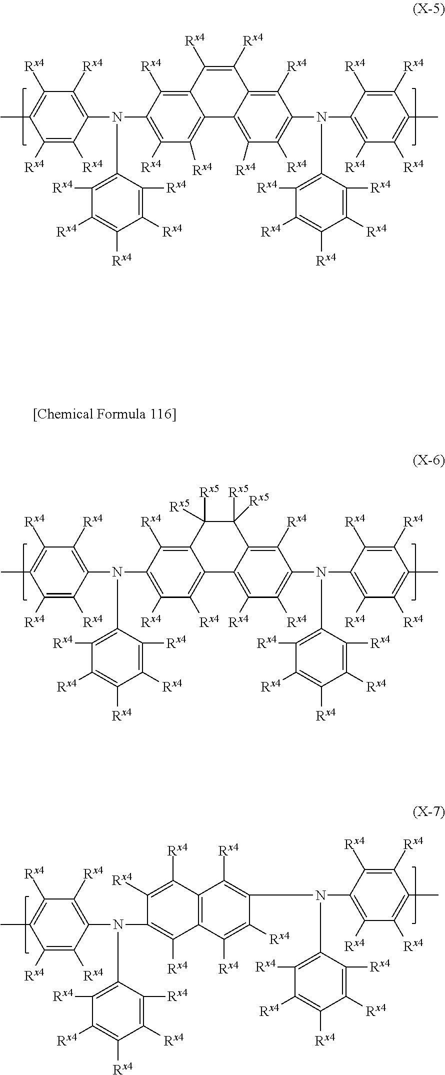

In the formulae, R^{X4} and R^{X5} each independently represent a hydrogen atom, an alkyl group, an alkoxy group, an aryl group, an aryloxy group, a halogen atom, a monovalent heterocyclic group or a cyano group, and these groups may have a substituent. A plurality of R^{X4}s may be the same or different from each other. A plurality of R^{X5}s may be the same or different from each other. Adjacent R^{X5}s may be combined with each other to form a ring together with the carbon atoms with which each of them combines.

The constitutional unit represented by formula (X) has excellent hole transporting properties, thus is preferably from 0 to 50% by mol, more preferably from 1 to 40% by mol, and further preferably from 5 to 30% by mol, based on the total amount of constitutional units included in a polymer host. [0316]

The constitutional unit represented by formula (X) includes, for example, a constitutional unit represented by formulae (X1-1) to (X1-11), and is preferably a constitutional unit represented by formulae (X1-1) to (X1-10).

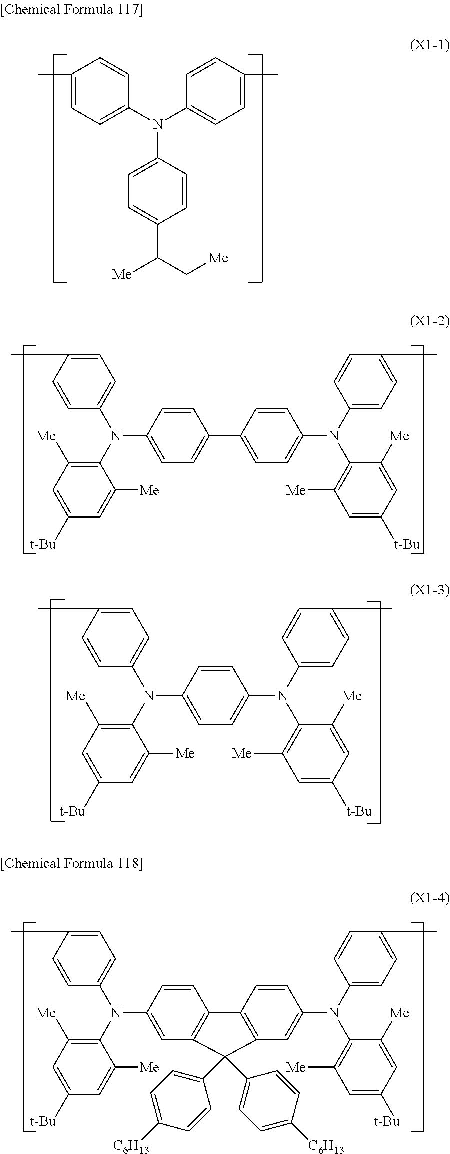

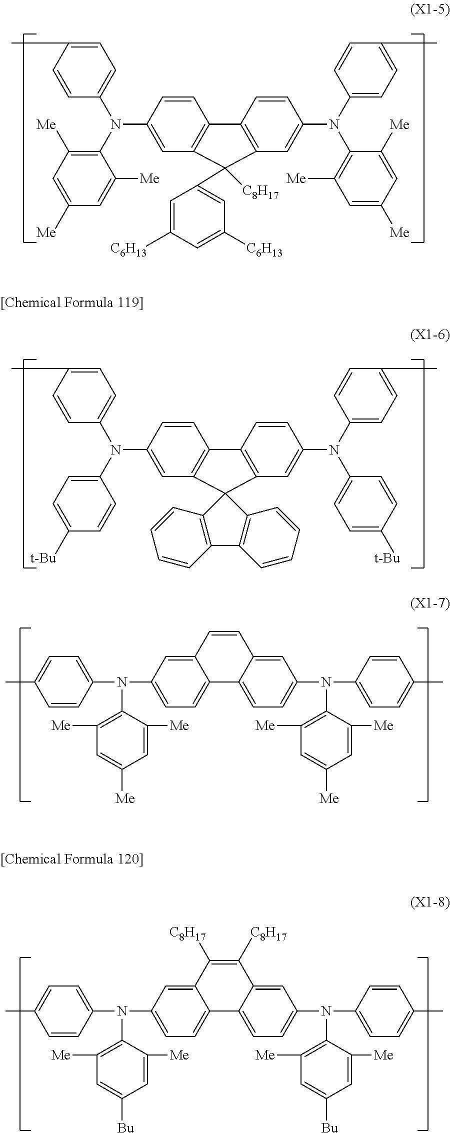

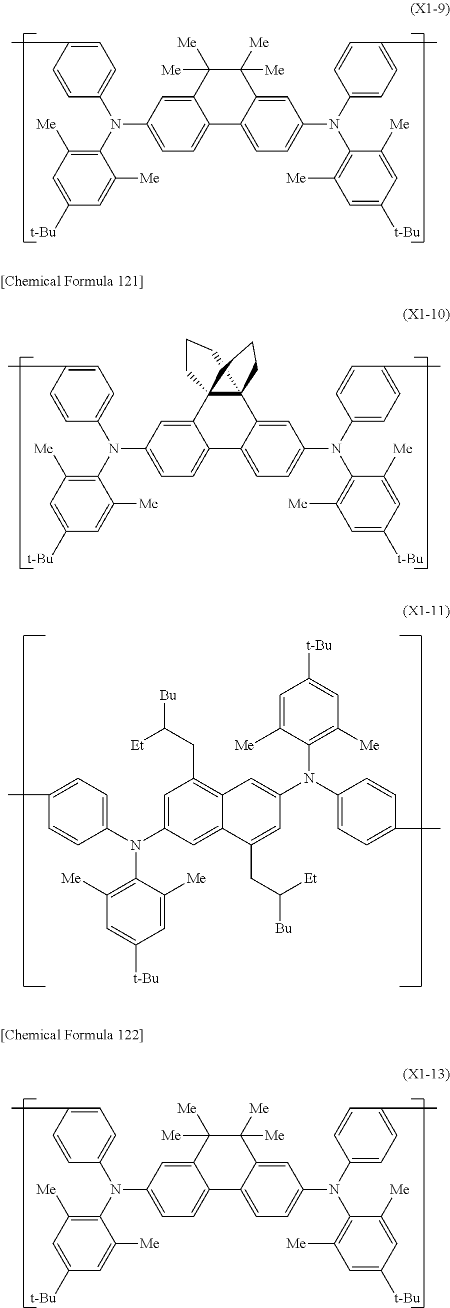

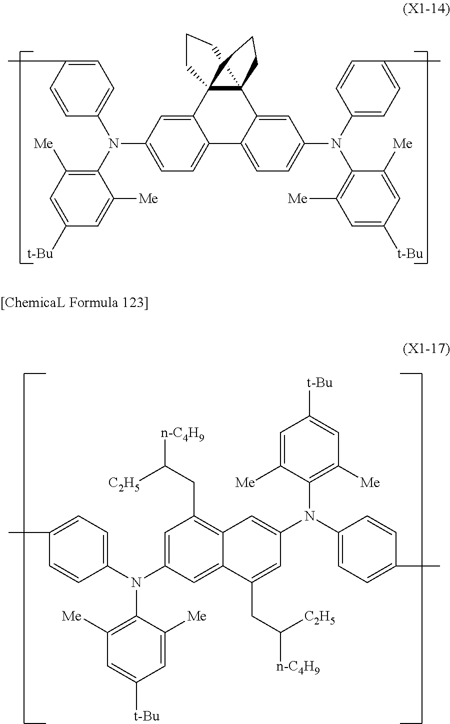

In the polymer host, only one kind of the constitutional unit represented by formula (X) may be included, or two or more kinds may be included.

Examples of the polymer host include polymer compounds P-1 to P-6 in Table 1 below. Here, “other” constitutional units mean constitutional units other than the constitutional unit represented by formula (Y) and the constitutional unit represented by formula (X).

TABLE 1

| | Constitutional unit and molar ratio thereof | | | | |
|---|---|---|---|---|---|
| | Formula (Y) | | | Formula (X) | |
| | Formula | Formula | Formula | Formula | |
| | (Y-1)-Formula | (Y-4)-Formula | (Y-8)-Formula | (X-1)-Formula | |
| | (Y-3) | (Y-7) | (Y-10) | (X-7) | Other |
| Polymer host | p | q | r | s | t |
| P-1 | 0.1-99.9 | 0.1-99.9 | 0 | 0 | 0-30 |
| P-2 | 0.1-99.9 | 0 | 0.1-99.9 | 0 | 0-30 |
| P-3 | 0.1-99.8 | 0.1-99.8 | 0 | 0.1-99.8 | 0-30 |
| P-4 | 0.1-99.8 | 0.1-99.8 | 0.1-99.8 | 0 | 0-30 |
| P-5 | 0.1-99.8 | 0 | 0.1-99.8 | 0.1-99.8 | 0-30 |
| P-6 | 0.1-99.7 | 0.1-99.7 | 0.1-99.7 | 0.1-99.7 | 0-30 |

In the table, p, q, r, s and t show molar ratios of each constitutional unit. p+q+r+s+t=100, and 100≧p+q+r+s≧70. Other constitutional units mean constitutional units other than the constitutional unit represented by formula (Y) and the constitutional unit represented by formula (X).

The polymer host may be any of a block copolymer, a random copolymer, an alternate copolymer and a graft copolymer, and may also be another embodiment. From the above viewpoints, the polymer host is preferably a copolymer obtained by copolymerizing plural kinds of raw material monomers.

### <Method for Producing Polymer Host>

A polymer host may be produced using a known polymerization method described in Chem. Rev., vol. 109, pages 897 to 1091, (2009) , and polymerization methods by a coupling reaction using a transition metal catalyst, such as Suzuki reaction, Yamamoto reaction, Buchwald reaction, Stile reaction, Negishi reaction, Kumada reaction, are exemplified.

In the polymerization method, examples of the method for charging monomers include a method of charging whole amount of monomers in a mass in a reaction system, a method of charging a part of monomers to react, then charging remaining monomers in a mass, continuously or dividedly, a method of charging monomers continuously or dividedly.

The liquid composition for an organic electroluminescent device (hereinafter, may be referred to as “ink”) used in the present invention is suitable for manufacture of a light emitting device using a printing method such as an inkjet printing method, a nozzle printing method and the like.

Viscosity of the ink may advantageously be adjusted depending on a kind of a printing method, and when a solution goes through a jetting apparatus such as in an inkjet printing method and the like, viscosity of the ink is preferably in a range of from 1 to 20 mPa·s at 25° C. for preventing clogging in jetting and flight deflection.

In the ink, the compounding amount of a solvent is usually from 1000 to 100000 parts by weight, and preferably from 2000 to 20000 parts by weight, based on 100 parts by weight of a phosphorescent material.

[Hole Transporting Material]

Hole transporting materials are classified into small molecule compounds and polymer compounds. As the hole transporting material, a polymer compound is preferable, and a polymer compound having a crosslink group is more preferable.

Examples of the polymer compound include polyvinylcarbazole and derivatives thereof; polyarylene having an aromatic amine structure in its side chain or main chain and derivatives thereof. The polymer compound may also be a compound in which an electron accepting portion is linked. The electron accepting portion includes, for example, fullerene, tetrafluorotetracyanoquinodimethane, tetracyanoethylene, trinitrofluorenone, and is preferably fullerene.

In the composition of the present invention, the compounding amount of the hole transporting material is usually from 1 to 400 parts by weight, and preferably from 5 to 150 parts by weight, based on 100 parts by weight of the phosphorescent material.

As the hole transporting material, one single kind of hole transporting material may be used, or two kinds or more may be used in combination.

### [Electron Transporting Material]

Electron transporting materials are classified into small molecule compounds and polymer compounds. The electron transporting material may have a crosslink group.

Examples of the small molecule compounds include a metal complex having 8-hydroxyquinoline as a ligand, oxadiazole, anthraquinodimethane, benzoquinone, naphthoquinone, anthraquinone, tetracyanoanthraquinodimethane, fluorenone, diphenyldicyanoethylene, diphenoquinone and derivatives thereof.

Examples of the polymer compounds include polyphenylene, polyfluorene and derivatives thereof. The polymer compounds may have been doped with a metal.

In the composition of the present invention, the compounding amount of the electron transporting material is usually from 1 to 400 parts by weight, and preferably from 5 to 150 parts by weight, based on 100 parts by weight of the phosphorescent material.

As the electron transporting material, one single kind of electron transporting material may be used, or two kinds or more may be used in combination.

[Hole Injecting Material and Electron Injecting Material]Hole injecting materials and electron injecting materials are each classified into small molecule compounds and polymer compounds. The hole injecting material and the electron injecting material each may have a crosslink group.

Examples of the small molecule compounds include metal phthalocyanines such as copper phthalocyanine ; carbon; oxides of metals such as molybdenum, tungsten ; and metal fluorides such as lithium fluoride, sodium fluoride, cesium fluoride, potassium fluoride.

Examples of the polymer compounds include polyaniline, polythiophene, polypyrrole, polyphenylenevinylene, polythienylenevinylene, polyquinoline and polyquinoxaline, and derivatives thereof, and electrically conductive polymers such as a polymer including a group represented by formula (X) in the main chain or side chain.

In the composition of the present invention, the compounding amounts of the hole injecting material and the electron injecting material are each usually from 1 to 400 parts by weight, and preferably from 5 to 150 parts by weight, based on 100 parts by weight of the phosphorescent material.

As the hole injecting material and the electron injecting material, one single kind of each may be used alone or two kinds or more of each may be used in combination.

[Ion Doping]

When the hole injecting material or the electron injecting material includes an electrically conductive polymer, electric conductivity of the electrically conductive polymer is preferably from 1×10⁻⁵ S/cm to 1×10³ S/cm. For adjusting electric conductivity of the electrically conductive polymer within such a range, the electrically conductive polymer may be doped with a suitable amount of ions.

The kind of an ion to be doped is an anion for a hole injecting material and a cation for an electron injecting material. Examples of the anion include a polystyrenesulfonate ion, an alkylbenzenesulfonate ion and a camphorsulfonate ion. Examples of the cation include a lithium ion, a sodium ion, a potassium ion and a tetrabutylammonium ion.

The ion to be doped may be one single kind or two kinds or more.

### [Antioxidant]

An antioxidant may advantageously be a compound that is soluble in the same solvent used for the phosphorescent material and that does not disturb light emission and charge transportation, and examples thereof include a phenol antioxidant and a phosphorus-based antioxidant.

In the composition of the present invention, the compounding amount of an antioxidant is usually from 0.001 to 10 parts by weight, based on 100 parts by weight of the phosphorescent material.

As the antioxidant, one single kind antioxidant may be used or two kinds or more may be used in combination.

<Polymer Compound Using Metal Complex that is Phosphorescent Material as Constitutional Unit>

A phosphorescent material included in the liquid composition of the present invention may be a polymer compound including a complex structure represented by formula (11). Here, the polymer compound denotes a compound having a polystyrene-equivalent molecular weight of 1000 or more and having molecular weight distribution. The polymer compound including a phosphorescent complex structure preferably includes a constitutional unit of a polymer compound used in an organic compound that is solid at 1 atm and 25° C. described above, and more preferably includes a structure represented by formula (Y). In the polymer compound, a group obtained by removing one or two hydrogen atoms from a complex structure represented by formula (11) may be bonded to the main chain or side chain of the polymer compound directly or through a divalent group as a spacer. Examples of the divalent group as a spacer include an optionally substituted alkylene group, arylene group and divalent heterocyclic group, and a substituted alkylene group and an arylene group are preferred. Examples of the optional substituent of an alkylene group include an alkyl group, an alkoxy group, an aryl group, an aryloxy group, an arylalkyl group, an arylalkoxy group, an arylalkenyl group, an arylalkynyl group, an arylamino group and a monovalent heterocyclic group, and an alkyl group, an alkoxy group, an aryl group and an aryloxy group are preferred.

An atmosphere in the container may be an atmosphere including an inert gas. The atmosphere may be an air atmosphere, or may be an atmosphere in which concentration of an inert gas in the atmosphere is not less than concentration of the inert gas included in an air atmosphere. Furthermore, concentration of the inert gas in the atmosphere may be not less than 99% in a volume ratio. Examples of an inert gas may include helium gas, argon gas, nitrogen gas, mixed gases thereof.

Temperature for storage of a sealed container itself storing a liquid composition is different according to the boiling point of an organic solvent included in the liquid composition, and the sealed container itself may be stored at temperature lower than the boiling point of the organic solvent. From a viewpoint of stability of the liquid composition, temperature is preferably −20° C. or more and 50° C. or less, and more preferably 0° C. or more and 50° C. or less.

### <Method for Producing Liquid Composition for Organic Electroluminescent Device>

The liquid composition of the present invention is produced by dissolving a phosphorescent material, and a second material for a light emitting layer and an additive as necessary, in a solvent. Charging order of a solvent, a phosphorescent material, a second material for a light emitting layer and an additive in a dissolution process is not particularly limited.

Production work environment is not particularly restricted, but since it is difficult to work in a dark place, the production work is preferably performed under a light source. In order to minimize deterioration and functional degradation of the liquid composition for an organic electroluminescent device, it is preferred to work under a yellow light source.

A dissolution container uses a material that reduces light for an outer wall portion and that has excellent chemical stability for an inner wall portion. Specific examples include a brown glass, a metal that is not dissolved in an organic solvent, a light-shielding container in which inner wall is a resin having a fluorine atom, plastics that is not dissolved in an organic solvent. Among them, the dissolution container is preferably a brown glass or a stainless container, and more preferably a stainless container.

Dissolution of the phosphorescent material in a solvent may be carried out under the atmosphere, or may be carried out under an inert gas atmosphere. Dissolution of the phosphorescent material in a solvent may be promoted by using a stirring blade, a stirrer, a shaker, a homogenizer, an ultrasonic generator and it is preferred to dissolve the phosphorescent material in a solvent while stirring with a stirring blade. Dissolution temperature is usually from −20° C. to a boiling point of the solvent, preferably from 0° C. to 80° C. and more preferably from 20° C. to 60° C. Dissolution time is usually from 5 minutes to 1 week, and preferably from 30 minutes to 3 days.

After confirming dissolution of the phosphorescent material in the solvent, filtration is performed, as necessary, for removing particles that may cause a defect of properties of an organic EL device manufactured using the liquid composition of the present invention, and the liquid composition is filled in the container. Examples of filtration include natural filtration, filtration under reduced pressure and pressure filtration, and pressure filtration is preferred. Examples of filter medium include a filter paper, a filter cloth, a sintered metal filter and a membrane filter. A membrane filter is preferred, and polytetrafluoroethylene (PTFE) membrane filter is more preferred. As a filter device when using a membrane filter, any of a flat membrane filter, a capsule filter and a cartridge filter is usable. As opening of a filter medium, usually, a filter medium with a pore size of 2 μm or less is used, it is preferred to use a filter medium with a pore size of 0.5 μm or less, and it is more preferred to use a filter medium with a pore size of 0.2 μm or less.

### <Storage Method and Use Method of Liquid Composition for Organic Electroluminescent Device>

When reducing the amount of exposure to yellow light, deterioration of the liquid composition for an organic electroluminescent device is delayed, and storage lifetime, or usable period is extended. Therefore, the liquid composition for an organic electroluminescent device is preferably stored in an environment with less exposure to yellow light. More preferably, the liquid composition for an organic electroluminescent device is stored in an environment in which yellow light is shut out.

Also, when film forming or function layer formation is performed by using a coating method, the liquid composition for an organic electroluminescent device is preferably stored in an environment with less exposure to yellow light until just before coating. As a means for that, for example, transmission of yellow light may be suppressed or shaded, as to a tank that stores a liquid composition for an organic electroluminescent device, equipped with a coating machine, or a piping that transports a liquid composition for an organic electroluminescent device.

### <Yellow Light>

Light having wavelength corresponding to yellow is a light having a wavelength component of from 500 nm to 780 nm. The light having a wavelength component of from 500 nm to 780 nm is obtained by sticking a colored film that absorbs light of wavelength region of from 380 nm to 500 urn (for example, “Lumicool 1905” (trade name) manufactured by Lintec Corporation) on a fluorescent lamp, by using a colored fluorescent lamp, or the like. From a viewpoint of stability of a liquid composition for an organic electroluminescent device, the maximum emission intensity at 380 nm to 500 nm is preferably 1/20 or less of the maximum emission intensity at 500 nm to 780 nm. (Such a light source includes, for example, moth-repelling fluorescent lamp FL20S-Y-F from Panasonic (National).) More preferably, a lamp in which light at 380 nm to 500 nm is shaded is used. (Such a light source includes, for example, fluorescent lamp with a scattering prevention film for a semiconductor factory FLR40S-Y-F/M-P from Panasonic (National).)

As a measure of confirming a degree of deterioration of a liquid composition for an organic electroluminescent device, the product of illuminance E (lm/m²) of light having a wavelength component of from 500 nm to 780 nm exposed to the liquid composition and irradiation time t (sec) of the light exposed to the liquid composition may be used. Hereinbelow, this value may be referred to as E×t value. Here, illuminance refers to a psychological physical amount representing brightness of light irradiated to a plane-shaped object. Also, in a case where a container and a packaging material that transmit light having a wavelength component of from 500 nm to 780 nm are used, illuminance may be obtained as the product of transmittance and illuminance before passing the container and the packaging material.

From a viewpoint of efficiency and lifetime of a light emitting device, E×t value is preferably 2.0×10³ or more and 4.8×10⁷ (sec·lm/m²) or less, more preferably 2.0×10³ or more and 2.0×10⁷ (sec·lm/m²) or less, further preferably 2.0×10³ or more and 9.9×10⁶ (sec·lm/m²) or less, far more preferably 2.0×10³ or more and 2.0×10⁶ (sec·lm/m²) or less and particularly preferably 2.0×10⁵ or more and 2.0×10⁶ (sec·lm/m²) or less.

<Film>

A film includes a phosphorescent material.

The film also comprises an insolubilized film obtained by insolubilizing a phosphorescent material in a solvent by cross-linkage. An insolubilized film is a film obtained by cross-linking a phosphorescent material by external stimulation such as heating, light irradiation. The insolubilized film may be suitably used for layering of a light emitting device because the film is substantially insoluble in a solvent.

Heating temperature for cross-linking a film is usually from 25 to 300° C., and because external quantum yield is improved, preferably from 50 to 250° C., and more preferably from 150 to 200° C.

The kind of light used in light irradiation for cross-linking the film includes, for example, ultraviolet light, near-ultraviolet light and visible light.

The film is suitable as a hole transporting layer or a light emitting layer in a light emitting device.

The film may be prepared, using the ink, for example, by a spin coating method, a casting method, a micro gravure coating method, a gravure coating method, a bar coating method, a roll coating method, a wire bar coating method, a dip coating method, a spray coating method, a screen printing method, a flexo printing method, an offset printing method, an inkjet printing method, a capillary coating method or a nozzle coating method.

Thickness of the film is usually from 1 nm to 10 μm.

<Light Emitting Device>

A light emitting device of the present invention is a light emitting device obtained by using a phosphorescent material, and may be a light emitting device in which a phosphorescent material is cross-linked intramolecularly or intermolecularly, or a light emitting device in which a phosphorescent material is cross-linked intramolecularly and intermolecularly.

As the constitution, for example, the light emitting device of the present invention has electrodes comprising an anode and a cathode, and a layer obtained by using a phosphorescent material disposed between the electrodes.

[Layer Constitution]

A layer obtained by using a phosphorescent material is usually a layer of one or more kinds of a light emitting layer, a hole transporting layer, a hole injecting layer, an electron transporting layer and an electron injecting layer, and is preferably a light emitting layer. These layers contain a light emitting material, a hole transporting material, a hole injecting material, an electron transporting material and an electron injecting material, respectively. These layers may be formed by dissolving a light emitting material, a hole transporting material, a hole injecting material, an electron transporting material and an electron injecting material in the solvent described above to prepare inks, respectively, and applying the inks using the same method as the above-described film preparation.

A light emitting device has a light emitting layer between an anode and a cathode. The light emitting device of the present invention preferably has at least one layer of a hole injecting layer and a hole transporting layer between an anode and a light emitting layer from viewpoints of hole injectability and of hole transportability, and preferably has at least one layer of an electron injecting layer and an electron transporting layer between a cathode and a light emitting layer from viewpoints of electron injectability and of electron transportability.

Materials of a hole transporting layer, an electron transporting layer, a light emitting layer, a hole injecting layer and an electron injecting layer include the above-described hole transporting material, electron transporting material, light emitting material, hole injecting material and electron injecting material, respectively, in addition to the phosphorescent material.

When the material of a hole transporting layer, the material of an electron transporting layer and the material of a light emitting layer are soluble in a solvent that is used in forming a layer adjacent to the hole transporting layer, the electron transporting layer and the light emitting layer, respectively, in manufacture of a light emitting device, it is preferable that the materials have a crosslink group to avoid dissolution of the materials in the solvent. After forming the layers using the materials having a crosslink group, the layers may be insolubilized by cross-linking the crosslink group.

Methods of forming respective layers such as a light emitting layer, a hole transporting layer, an electron transporting layer, a hole injecting layer, an electron injecting layer in the light emitting device of the present invention include, for example, a method of vacuum vapor deposition from a powder and a method of film formation from solution or melted state when a small molecule compound is used, and, for example, a method of film formation from solution or melted state when a polymer compound is used.

Order and the number of layers to be layered and thickness of each layer may advantageously be controlled in view of external quantum yield and device lifetime.

[Substrate/Electrode]

The substrate in the light emitting device may advantageously be a substrate on which an electrode may be formed and which does not chemically change in forming an organic layer, and is a substrate made of a material such as, for example, glass, plastic, silicon. In a case of an opaque substrate, it is preferred that an electrode most remote from the substrate is transparent or semi-transparent.

The material of an anode includes, for example, an electrically conductive metal oxide and a semi-transparent metal, and preferably, an indium oxide, a zinc oxide and a tin oxide; an electrically conductive compound such as indium-tin-oxide (ITO), indium-zinc-oxide; a composite of silver, palladium and copper (APC); NESA, gold, platinum, silver and copper.

The material of a cathode includes, for example, metal such as lithium, sodium, potassium, rubidium, cesium, beryllium, magnesium, calcium, strontium, barium, aluminum, zinc, indium ; an alloy composed of two or more of these metals; an alloy composed of one or more of these metals and at least one of silver, copper, manganese, titanium, cobalt, nickel, tungsten and tin; and graphite and a graphite intercalation compound. The alloy includes, for example, a magnesium-silver alloy, a magnesium-indium alloy, a magnesium-aluminum alloy, an indium-silver alloy, a lithium-aluminum alloy, a lithium-magnesium alloy, a lithium-indium alloy and a calcium-aluminum alloy.

The anode and the cathode may each take a layered structure composed of two or more layers.

[Use]

For obtaining planar light emission using a light emitting device, it may be advantageous that a planar anode and a planar cathode are disposed so as to overlap. Methods for obtaining light emission in a form of a pattern are a method in which a mask having a window in a form of a pattern is placed on the surface of a planer light emitting device, a method in which a layer intended as a non-light emitting part is formed to be extremely thick to give substantially no emission, and a method in which an anode or a cathode or both electrodes are formed in a form of a pattern. By forming a pattern by any of these methods and by disposing several electrodes so that the electrodes may be independently turned ON/OFF, a segment type display device capable of displaying numbers and letters is obtained. For obtaining a dot matrix display device, it may be advantageous that both an anode and a cathode are formed in forms of stripes and disposed so as to cross each other. Partial color display and multi-color display are made possible by a method in which several kinds of polymer compounds showing different emission colors are painted separately and a method of using a color filter or a fluorescence conversion filter. The dot matrix display device may be also passively driven, or actively driven combined with TFT. These display devices may be used in displays of computers, television, portable terminals. The planar light emitting device may be suitably used as a planer light source for backlight of a liquid display device, or as a planar light source for illumination. When a flexible substrate is used, it may be used also as a curved light source and a curved display device.

### EXAMPLES

The present invention is described in further detail below by examples, but the present invention is not limited to the examples.

In the examples, weight-average molecular weight (Mw) and number-average molecular weight (Mn) of a polymer compound were obtained as polystyrene equivalent weight-average molecular weight and polystyrene equivalent number-average molecular weight by using gel permeation chromatography (GPC) (HLC-8220GPC, manufactured by Tosoh Corporation). A sample to be measured was dissolved in tetrahydrofuran so as to have a concentration of about 0.5% by weight, and 50 μL thereof was injected into GPC. Tetrahydrofuran was used as a mobile phase of GPC, and flown at a flow rate of 0.5 mlimin. PLgel MIXED-B (manufactured by Polymer Laboratories) was used as a column, and a UV-VIS detector was used as a detector.

Illuminance was measured by the following method.

For conducting measurement in such conditions that the illuminance to be received becomes equal to that of the surface of the liquid composition for an organic electroluminescent device, an illuminometer (HIOKI lux HI TESTER 3421 (trade name, manufactured by Hioki E.E. CORPORATION) was placed in the same place as the liquid surface, and a soda-lime glass lid of a petri dish as a test container, in which a liquid composition was contained, was put on a light detection part, and illuminance was measured.

### Synthesis Example 1

### Synthesis of N,N′-bis(4-bromophenyl)-N,N′-bis(4-tert-butyl-2,6-dimethylphenyl)1,4-phenylenediamine

Monomer N,N′-bis(4-bromophenyl)-N,N′-bis(4-tert-butyl-2,6-dimethylphenyl)01,4-phenylenediamine was synthesized according to the method described in Japanese Patent Laid-open Publication No. 2004-143419.

### Synthesis Example 2

### Synthesis of 2,7-bis(4,4,5,5-tetramethyl-1,3,2-dioxaborolan-2-yl)-9,9-di(4-hexylphenyl)fluorene

Monomer 2,7-bis(4,4,5,5-tetramethyl-1,3,2-dioxaborolan-2-yl)-9,9-di(4-hexylphenyl)fluorene was synthesized according to the method described in WO 2012/86671.

### Synthesis Example 3

### Synthesis of Polymer Compound 1

The inside of a reactor vessel was replaced with an inert atmosphere, then 2,7-dibromo-9,9-di(octyl)fluorene ((commercial product) 9.0 g), N,N′-bis(4-bromop henyl)-N,N′-bis(4-tert-butyl-2, 6-dimethylphenyl) 1, 4-phenylenediamine (1.3 g), 2, 7-bis(4, 4,5,5-tetra methyl-1,3, 2-dioxaborolan-2-yl)-9, 9-di(4-hexylphenyl)fluorene (13.4 g), tetraethylammonium hydroxide (43.0 g), palladium acetate (8 mg), tri(2-methoxyphenyl)phosphine (0.05 g) and toluene (200 mL) were mixed, and the resulting mixture was heated and stirred at 90° C. for 8 hours. Subsequently, phenylboronic acid (0.22 g) was added, and the resulting mixture was stirred for 14 hours. After cooling the mixture, the aqueous layer was removed, and an aqueous sodium diethyldithiocarbamate solution was added thereto and stirred. Thereafter, the aqueous layer was removed, and the organic layer was washed with water and 3% by weight of aqueous acetic acid. The organic layer was poured to methanol to precipitate a solid, then the filtered solid was again dissolved in toluene, and the solution was passed through a column of silica gel and alumina. The eluted toluene solution including the solid was collected, and the collected toluene solution was poured into methanol to precipitate a solid. The precipitated solid was vacuum dried at 50° C. to obtain a light-emitting polymer material (12.5 g). According to the gel permeation chromatography, polystyrene-equivalent weight average molecular weight of the resulting light-emitting polymer material was 3.1×10⁵.

### Synthesis Example 4

### Synthesis of Phosphorescent Material

The phosphorescent material was synthesized according to the method described in Japanese Patent Laid-open Publication No. 2006-188673.

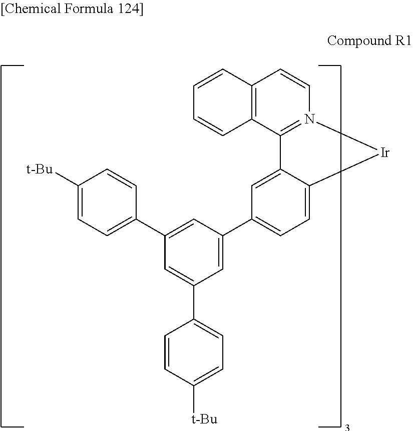

The maximum peak wavelength of the emission spectrum of compound R1 was 619 nm. Also, the maximum peak wavelength of the UV absorption spectrum was 289 nm, and the absorption edge thereof was 736 nm.

### Synthesis Example 5

### Synthesis of Polymer Compound 2

Polymer compound 2 is a copolymer having constitutional units represented by the following formulae H1, H2, H3, H4 at a molar ratio of 50:30:12.5:7.5, and was synthesized according to the method described in Japanese Patent Laid-open Publication No. 2012-144722.

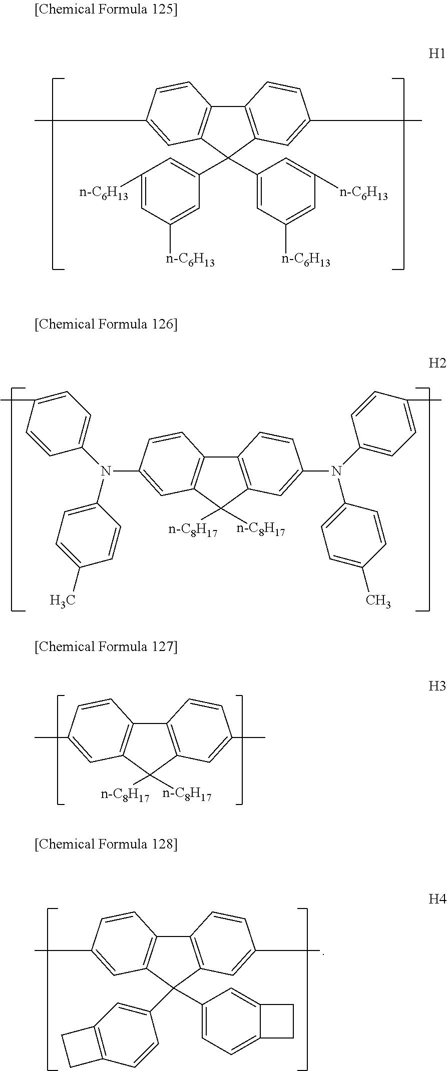

### Example 1

### (Preparation of Liquid Composition 1)

Under an air atmosphere, 119 parts by weight of the polymer compound, 1 part by weight of the phosphorescent material (compound R1) and 980 parts by weight of cyclohexylbenzene were put in a brown glass container and mixed, then dissolved at room temperature in a shading state with an aluminum foil to obtain liquid composition 1.

### Example 2

### (Preparation of Liquid Composition 2)

Liquid composition 1 was filled in a brown bottle, and the brown bottle was shaded with an aluminum foil.

Preparation of liquid composition 2 from liquid composition 1 was worked under yellow light (fluorescent lamp FLR40S-Y-F/M-P (manufactured by Panasonic)), then the illuminance, that the liquid surface had received, was 550 lm/m², and the irradiated time was totally 0.10 hour. The wavelength component of the yellow light was from 500 nm to 780 nm. After irradiation, the liquid composition was filled in a brown bottle, and the brown bottle was shaded with an aluminum foil and stored for 71.90 hours to obtain liquid composition 2.

The E×t value of liquid composition 2 at that time was 2.0×10⁵ (sec·lm/m²).

### Example D1

### (Manufacture and Evaluation of Light Emitting Device D1)

On a glass substrate carrying thereon an ITO film with a thickness of 45 nm formed by a sputtering method, a mixed solution of polythiophenesulfonic acid in ethylene glycol monobutyl ether/water=3/2 (volume ratio) (Sigma Aldrich, trade name: Plexcore OC 1200) was spin-coated to form a film with a thickness of 50 nm, that was then dried on a hot plate at 170° C. for 15 minutes to form a hole injection layer.

Next, polymer compound 2 was dissolved in xylene to prepare 0.65% by weight xylene solution. This xylene solution was spin-coated on the above-described glass substrate having the hole injection layer formed thereon, to form an organic thin film of polymer compound 2 with a thickness of 20 nm. This was heated on a hot plate at 180° C. for 60 minutes, in a nitrogen gas atmosphere having an oxygen concentration and a moisture concentration, both of which were 10 ppm or less (weight-based), to form a hole transporting layer as an insolubilized organic thin film.

Next, liquid compound 2 was spin-coated on the above-described glass substrate having the hole transporting layer formed thereon, to form an organic thin film having a thickness of 80 nm. This was dried by heating on a hot plate at 150° C. for 10 minutes, in a nitrogen gas atmosphere having an oxygen concentration and a moisture concentration, both of which were 10 ppm or less (weight-based), to form a light emitting layer.

Next, sodium fluoride was vapor-deposited with a thickness of about 5 nm, then aluminum was vapor-deposited with a thickness of about 80 nm, as a cathode, to manufacture light emitting device D1. After degree of vacuum reached 1×10⁻⁴ Pa or less, vapor deposition of the metal was initiated.

When voltage was applied to the resulting light emitting device D1, EL light emission showing a peak at 625 nm was obtained from this device, and the maximum current efficiency was 11 cd/A. Also, time (LT75) until the luminance became 75% of initial luminance when driven with constant current at initial luminance of 8,000 cd/m² was 107 hours.

### Example 3

### (Preparation of Liquid Composition 3)

To a soda-lime glass petri dish (diameter×height (mm): 64 mm×19 mm) was charged 15 ml of the liquid composition 1, and the petri dish was put on a black sheet. Then, yellow light (fluorescent lamp FLR40S-Y-F/M-P (manufactured by Panasonic)) was irradiated from above for 0.9 hours. After irradiation, the liquid composition was filled in a brown bottle, and the brown bottle was shaded with an aluminum foil. Since irradiation of yellow light was received for 0.1 hour in the filling work, at this time, the illuminance, that the liquid surface had received, was 550 lm/m², and the total irradiation time was 1.0 hour. Thereafter, the resulting liquid composition was stored for 71.0 hours to obtain liquid composition 3.

The E×t value of the liquid composition 3 at that time was 2.0×10⁶ (sec·lm/m²).

### Example D2

### (Manufacture and Evaluation of Light Emitting Device D2)

A light emitting device was manufactured according to the same manner as in Example D1, except that liquid composition 3 was employed instead of liquid composition 2, and evaluated. The maximum current efficiency was 11 cd/A. Also, time (LT75) until the luminance became 75% of the initial luminance when driven with constant current at an initial luminance of 8,000 cd/m² was 98 hours.

### Examples 4 to 6, Comparative Examples 1 and 2, Examples D3 to D5, and Comparative Examples CD1 and CD2

Liquid compositions 4 to 8 were prepared according to the same manner as in Example 3, except that the irradiation time of liquid compositions and the storage time after shading were changed as shown in Table 2. A light emitting device was manufactured according to the same manner as in Example D1, except that liquid compositions 4 to 8 were respectively employed instead of liquid composition 2, and evaluated. The result is shown in Table 3. The illuminance, that the liquid surface had received, was 550 lm/m² in every standard.

TABLE 2

| | | | Storage time | Illuminance | |
|---|---|---|---|---|---|
| | | Irradiation | after shading | (lm/m²) × | |
| | Liquid composition | time (h) | (h) | Irradiation time (s) | Device |
| Example 2 | Liquid composition 2 | 0.10 | 71.90 | 2.0E+05 | Example D1 |
| Example 3 | Liquid composition 3 | 1.0 | 71.0 | 2.0E+06 | Example D2 |
| Example 4 | Liquid composition 4 | 5.0 | 67.0 | 9.9E+06 | Example D3 |
| Example 5 | Liquid composition 5 | 10 | 62 | 2.0E+07 | Example D4 |
| Example 6 | Liquid composition 6 | 24 | 48 | 4.8E+07 | Example D5 |
| Comparative | Liquid composition 7 | 72 | 0 | 1.4E+08 | Comparative |
| Example 1 | | | | | Example CD1 |
| Comparative | Liquid composition 8 | 168 | 0 | 3.3E+08 | Comparative |
| Example 2 | | | | | Example CD2 |

TABLE 3

| | | Current | |
|---|---|---|---|
| | | efficiency | Lifetime LT75 (h) |
| Device | Liquid composition | (cd/A) | (@8000 cd/m²) |
| Example D1 | Liquid composition 2 | 11 | 107 |
| Example D2 | Liquid composition 3 | 11 | 98 |
| Example D3 | Liquid composition 4 | 10 | 90 |
| Example D4 | Liquid composition 5 | 10 | 84 |
| Example D5 | Liquid composition 6 | 7.9 | 58 |
| Comparative | Liquid composition 7 | 3.8 | 4.1 |
| Example CD1 | | | |
| Comparative | Liquid composition 8 | 1.8 | — |
| Example CD2 | | | |

It could be seen based on the results that, when the E×t value of the liquid composition exceeds 4.8×10⁷ (sec·lm/m²), current efficiency and the lifetime are greatly reduced. Subsequently, using this knowledge, an irradiation experiment was performed with varying transmittance.

### Example A1

### (Preparation of Liquid Composition 9)

Liquid composition 1 was filled in a brown bottle, and the brown bottle was shaded with an aluminum foil.

Preparation of liquid composition 9 from the liquid composition 1 was worked under yellow light (fluorescent lamp FLR40S-Y-F/M-P (manufactured by Panasonic)), then the illuminance, that the liquid surface had received, was 550 lm/m², and the irradiation time was totally 0.10 hour. The E×t value of liquid composition 9 at that time was 2.0×10⁵ (sec·lm/m²).

### Example DA1

### (Manufacture and Evaluation of Light Emitting Device DA1)

A light emitting device was manufactured according to the same manner as in Example D1, except that liquid composition 9 was employed instead of liquid composition 2, and evaluated. The maximum current efficiency was 11 cd/A. Also, time (LT75) until the luminance became 75% of initial luminance when driven with constant current at an initial luminance of 8,000 cd/m² was 101 hours.

### Example A2

### (Preparation of Liquid Composition 10)

To a soda-lime glass petri dish (diameter×height (mm): 64 mm×19 mm) was charged 15 ml of liquid composition 1, and the petri dish, except for the upper part, was covered with a black sheet. Thereafter, yellow light (fluorescent lamp FLR40S-Y-F/M-P (manufactured by Panasonic)) was turned on, and adjusted so that illuminance of the upper part of liquid surface was 500 lm/m². Subsequently, wide-range ultraviolet blocking films (Lumicool 1905, <manufactured by Lintec Corporation>), that were layered in advance such that transmittance of yellow light was adjusted to 1.8%, was put on the upper part, and then irradiated for 218 hours. After irradiation, the liquid composition was filled in a brown bottle, and the brown bottle was shaded with an aluminum foil, and stored to obtain liquid composition 10. The E×t value of liquid composition 10 at that time was 7.3×10⁶ (sec·lm/m²).

### Example DA2

### (Manufacture and Evaluation of Light Emitting Device DA2)

A light emitting device was manufactured according to the same manner as in Example D1, except that liquid composition 10 was employed instead of liquid composition 2, and evaluated. The maximum current efficiency was 10 cd/A. Also, time (LT75) until luminance became 75% of initial luminance when driven with constant current at an initial luminance of 8,000 cd/m² was 94 hours.

### Examples A3 and A4, Comparative Example A1, Examples DA3 and DA4, and Comparative Example CDA1

Liquid compositions 11 to 13 were prepared according to the same manner as in Example A2, except that the number of the overlapped wide-range ultraviolet blocking films was varied to change transmittance of yellow light as shown in Table 4. A light emitting device was manufactured according to the same manner as in Example D1, except that liquid compositions 11 to 13 were respectively employed instead of liquid composition 2, and evaluated. The result is shown in Table 5.

TABLE 4

| | | | | Illuminance | *Illuminance | |
|---|---|---|---|---|---|---|
| | | | | (lm/m²) | (lm/m²) × | |
| | Liquid | Transmittance | Irradiation | <Transmittance | Irradiation | |
| | composition | (%) | time (h) | Conversion> | time (s) | Device |
| Example A1 | Liquid | 0.0 | 218 | 0.0 | 2.0E+05 | Example DA1 |
| | composition 9 | | | | | |
| Example A2 | Liquid | 1.8 | ↑ | 9.0 | 7.3E+06 | Example DA2 |
| | composition 10 | | | | | |
| Example A3 | Liquid | 4.9 | ↑ | 25 | 1.9E+07 | Example DA3 |
| | composition 11 | | | | | |
| Example A4 | Liquid | 11 | ↑ | 53 | 4.2E+07 | Example DA4 |
| | composition 12 | | | | | |
| Comparative | Liquid | 29 | ↑ | 143 | 1.1E+08 | Comparative |
| Example A1 | composition 13 | | | | | Example CDA1 |

*Illuminance (lm/m²) × Irradiation time (s): Also including a time to be irradiated from preparation of the liquid composition 1, through filling each liquid composition in a brown glass sample bottle, and covering the entire bottle with an aluminum foil to be completely shaded.

TABLE 5

| | | Current | |
|---|---|---|---|
| | | efficiency | Lifetime LT75 (h) |
| Device | Liquid composition | (cd/A) | (@8000 cd/m²) |
| Example DA1 | Liquid | 11 | 101 |
| | composition 9 | | |
| Example DA2 | Liquid | 10 | 94 |
| | composition 10 | | |
| Example DA3 | Liquid | 9.7 | 89 |
| | composition 11 | | |
| Example DA4 | Liquid | 8.0 | 62 |
| | composition 12 | | |
| Comparative | Liquid | 5.1 | 12 |
| Example CDA1 | composition 13 | | |

Comparative examples in the above results were assumed that transmittance of light of the brown glass was from 20 to 30%. On the other hand, it was found that, when transmittance was 15% or less, reduction in current efficiency and reduction in lifetime were remarkably small. Accordingly, the liquid composition for an organic electroluminescent device including a phosphorescent material and a solvent of the invention of the present application is stored with a container alone or combined therewith a wrapping material in the state that transmittance of light having a wavelength component of from 500 nm to 780 nm is 15% or less, and preferably 10% or less, whereby reduction in current efficiency and reduction in lifetime is able to be remarkably restricted.

### Comparative Example B1

### (Preparation of Liquid Composition 14)

Under an air atmosphere, 12 parts by weight of polymer compound 1, and 98 parts by weight of cyclohexylbenzene were put in a brown glass container and mixed, then dissolved at room temperature in a shading state with an aluminum foil to obtain liquid composition 14.

### Comparative Example B2

### (Preparation of Liquid Composition 15)

Liquid composition 14 was filled in a brown bottle, and the brown bottle was shaded with an aluminum foil.

Preparation of liquid composition 15 from liquid composition 14 was worked under yellow light (fluorescent lamp FLR40S-Y-F/M-P (manufactured by Panasonic)), then the illuminance, that the liquid surface had received, was 550 lm/m², and irradiated time was totally 0.10 hour. After irradiation, the liquid composition was filled in a brown bottle, and the brown bottle was shaded with an aluminum foil and stored for 77.90 hours to obtain liquid composition 15. The E×t value of liquid composition 15 at that time was 2.0×10⁵ (sec·lm/m²).

### Comparative Example B3

### (Preparation of Liquid Composition 16)

To a soda-lime glass petri dish (diameter×height (mm): 64 mm×19 mm) was charged 15 ml of liquid composition 14, and the petri dish was put on a black sheet. Then, yellow light (fluorescent lamp FLR40S-Y-F/M-P (manufactured by Panasonic)) was irradiated from above for 78 hours. After irradiation, the liquid composition was filled in a brown bottle, and the brown bottle was shaded with an aluminum foil to obtain liquid composition 16. The E×t value of liquid composition 16 at that time was 1.4×10⁸ (sec·lm/m²).

### Comparative Example DB1

### (Manufacture and Evaluation of Light Emitting Device DB1)

A light emitting device was manufactured according to the same manner as in Example D1, except that liquid composition 15 was employed instead of liquid composition 2, and evaluated. The maximum current efficiency was 4.0 cd/A. Also, time (LT50) until luminance became 50% of initial luminance when driven with constant current at an initial luminance of 5,000 cd/m² was 56 hours.

### Comparative Example DB2

### (Manufacture and Evaluation of Light Emitting Device DB2)

A light emitting device was manufactured according to the same manner as in Example D1, except that liquid composition 16 was employed instead of liquid composition 2, and evaluated. The maximum current efficiency was 3.7 cd/A. Also, time (LT50) until the luminance became 50% of initial luminance when driven with constant current at an initial luminance of 5,000 cd/m² was 56 hours.

TABLE 6

| | | | Storage | Illuminance | |
|---|---|---|---|---|---|
| | | | time | (lm/m²) × | |
| | Liquid | Irra- | after | Irradiation | |
| | compo- | diation | shading | time | |
| | sition | time (h) | (h) | (s) | Device |
| Com- | Liquid | 0.1 | 77.9 | 2.0E+05 | Comparative |
| parative | compo- | | | | Example DB1 |
| Example | sition 15 | | | | |
| B2 | | | | | |
| Com- | Liquid | 78 | 0 | 1.4E+08 | Comparative |
| parative | compo- | | | | Example DB2 |
| Example | sition 16 | | | | |
| B3 | | | | | |

TABLE 7

| | | Current | |
|---|---|---|---|
| | | efficiency | Lifetime LT50 (h) |
| Device | Liquid composition | (cd/A) | (@5000 cd/m²) |
| Comparative | Liquid composition15 | 4.0 | 56 |
| Example DB1 | | | |
| Comparative | Liquid composition16 | 3.7 | 56 |
| Example DB2 | | | |

Based on the results of Comparative Example DB1 and Comparative Example DB2, at an event that a phosphorescent material was not included, even Comparative Example DB2 that employs liquid composition 16 with 1.4×10⁸ (sec·lm/m²) of E×t value of light having a wavelength component of from 500 nm to 780 nm, that largely exceeded 4.8×10⁷ (sec·lm/m²), did not deteriorate in current efficiency and lifetime.

Based on the above, it has been realized that the present invention achieves improvement in storage stability, that is a problem for a liquid composition for an organic electroluminescent device including a phosphorescent material and a solvent.

### Example E1

### (Preparation of Transmittance Data)

Under yellow light (fluorescent lamp “FLR40S-Y-F/M-P” (trade name) manufactured by Panasonic Corporation) with illuminance of 510 lm/m², illuminance was measured using an illuminometer (“HIOKI lux HI TESTER 3421” (trade name) manufactured by Hioki E.E. CORPORATION) with varying the number of wide-range ultraviolet blocking films (“Lumicool 1905”(trade name) manufactured by Lintec Corporation). The measured illuminance was divided by illuminance with employing no film, and it was defined as transmittance. The result is shown in Table 8.

TABLE 8

| Number of films | Transmittance |
|---|---|
| 1 | 58.8% |
| 2 | 41.2% |
| 4 | 23.5% |
| 8 | 5.88% |
| 12 | 3.43% |
| 13 | 2.82% |
| 14 | 2.21% |
| 15 | 1.59% |
| 16 | 0.98% |

### Example E2

### (Transmittance and Visibility of Liquid Inside Package)

Under yellow light (fluorescent lamp “FLR40S-Y-F/M-P”(trade name) manufactured by Panasonic Corporation) with illuminance of 510 lm/m², a transparent screw bottle (“No. 5” (trade name) manufactured by Maruemu Corporation), to which cyclohexylbenzene was contained in about half an amount, was placed, and visual observation was conducted whether or not the liquid surface was able to be confirmed with varying the number of wide-range ultraviolet cutting films (“Lumicool 1905” (trade name) manufactured by Lintec Corporation) put on side surface of the screw bottle. The result is shown in Table 9.

TABLE 9

| Number of films | Transmittance | Visibility |
|---|---|---|
| 1 | 58.8% | ∘ |
| 2 | 41.2% | ∘ |
| 4 | 23.5% | ∘ |
| 8 | 5.88% | ∘ |
| 12 | 3.43% | ∘ |
| 13 | 2.82% | Δ |
| 14 | 2.21% | Δ |
| 15 | 1.59% | Δ |
| 16 | 0.98% | x |

Explanatory notes
∘ . . . Liquid surface is easily confirmed
Δ . . . Liquid surface is confirmed when shaking container
x . . . Liquid surface is not confirmed

### Example E3

### (Transmittance and Visibility of Liquid Inside Package)

Under white daylight (fluorescent lamp “FHF32N-EDL-NU” (trade name) manufactured by Panasonic Corporation) with illuminance of 450 lm/m², a transparent screw bottle (“No. 5” (trade name) manufactured by Maruemu Corporation), to which cyclohexylbenzene was contained in about half an amount, was placed, and visual observation was conducted whether or not the liquid surface was able to be confirmed with varying the number of wide-range ultraviolet blocking films (“Lumicool 1905” (trade name) manufactured by Lintec Corporation) put on side surface of the screw bottle. The result is shown in Table 10.

TABLE 10

| Number of films | *Transmittance | Visibility |
|---|---|---|
| 1 | 58.8% | ∘ |
| 2 | 41.2% | ∘ |
| 4 | 23.5% | ∘ |
| 8 | 5.88% | ∘ |
| 12 | 3.43% | ∘ |
| 13 | 2.82% | ∘ |
| 14 | 2.21% | Δ |
| 15 | 1.59% | Δ |
| 16 | 0.98% | Δ |

*Transmittance: Value under yellow light described in Example 1.
Explanatory notes
∘ . . . Liquid surface is easily confirmed
Δ . . . Liquid surface is confirmed when shaking container
x . . . Liquid surface is not confirmed

Based on the above, with regard to visibility aspect, the transmittance is preferably 1% or more, more preferably 2.5% or more, and further preferably 3% or more.

1. A package of a liquid composition for an organic electroluminescent device having a liquid composition for an organic electroluminescent device including a phosphorescent material and a solvent, and a container that contains the liquid composition for an organic electroluminescent device, wherein the package of a liquid composition for an organic electroluminescent device has a transmittance of light, that is a wavelength component of from 500 nm to 780 nm, from outside of the package to inside of the container of 15% or less.

2. The package of a liquid composition for an organic electroluminescent device according to claim 1, having a wrapping material that covers the container.

3. The package of a liquid composition for an organic electroluminescent device according to claim 2, wherein the container has a light-transmitting part, and the wrapping material covers at least the light-transmitting part of the container.

4. The package of a liquid composition for an organic electroluminescent device according to claim 1, wherein the phosphorescent material is a compound represented by formula (11):
[Chemical Formula 1]
M(L)ₖₐ(Z)_{kb} (11)
wherein, M represents ruthenium, rhodium, palladium, osmium, iridium or platinum, L represents a neutral or monovalent to trivalent anionic ligand that may multidentately coordinate by forming at least two bonds selected from the group consisting of a coordinate bond and a covalent bond with the metal atom represented by M, Z represents a counter anion, ka represents an integer of 1 or more, and kb represents an integer of 0 or more, when there are a plurality of Ls, they may be the same or different from each other, and when there are a plurality of Zs, they may be the same or different from each other.

5. The package of a liquid composition for an organic electroluminescent device according to claim 1, wherein the phosphorescent material is a polymer compound having a constitutional unit derived from formula (11).

6. The package of a liquid composition for an organic electroluminescent device according to claim 4, wherein M in formula (11) is iridium.

7. The package of a liquid composition for an organic electroluminescent device according to claim 4, wherein L in formula (11) is a monoanionic ortho-metallized ligand.

8. The package of a liquid composition for an organic electroluminescent device according to claim 1, wherein the liquid composition for an organic electroluminescent device further includes an organic compound that is solid at 1 atm and 25° C.

9. The package of a liquid composition for an organic electroluminescent device according to claim 8, wherein the organic compound is a polymer compound.

10. The package of a liquid composition for an organic electroluminescent device according to claim 1, wherein the solvent is an aromatic hydrocarbon, an aromatic ether or a mixed solvent of an aromatic hydrocarbon and an aromatic ether.

11. The package of a liquid composition for an organic electroluminescent device according to claim 1, wherein, the liquid composition for an organic electroluminescent device has a product of an illuminance E (lm/m²) of the light, that is a wavelength component of from 500 nm to 780 nm, to which the liquid composition has been exposed, and irradiation time t (sec) of the light, to which the liquid composition has been exposed, of 4.8×10⁷ (sec·lm/m²) or less.

12. The package of a liquid composition for an organic electroluminescent device according to claim 1, wherein a part or the whole of a package part has a transmittance of light, that is a wavelength component of from 500 nm to 780 nm, of 1% or more.
